(19) United States
(12) Patent Application Publication
(10) Pub. No.: US 2023/0333434 A1
(43) Pub. Date: Oct. 19, 2023

(54) MAPPING ACOUSTIC PROPERTIES IN AN ENCLOSURE

(71) Applicant: View, Inc., Milpitas, CA (US)

(72) Inventors: Anurag Gupta, San Jose, CA (US); Brandon Dillan Tinianov, Santa Clara, CA (US); Nitesh Trikha, Pleasanton, CA (US)

(21) Appl. No.: 18/042,712

(22) PCT Filed: Aug. 20, 2021
(86) PCT No.: PCT/US2021/046838

§ 371 Date: Feb. 23, 2023

Related U.S. Application Data
(63) Continuation-in-part of application No. 16/447,169, filed on Jun. 20, 2019, now Pat. No. 11,743,071.
Application No. PCT/US2021/046838 is a continuation-in-part of application No. 17/083,128, filed on Oct. 28, 2020.
Application No. 17/083,128 is a continuation of application No. 16/664,089, filed on Oct. 25, 2019, now Pat. No. 11,294,254.
Application No. 16/664,089 is a continuation-in-part of application No. PCT/US2019/030467, filed on May 2, 2019.
Application No. 16/664,089 is a continuation-in-part of application No. PCT/US2018/029460, filed on Apr. 25, 2018.
Application No. PCT/US2021/046838 is a continuation-in-part of application No. 17/759,709, filed on Jul. 28, 2022.
Application No. 17/759,709 is a continuation-in-part of application No. 17/251,100, filed on Dec. 10, 2020.
Application No. PCT/US2021/046838 is a continuation-in-part of application No. 17/922,219, filed on Oct. 28, 2022.
Application No. 17/922,219 is a continuation-in-part of application No. 17/904,156, filed on Aug. 12, 2022.
(60) Provisional application No. 63/233,122, filed on Aug. 13, 2021.
(60) Provisional application No. 63/069,358, filed on Aug. 24, 2020.
(60) Provisional application No. 62/858,100, filed on Jun. 6, 2019.
(60) Provisional application No. 62/803,324, filed on Feb. 8, 2019.
(60) Provisional application No. 62/768,775, filed on Nov. 16, 2018.
(60) Provisional application No. 62/688,957, filed on Jun. 22, 2018.
(60) Provisional application No. 62/666,033, filed on May 2, 2018.
(60) Provisional application No. 62/607,618, filed on Dec. 19, 2017.
(60) Provisional application No. 62/523,606, filed on Jun. 22, 2017.
(60) Provisional application No. 62/507,704, filed on May 17, 2017.
(60) Provisional application No. 62/506,514, filed on May 15, 2017.
(60) Provisional application No. 62/490,457, filed on Apr. 26, 2017.
(60) Provisional application No. 62/967,204, filed on Jan. 29, 2020.
(60) Provisional application No. 62/827,674, filed on Apr. 1, 2019.
(60) Provisional application No. 62/683,572, filed on Jun. 11, 2018.
(60) Provisional application No. 63/079,851, filed on Sep. 17, 2020.
(60) Provisional application No. 63/034,792, filed on Jun. 4, 2020.
(60) Provisional application No. 63/020,819, filed on May 6, 2020.
(60) Provisional application No. 63/146,365, filed on Feb. 5, 2021.
(60) Provisional application No. 63/027,452, filed on May 20, 2020.
(60) Provisional application No. 62/978,755, filed on Feb. 19, 2020.
(60) Provisional application No. 62/977,001, filed on Feb. 14, 2020.

(51) Int. Cl. G02F 1/163; G05B 19/042; G06F 3/044; G05B 15/02; G02F 1/15; B32B 17/10; E06B 9/24; G02F 1/155; G06F 3/041; H02J 50/80; H02J 50/20; G09F 19/22; G06F 3/14; G09G 3/38; H10K 50/80; H10K 59/65

(52) U.S. Cl. CPC G02F 1/163; G05B 19/0426; G06F 3/044; G05B 15/02; G02F 1/15; B32B 17/10513; E06B 9/24; G02F 1/155; G06F 3/0412; H02J 50/80; H02J 50/20; G05B 19/042; G09F 19/227; G06F 3/1446; G09G 3/38; H10K 50/80; H10K 59/65; H04K 3/45

(57) ABSTRACT

Disclosed herein are methods, apparatuses, systems, and computer readable media relating to formation of acoustic conditioning and acoustic mapping of an enclosure using sound sensor(s) and emitter(s).

### RELATED APPLICATIONS

This application claims priority from U.S. Provisional patent application Ser. No. 63/069,358 filed Aug. 24, 2020, titled “MAPPING ACOUSTIC PROPERTIES IN AN ENCLOSURE,” and from U.S. Provisional patent application Ser. No. 63/233,122 filed Aug. 13, 2021, titled “MAPPING ACOUSTIC PROPERTIES IN AN ENCLOSURE.” This application also claims priority from U.S. patent application Ser. No. 16/447,169, filed Jun. 20, 2019, titled “SENSING AND COMMUNICATIONS UNIT FOR OPTICALLY SWITCHABLE WINDOW SYSTEMS,” which is a Continuation-in-Part of International Patent Application Serial No. PCT/US19/30467, filed May 2, 2019, titled “EDGE NETWORK FOR BUILDING SERVICES,” and which claims priority to U.S. Provisional patent application Ser. No. 62/688,957, filed Jun. 22, 2018, titled “SENSING AND COMMUNICATIONS UNIT FOR OPTICALLY SWITCHABLE WINDOW SYSTEMS;” U.S. Provisional patent application Ser. No. 62/768,775, filed Nov. 16, 2018, titled “SENSING AND COMMUNICATIONS UNIT FOR OPTICALLY SWITCHABLE WINDOW SYSTEMS;” U.S. Provisional patent application Ser. No. 62/803,324, filed Feb. 8, 2019, titled “SENSING AND COMMUNICATIONS UNIT FOR OPTICALLY SWITCHABLE WINDOW SYSTEMS;” U.S. Provisional patent application Ser. No. 62/858,100, filed Jun. 6, 2019, titled “SENSING AND COMMUNICATIONS UNIT FOR OPTICALLY SWITCHABLE WINDOW SYSTEMS;” and U.S. Provisional patent application Ser. No. 62/666,033, filed May 2, 2018, titled “EDGE NETWORK FOR BUILDING SERVICES. This application also claims priority from International Patent Application Serial No. PCT/US19/38429 filed Jun. 21, 2021, titled “SENSING AND COMMUNICATIONS UNIT FOR OPTICALLY SWITCHABLE WINDOW SYSTEMS,” which claim priority to U.S. patent application Ser. No. 16/447,169 and to its priority chain recited herein.” This application claims priority from International Patent Application Serial No. PCT/US21/17946 filed Feb. 12, 2021 titled “DATA AND POWER NETWORK OF A FACILITY,” which claim priority from U.S. Provisional patent application Ser. No. 63/146,365, filed Feb. 5, 2021, from U.S. Provisional patent application Ser. No. 63/027,452, filed May 20, 2020, from U.S. Provisional patent application Ser. No. 62/978,755, filed Feb. 19, 2020; from U.S. Provisional patent application Ser. No. 62/977,001, filed Feb. 14, 2020. This application is also a Continuation-in-Part of U.S. patent application Ser. No. 17/083,128, filed Oct. 28, 2020, titled “BUILDING NETWORK,” which is a Continuation of U.S. patent application Ser. No. 16/664,089, filed Oct. 25, 2019, titled “BUILDING NETWORK.” U.S. patent application Ser. No. 17/083,128 is also a Continuation-in-Part of International Patent Application Serial No. PCT/US19/30467, filed May 2, 2019, titled “EDGE NETWORK FOR BUILDING SERVICES,” which claims priority from U.S. Provisional patent application Ser. No. 62/666,033, filed May 2, 2018, titled “EDGE NETWORK FOR BUILDING SERVICES.” U.S. patent application Ser. No. 16/664,089 is also a Continuation-in-Part of International Patent Application Serial No. PCT/US18/29460, filed Apr. 25, 2018, titled “TINTABLE WINDOW SYSTEM FOR BUILDING SERVICES,” that claims priority from U.S. Provisional patent application Ser. No. 62/607,618, filed on Dec. 19, 2017, titled “ELECTROCHROMIC WINDOWS WITH TRANSPARENT DISPLAY TECHNOLOGY FIELD,” from U.S. Provisional patent application Ser. No. 62/523,606, filed on Jun. 22, 2017, titled “ELECTROCHROMIC WINDOWS WITH TRANSPARENT DISPLAY TECHNOLOGY,” from U.S. Provisional patent application Ser. No. 62/507,704, filed on May 17, 2017, “ELECTROCHROMIC WINDOWS WITH TRANSPARENT DISPLAY TECHNOLOGY,” from U.S. Provisional patent application Ser. No. 62/506,514, filed on May 15, 2017, titled “ELECTROCHROMIC WINDOWS WITH TRANSPARENT DISPLAY TECHNOLOGY,” and from U.S. Provisional patent application Ser. No. 62/490,457, filed on Apr. 26, 2017, titled “ELECTROCHROMIC WINDOWS WITH TRANSPARENT DISPLAY TECHNOLOGY.” This application also claims priority to International Patent Application Serial No. PCT/US21/15378 filed Jan. 28, 2021, titled “SENSOR CALIBRATION AND OPERATION,” which claims priority from U.S. Provisional patent application Ser. No. 62/967,204, filed Jan. 29, 2020, titled “SENSOR CALIBRATION AND OPERATION.” International Patent Application Serial No. PCT/US21/15378 is also a Continuation-in-Part of U.S. patent application Ser. No. 17/083,128 and its priority chain recited herein. International Patent Application Serial No. PCT/US21/15378 is also a Continuation-in-Part of U.S. patent application Ser. No. 16/447,169 and its priority chain recited herein. This application is also a continuation in part of International Patent Application Serial No. PCT/US19/36571 filed Jun. 11, 2019, titled “OPTICALLY SWITCHABLE WINDOWS FOR SELECTIVELY IMPEDING PROPAGATION OF LIGHT FROM AN ARTIFICIAL SOURCE,” which claims priority from U.S. Provisional patent application Ser. No. 62/827,674 filed Apr. 1, 2019 titled “OPTICALLY SWITCHABLE WINDOWS FOR SELECTIVELY IMPEDING PROPAGATION OF LIGHT FROM AN ARTIFICIAL SOURCE,” and from U.S. Provisional patent application Ser. No. 62/683,572 field Jun. 11, 2018, titled “OPTICALLY SWITCHABLE WINDOWS IN LiFi SYSTEMS.” This application is a continuation in part of International Patent Application Serial No. PCT/US21/30798 filed May 5, 2021, titled “DEVICE ENSEMBLES AND COEXISTENCE MANAGEMENT OF DEVICES,” which claims priority from (a) from U.S. Provisional patent application Ser. No. 63/079,851, filed Sep. 17, 2020, titled “DEVICE ENSEMBLES AND COEXISTENCE MANAGEMENT OF DEVICES,” (b) from U.S. Provisional patent application Ser. No. 63/034,792, filed Jun. 4, 2020, titled “DEVICE ENSEMBLES AND COEXISTENCE MANAGEMENT OF DEVICES,” and (c) from U.S. Provisional patent application Ser. No. 63/020,819, filed May 6, 2020, titled “DEVICE ENSEMBLES AND COEXISTENCE MANAGEMENT OF DEVICES.” Each of the patent applications recited above is incorporated by reference herein in its entirety.

### BACKGROUND

A processing system may have a plurality of nodes that may be linked together in a network. The processing system can be, can be included in, or can include a control system. Some of the nodes may include software and/or hardware that may be configured to operate various systems in one or more facilities (i.e., enclosures). Facilities can include at least one building or any portion(s) of the building. The operating systems to be controlled can include smart windows (e.g., having insulated glass units such as electrochromic devices), building management systems, environmental sensors, and/or actuators (e.g., HVAC systems).

Optically switchable windows, sometimes referred to as “smart windows,” exhibit a controllable and reversible change in an optical property when appropriately stimulated by, for example, a voltage change. The optical property is typically color, transmittance, absorbance, and/or reflectance. Electrochromic (EC) devices are sometimes used in optically switchable windows. One well-known electrochromic material, for example, is tungsten oxide (WO₃). Tungsten oxide is a cathodic electrochromic material in which a coloration transition, transparent to blue, occurs by electrochemical reduction.

Electrically switchable windows, sometimes referred to as “smart windows”, whether electrochromic or otherwise, may be used in buildings to control transmission of solar energy. Switchable windows may be manually or automatically tinted and cleared to reduce energy consumption, by heating, air conditioning and/or lighting systems, while maintaining occupant comfort.

Electrochromic materials may be incorporated into, for example, windows for home, commercial and other uses as thin film coatings on the window glass. A small voltage applied to an electrochromic device of the window will cause them to darken; reversing the voltage polarity causes them to lighten. This capability allows control of the amount of light that passes through the windows and presents an opportunity for electrochromic windows to be used as energy-saving devices.

A community of components (e.g., sensors, emitters, timing circuits, actuators, transmitters, and/or receivers) may be placed at various locations in an enclosure (e.g., a facility, a building, and/or a room) to analyze, detect, and/or react to: data, an/or (e.g., environmental) aspects of the enclosure. The various aspects may include temperature, humidity, sound, electromagnetic waves, position, distance, movement, speed, vibration, volatile compounds (VOCs), dust, light, glare, color, gases, and/or other aspects of the enclosure. Components may be deployed in an ensemble in a common assembly having a housing (e.g., box) containing a requested grouping of such components (e.g., modules). The components may include sensors, emitters, actuators, controllers, processors, antenna, electronic memory, and/or other peripheral electronics. The peripheral electronics may interconnect in a hierarchical manner, such as is shown in U.S. patent Ser. No. 10,495,939, issued Dec. 3, 2019, titled “CONTROLLERS FOR OPTICALLY-SWITCHABLE DEVICES,” that is incorporated herein by reference in its entirety.

To establish, manipulate, and/or maximize acoustic comfort, accurate sound mapping (e.g., and tuning) of various facility environments (e.g., of rooms) may be beneficial, e.g., to ensure that these environments are acoustically suitable for their intended purpose. For example, a conference room or library may have stricter sound requirements that an entrance hall or cafeteria. The acoustics of an environment depends, e.g., on the various fixtures and non-fixtures in that environment, their arrangement, material properties and the like. The acoustics of an environment may be subject to change when these fixtures and non-fixtures are altered. Fixtures may include non-movable objects such as walls, ceilings, floors, light fixtures and/or other immovable or semi-permanent objects. Non-fixtures may include movable objects, e.g., furniture, appliances, portable light fixtures, plants, blinds, shutters, computers and/or people.

### SUMMARY

According to some aspects, in order to accurately adjust the acoustic characteristic of the environment, a current acoustic map of the facility areas is established. An update of the acoustic mapping during operation of the facility may be required as any of the fixtures and/or non-fixtures change. To reduce costs and burden, and increase accuracy of the acoustic map, updates of the acoustic map of the facility can be done automatically and/or as close as possible to the change made to the facility (e.g., in real time). In some embodiments, sound emitters (e.g., speakers) and sound sensors (e.g., microphones) disposed in the facility are used to acoustically map facility environments. The sound emitters and sensors have a known location and are communicative coupled via a network, e.g., a building communications and power network, e.g., as described in This application claims priority from International Patent Application Serial No. PCT/US21/17946 filed Feb. 12, 2021, titled “DATA AND POWER NETWORK OF A FACILITY,” which is incorporated herein by reference in its entirety. The sound emitters and sensors may use (i) sound frequency sweeping, (ii) their location, and (iii) mutual coordination, to generate the acoustic mapping of the facility. Such acoustic mapping can be done automatically, in situ, and/or in real time. Any change in the facility affecting the acoustic mapping can be accounted for in initial acoustic mapping and/or updates. In one example, acoustic mapping allows one to know how well various facility environments are isolated from noise, and those that are not sufficiently isolated. From this data, e.g., by including sound absorbers, diffusers and/or deflectors in specific areas, insufficiently acoustically isolated facility environments can be modified to improve the acoustic isolation. In another example, acoustics of a space can be tuned for a specific purpose, such as interpersonal communication, musical listening, and the like.

In another aspect, a method of acoustic mapping, the method comprises: (A) using an emitter to emit a first acoustic test signal, which first emitter is disposed at a first location in an enclosure; (B) using a sensor to measure a first acoustic response corresponding to the first acoustic test signal, which sensor is disposed at a second location; (C) storing a first acoustic map indicative of an acoustic transfer function between the first location and the second location; (D) using the emitter to emit a second acoustic test signal; (E) measuring a second acoustic response corresponding to the second acoustic test signal; (F) determining a second acoustic map; and (G) generating a notification and/or a report when a difference between the second acoustic map and the first acoustic map is greater than a threshold.

In some embodiments, the emitter is part of a device ensemble housing at least one sensor and at least one emitter. In some embodiments, the threshold is a function. In some embodiments, the emitter is operatively coupled to a control system. In some embodiments, the method further comprises controlling at least one apparatus in the enclosure and/or in a facility in which the enclosure is disposed, which controlling is by the control system. In some embodiments, the at least one apparatus comprises a lighting device, a tintable window, another sensor, another emitter, a media display, a dispenser, a processor, a power source, a security system, a fire alarm system, a sound media, a heater, a cooler, a vent, or a heating ventilation and air conditioning system (HVAC). In some embodiments, the control system comprises a hierarchy of controllers. In some embodiments, the emitter is operatively coupled to a network. In some embodiments, the sensor is communicatively coupled to a network in a wired and/or wireless manner. In some embodiments, the emitter and/or the sensor are communicatively coupled to a network in a wired and/or wireless manner. In some embodiments, the network is configured to transmit power and/or data. In some embodiments, the network is configured to transmit broadband cellular network technology communication of at least a third generation, fourth generation, or fifth generation cellular communication protocol. In some embodiments, the network is operatively coupled to a router, multiplier, antenna, and/or transceiver. In some embodiments, the network is disposed at least in an envelope of the enclosure and/or a building in which the enclosure is disposed. In some embodiments, the emitter comprises a buzzer. In some embodiments, the method further comprises using the emitter to emit sounds including discrete sounds of a sound spectrum. In some embodiments, the sensor is configured to detect sounds including continuous sounds of a sound spectrum. In some embodiments, the method further comprises using the emitter to emit sounds including sounds of a sound having a spectrum frequency of from about 10 Hz to about 20 kHz. In some embodiments, the method further comprises using the emitter to emit the first acoustic test signal and/or the second acoustic test signal according to a schedule. In some embodiments, the method further comprises using the emitter to emit the first acoustic test signal and/or the second acoustic test signal when the enclosure is non-inhabited. In some embodiments, the method further comprises using the emitter to emit the first acoustic test signal and/or the second acoustic test signal outside standard work hours in the enclosure and/or in a facility in which the enclosure is disposed. In some embodiments, the method further comprises using the emitter to emit the first acoustic test signal and/or the second acoustic test signal when the enclosure is forecasted to experience a quiet period of a length that is at least sufficient to generate the first acoustic map and/or the second acoustic map. In some embodiments, the method further comprises using the emitter to emit the second acoustic test signal according to a schedule that considers a change in a fixture of the enclosure and/or of the facility in which the enclosure is disposed. In some embodiments, the method further comprises using the emitter to emit the second acoustic test signal according to a schedule that considers a change in a Building Information Modeling file of the enclosure and/or of the facility in which the enclosure is disposed. In some embodiments, the enclosure is at least part of a building, or a vehicle. In some embodiments, the enclosure comprises a room. In some embodiments, the enclosure is configured for one or more occupants. In some embodiments, the sensor is comprised in a device ensemble housing another device that includes at least one sensor and/or at least one emitter. In some embodiments, the second location is in the enclosure. In some embodiments, the second location is outside of the enclosure. In some embodiments, the storing of the first acoustic map utilizes a memory disposed in the enclosure, and/or in a building in which the enclosure is disposed. In some embodiments, storing of the first acoustic map utilizes a memory disposed outside of the enclosure and/or outside of a building in which the enclosure is disposed. In some embodiments, storing of the first acoustic map is in an ensemble housing at least one other device including at least one sensor and/or at least one emitter. In some embodiments, storing of the first acoustic map utilizes a network to which the sensor and emitter are coupled to. In some embodiments, the first acoustic map and/or the second acoustic map is generated by a processor that is part of, or is operatively coupled to, a control system. In some embodiments, the acoustic map is generated by a processor that is part of, or is operatively coupled to, a network to which the sensor and emitter are coupled to. In some embodiments, generation of the acoustic map excludes utilizing a Building Information Modeling file of the enclosure and/or of the facility in which the enclosure is disposed. In some embodiments, generation of the acoustic map comprises utilizing a Building Information Modeling file of the enclosure and/or of the facility in which the enclosure is disposed. In some embodiments, measurement of the second acoustic response is by the same sensor measuring the first acoustic response. In some embodiments, the sensor is a first sensor, and wherein measurement of the second acoustic response is at least in part by a second sensor. In some embodiments, the second sensor is disposed in the enclosure. In some embodiments, the second sensor is disposed outside of the enclosure. In some embodiments, the sensor is a first sensor, and wherein the method further comprises operations: (H) using a second sensor disposed at a third location to measure a third acoustic response to the second acoustic test signal, wherein the second acoustic response measured in (E) is sensed at the second location by the second sensor; and (I) comparing the second acoustic response and the third acoustic response to detect a fault in the emitter or in one of the sensors. In some embodiments, the emitter is a first emitter, and wherein the method further comprises operations: (H) using a second emitter at a third location to emit a third acoustic test signal; (I) measuring a third acoustic response corresponding to the third acoustic test signal; and (J) comparing the third acoustic response to the acoustic response to the second acoustic test signal to detect a fault in the sensor, in the first emitter, or in the second emitter. In some embodiments, the method further comprises operations: (H) detecting an irregular sound event in the enclosure utilizing a plurality of sensors that include the sensor; (I) compensating the detected sound event according to a corresponding acoustic transfer function from the first acoustic map and/or the second acoustic map; (J) recognizing an event type utilizing the compensated detected sound event; and (K) generating a notification of the event type to a user. In some embodiments, the method further comprises localizing an origination of the irregular sound event based at least in part on relative magnitudes of the detected irregular sound event by at least two, or by at least three of the plurality of sensors.

In another aspect, a non-transitory computer readable media for acoustic mapping, the non-transitory computer readable media, when read by one or more processors, is configured to execute operations comprises: (A) using, or direct usage of, an emitter to emit a first acoustic test signal, which first emitter is disposed in a first location in an enclosure; (B) using, or direct usage of, a sensor to measure a first acoustic response corresponding to the first acoustic test signal, which sensor is disposed in a second location; (C) storing, or direct storage of, a first acoustic map indicative of an acoustic transfer function between the first location and the second location; (D) using, or direct usage of, the emitter to emit a second acoustic test signal; (E) measuring, or directing measurement of, a second acoustic response corresponding to the second acoustic test signal; (F) determining, or directing determination of, a second acoustic map; and (G) generating, or directing generation of, a notification and/or a report when a difference between the second acoustic map and the first acoustic map is greater than a threshold.

In some embodiments, the emitter is part of a device ensemble housing at least one sensor and at least one emitter. In some embodiments, the threshold is a function. In some embodiments, the emitter is operatively coupled to a control system. In some embodiments, the operations comprise controlling at least one apparatus in the enclosure and/or in a facility in which the enclosure is disposed, which controlling is by the control system. In some embodiments, the at least one apparatus comprises a lighting device, a tintable window, another sensor, another emitter, a media display, a dispenser, a processor, a power source, a security system, a fire alarm system, a sound media, a heater, a cooler, a vent, or a heating ventilation and air conditioning system (HVAC). In some embodiments, the control system comprises a hierarchy of controllers. In some embodiments, the emitter is operatively coupled to a network. In some embodiments, the sensor is communicatively coupled to a network in a wired and/or wireless manner. In some embodiments, the emitter and/or the sensor are communicatively coupled to a network in a wired and/or wireless manner. In some embodiments, the network is configured to transmit power and/or data. In some embodiments, the network is configured to transmit broadband cellular network technology communication of at least a third generation, fourth generation, or fifth generation cellular communication protocol. In some embodiments, the network is operatively coupled to a router, multiplier, antenna, and/or transceiver. In some embodiments, the network is disposed at least in an envelope of the enclosure and/or a building in which the enclosure is disposed. In some embodiments, the emitter comprises a buzzer. In some embodiments, the operations comprise using the emitter to emit sounds including discrete sounds of a sound spectrum. In some embodiments, the sensor is configured to detect sounds including continuous sounds of a sound spectrum. In some embodiments, the operations comprise using the emitter to emit sounds including sounds of a sound having a spectrum frequency of from about 10 Hz to about 20 kHz. In some embodiments, the operations comprise using the emitter to emit the first acoustic test signal and/or the second acoustic test signal according to a schedule. In some embodiments, the operations comprise using the emitter to emit the first acoustic test signal and/or the second acoustic test signal when the enclosure is non-inhabited. In some embodiments, the operations comprise using the emitter to emit the first acoustic test signal and/or the second acoustic test signal outside standard work hours in the enclosure and/or in a facility in which the enclosure is disposed. In some embodiments, the operations comprise using the emitter to emit the first acoustic test signal and/or the second acoustic test signal when the enclosure is forecasted to experience a quiet period of a length that is at least sufficient to generate the first acoustic map and/or the second acoustic map. In some embodiments, the operations comprise using the emitter to emit the second acoustic test signal according to a schedule that considers a change in a fixture of the enclosure and/or of the facility in which the enclosure is disposed. In some embodiments, the operations comprise using the emitter to emit the second acoustic test signal according to a schedule that considers a change in a Building Information Modeling file of the enclosure and/or of the facility in which the enclosure is disposed. In some embodiments, the enclosure is at least part of a building, or a vehicle. In some embodiments, the enclosure comprises a room. In some embodiments, the enclosure is configured for one or more occupants. In some embodiments, the sensor is comprised in a device ensemble housing another device that includes at least one sensor and/or at least one emitter. In some embodiments, the second location is in the enclosure. In some embodiments, the second location is outside of the enclosure. In some embodiments, storing of the first acoustic map utilizes a memory disposed in the enclosure, and/or in a building in which the enclosure is disposed. In some embodiments, storing of the first acoustic map utilizes a memory disposed outside of the enclosure and/or outside of a building in which the enclosure is disposed. In some embodiments, storing of the first acoustic map is in an ensemble housing at least one other device including at least one sensor and/or at least one emitter. In some embodiments, storing of the first acoustic map utilizes a network to which the sensor and emitter are coupled to. In some embodiments, the first acoustic map and/or the second acoustic map is generated by a processor that is part of, or is operatively coupled to, a control system. In some embodiments, the operations further comprise generating, or directing generation of, the acoustic map by at least one processor that is part of, or is operatively coupled to, a network to which the sensor and emitter are coupled to. In some embodiments, generation of the acoustic map excludes utilizing a Building Information Modeling file of the enclosure and/or of the facility in which the enclosure is disposed. In some embodiments, generation of the acoustic map comprises utilizing a Building Information Modeling file of the enclosure and/or of the facility in which the enclosure is disposed. In some embodiments, measurement of the second acoustic response is by the same sensor measuring the first acoustic response. In some embodiments, the sensor is a first sensor, and wherein measurement of the second acoustic response is at least in part by a second sensor. In some embodiments, the second sensor is disposed in the enclosure. In some embodiments, the second sensor is disposed outside of the enclosure. In some embodiments, the sensor is a first sensor, and wherein the operations comprise: (H) using a second sensor disposed at a third location to measure a third acoustic response to the second acoustic test signal, wherein the second acoustic response measured in (E) is sensed at the second location by the second sensor; and (I) comparing the second acoustic response and the third acoustic response to detect a fault in the emitter or in one of the sensors. In some embodiments, the emitter is a first emitter, and wherein the operations comprise: (H) using a second emitter at a third location to emit a third acoustic test signal; (I) measuring a third acoustic response corresponding to the third acoustic test signal; and (J) comparing the third acoustic response to the acoustic response to the second acoustic test signal to detect a fault in the sensor, in the first emitter, or in the second emitter. In some embodiments, the operations comprise: (H) detecting an irregular sound event in the enclosure utilizing a plurality of sensors that include the sensor; (I) compensating the detected sound event according to a corresponding acoustic transfer function from the first acoustic map and/or the second acoustic map; (J) recognizing an event type utilizing the compensated detected sound event; and (K) generating a notification of the event type to a user.

In another aspect, an apparatus for acoustic mapping, the apparatus comprises at least one controller comprising circuitry, which at least one controller is configured to: (A) operatively couple to a first emitter, a second emitter, and to a sensor; (B) direct the first emitter to emit, a first acoustic test signal, which first emitter is disposed in a first location in an enclosure; (C) direct the sensor to measure a first acoustic response corresponding to the first acoustic test signal, which sensor is disposed in a second location; (D) store, or direct storage of, a first acoustic map indicative of an acoustic transfer function between the first location and the second location; (E) direct the first emitter to emit a second acoustic test signal; (F) direct measurement of a second acoustic response corresponding to the second acoustic test signal; (G) determine, or direct determination of, a second acoustic map; and (H) generate, or direct generation of, a notification and/or a report when a difference between the second acoustic map and the first acoustic map is greater than a threshold.

In some embodiments, the emitter is included in a device ensemble housing at least one sensor and at least one emitter. In some embodiments, the threshold is a function. In some embodiments, the emitter is operatively coupled to a control system. In some embodiments, the at least one controller is configured to control at least one apparatus in the enclosure and/or in a facility in which the enclosure is disposed, which controlling is by the control system. In some embodiments, the at least one apparatus in the enclosure comprises a lighting device, a tintable window, another sensor, another emitter, a media display, a dispenser, a processor, a power source, a security system, a fire alarm system, a sound media, a heater, a cooler, a vent, or a heating ventilation and air conditioning system (HVAC). In some embodiments, the control system is configured to include a hierarchy of controllers. In some embodiments, the emitter is operatively coupled to a network. In some embodiments, the sensor is communicatively coupled to a network in a wired and/or wireless manner. In some embodiments, the emitter and/or the sensor are communicatively coupled to a network in a wired and/or wireless manner. In some embodiments, the network is configured to transmit power and/or data. In some embodiments, the network is configured to transmit broadband cellular network technology communication of at least a third generation, fourth generation, or fifth generation cellular communication protocol. In some embodiments, the network is operatively coupled to a router, multiplier, antenna, and/or transceiver. In some embodiments, the network is disposed at least in an envelope of the enclosure and/or a building in which the enclosure is disposed. In some embodiments, the emitter comprises a buzzer. In some embodiments, the at least one controller is configured to direct the emitter to emit sounds including discrete sounds of a sound spectrum. In some embodiments, the at least one controller is configured to direct the sensor to detect sounds including continuous sounds of a sound spectrum. In some embodiments, the at least one controller is configured to direct the emitter to emit sounds including sounds of a sound having a spectrum frequency of from about 10 Hz to about 20 kHz. In some embodiments, the at least one controller is configured to direct the emitter to emit the first acoustic test signal and/or the second acoustic test signal according to a schedule. In some embodiments, the at least one controller is configured to direct the emitter to emit the first acoustic test signal and/or the second acoustic test signal when the enclosure is non-inhabited. In some embodiments, the at least one controller is configured to direct the emitter to emit the first acoustic test signal and/or the second acoustic test signal outside standard work hours in the enclosure and/or in a facility in which the enclosure is disposed. In some embodiments, the at least one controller is configured to direct the emitter to emit the first acoustic test signal and/or the second acoustic test signal when the enclosure is forecasted to experience a quiet period of a length that is at least sufficient to generate the first acoustic map and/or the second acoustic map. In some embodiments, the at least one controller is configured to direct the emitter to emit the second acoustic test signal according to a schedule that considers a change in a fixture of the enclosure and/or of the facility in which the enclosure is disposed. In some embodiments, the at least one controller is configured to direct the emitter to emit the second acoustic test signal according to a schedule that considers a change in a Building Information Modeling file of the enclosure and/or of the facility in which the enclosure is disposed. In some embodiments, the enclosure is at least part of a building, or a vehicle. In some embodiments, the enclosure comprises a room. In some embodiments, the enclosure is configured for one or more occupants. In some embodiments, the sensor is comprised in a device ensemble housing another device that includes at least one sensor and/or at least one emitter. In some embodiments, the second location is in the enclosure. In some embodiments, the second location is outside of the enclosure. In some embodiments, the method further comprises a memory storing the first acoustic map, wherein the memory is disposed in the enclosure, and/or in a building in which the enclosure is disposed. In some embodiments, the method further comprises a memory storing the first acoustic map, wherein the memory is disposed outside of the enclosure and/or outside of a building in which the enclosure is disposed. In some embodiments, the method further comprises an ensemble housing at least one other device including at least one sensor and/or at least one emitter, wherein the first acoustic map is stored in the ensemble. In some embodiments, the at least one controller is configured to store the first acoustic map in a network to which the sensor and emitter are coupled to. In some embodiments, the at least one controller is configured to generate the first acoustic map and/or the second acoustic map, and wherein the at least one controller is part of, or is operatively coupled to, a control system. In some embodiments, the at least one controller is configured to generate the acoustic map, and wherein the at least one controller is part of, or is operatively coupled to, a network to which the sensor and emitter are coupled to. In some embodiments, the at least one controller is configured to generate the acoustic map without utilizing a Building Information Modeling file of the enclosure and/or of the facility in which the enclosure is disposed. In some embodiments, the at least one controller is configured to generate the acoustic map utilizing a Building Information Modeling file of the enclosure and/or of the facility in which the enclosure is disposed. In some embodiments, the same sensor measuring the first acoustic response is configured to measure the second acoustic response. In some embodiments, the sensor is a first sensor, and wherein measurement of the second acoustic response is at least in part by a second sensor. In some embodiments, the second sensor is disposed in the enclosure. In some embodiments, the second sensor is disposed outside of the enclosure. In some embodiments, the sensor is a first sensor, and wherein the at least one controller is configured to: (H) operatively couple to a second sensor disposed at a third location; (I) direct the second sensor to measure a third acoustic response to the second acoustic test signal, wherein the second acoustic response measured in (E) is sensed at the second location by the second sensor; and (I) compare, or direct comparison of, the second acoustic response and the third acoustic response to detect a fault in the emitter or in one of the sensors. In some embodiments, the emitter is a first emitter, and wherein the at least one controller is configured to: (H) operatively couple to a second emitter disposed at a third location; (I) direct the second emitter to emit a third acoustic test signal; (J) measure, or direct measurement of, a third acoustic response corresponding to the third acoustic test signal; and (H) compare, or direct comparison of, the third acoustic response to the acoustic response to the second acoustic test signal to detect a fault in the sensor, in the first emitter, or in the second emitter. In some embodiments, the at least one controller is configured to: (H) operatively couple to a plurality of sensors that include the sensor; (I) direct the plurality of sensors to detect an irregular sound event in the enclosure; (J) compensate, or direct compensation of, the detected sound event according to a corresponding acoustic transfer function from the first acoustic map and/or the second acoustic map; (K) recognize, or direct recognition of, an event type utilizing the compensated detected sound event; and (L) generate, or direct generation of, a notification of the event type to a user. In some embodiments, the at least one controller is configured to localize, or direct localization of, an origination of the irregular sound event based at least in part on relative magnitudes of the detected irregular sound event by at least two, or by at least three of the plurality of sensors.

In another aspect, a method of acoustic mapping, the method comprises: (A) using an emitter to emit an acoustic test signal, which emitter is disposed at a first location in an enclosure; (B) using a sensor to measure an acoustic response corresponding to the acoustic test signal, which sensor is disposed at a second location; and (C) using information pertaining to an inanimate alteration to generate an acoustic map indicative of an acoustic transfer function between the first location and the second location, which inanimate alteration is projected to affect the acoustic mapping of the enclosure.

In some embodiments, the emitter is included in a device ensemble housing that includes at least one sensor and/or at least one emitter. In some embodiments, the emitter is operatively coupled to a control system. In some embodiments, the method further comprises controlling at least one apparatus in the enclosure and/or in a facility in which the enclosure is disposed, which controlling is by the control system. In some embodiments, the at least one apparatus comprises a lighting device, a tintable window, another sensor, another emitter, a media display, a dispenser, a processor, a power source, a security system, a fire alarm system, a sound media, a heater, a cooler, a vent, or a heating ventilation and air conditioning system (HVAC). In some embodiments, the control system comprises a hierarchy of controllers. In some embodiments, the emitter is operatively coupled to a network. In some embodiments, the sensor is communicatively coupled to a network in a wired and/or wireless manner. In some embodiments, the emitter and/or the sensor are communicatively coupled to a network in a wired and/or wireless manner. In some embodiments, the network is configured to transmit power and/or data. In some embodiments, the network is configured to transit broadband cellular network technology communication of at least a third generation, fourth generation, or fifth generation cellular communication protocol. In some embodiments, the network is operatively coupled to a router, multiplier, antenna, and/or transceiver. In some embodiments, the network is disposed at least in an envelope of the enclosure and/or a building in which the enclosure is disposed. In some embodiments, the emitter comprises a buzzer. In some embodiments, the method further comprises using the emitter to emit sounds including discrete sounds of a sound spectrum. In some embodiments, the method further comprises using the sensor to sense sounds including discrete sounds of a sound spectrum. In some embodiments, the method further comprises using the emitter to emit sounds including sounds having a spectrum frequency from about 10 Hz to about 20 kHz. In some embodiments, the method further comprises using the emitter to emit the first acoustic test signal and/or the second acoustic test signal according to a schedule. In some embodiments, the method further comprises using the emitter to emit the first acoustic test signal and/or the second acoustic test signal when the enclosure is non-inhabited. In some embodiments, the method further comprises using the emitter to emit the first acoustic test signal and/or the second acoustic test signal outside standard work hours in the enclosure and/or in a facility in which the enclosure is disposed. In some embodiments, the method further comprises using the emitter to emit the second acoustic test signal according to a schedule that considers a change in a Building Information Modeling file of the enclosure and/or of the facility in which the enclosure is disposed. In some embodiments, the enclosure is at least part of a building, or a vehicle. In some embodiments, the enclosure comprises a room. In some embodiments, the enclosure is configured for one or more occupants. In some embodiments, the emitter is a first emitter, and wherein the method further comprises using a second emitter disposed at a third location to emit at least one other acoustic test signal. In some embodiments, the third location is different from the first location and from the second location. In some embodiments, one or more of the locations is disposed in the enclosure. In some embodiments, one or more of the locations is disposed outside the enclosure. In some embodiments, generation of the acoustic map comprises utilizing sensor measurements responsive to the at least one other acoustic test signal. In some embodiments, the second location is in the enclosure. In some embodiments, the second location is outside of the enclosure. In some embodiments, the sensor is a first sensor, and wherein the method further comprises using a second sensor to measure at least one other acoustic response corresponding to the first acoustic test signal, which second sensor is disposed at a third location different from the second location. In some embodiments, the third location is different from the first location. In some embodiments, one or more of the locations is disposed in the enclosure. In some embodiments, one or more of the locations is disposed outside the enclosure. In some embodiments, generation of the acoustic map comprises utilizing measurements of the second sensor. In some embodiments, the second sensor is at least two other sensors. In some embodiments, the second location differs from the third location horizontally and/or vertically. In some embodiments, the method further comprises generating a second acoustic mapping at a second time after the inanimate alteration to detect the alteration in the acoustic transfer function. In some embodiments, the information is based at least in part on a Building Information Modeling file. In some embodiments, the information comprises a shape, or a material property of the one or more fixtures. In some embodiments, the inanimate alteration is of one or more fixtures and/or non-fixtures. In some embodiments, the alteration comprises an alteration in the enclosure. In some embodiments, the alteration comprises an alteration out of the enclosure. In some embodiments, the fixture comprises a wall, a window, a shelf, a lighting, or a door. In some embodiments, the non-fixtures comprise a desk, or a chair. In some embodiments, the inanimate alteration is of an inanimate object. In some embodiments, the first acoustic map is stored in a memory disposed in the enclosure, and/or in a building in which the enclosure is disposed. In some embodiments, the first acoustic map is stored in a memory disposed outside of the enclosure and/or outside of a building in which the enclosure is disposed. In some embodiments, storing the first acoustic map utilizes a network to which the sensor and emitter are coupled to. In some embodiments, the first acoustic map and/or the second acoustic map is generated by a processor that is part of, or is operatively coupled to, a control system. In some embodiments, the acoustic map is generated by a processor that is part of, or is operatively coupled to, a network to which the sensor and emitter are coupled to. In some embodiments, generation of the acoustic map comprises utilizing a Building Information Modeling file of the enclosure and/or of the facility in which the enclosure is disposed. In some embodiments, the first acoustic map is generated within at most about a day, 8 h, 4 h, 2 h, or 1 h. In some embodiments, generation of the acoustic map utilizes information of (i) sound frequency sweeping, (ii) location, and (iii) coordination, of the emitter, of the sensor, of the at least one other emitter, and/or of the at least one sensor. In some embodiments, coordination comprises coordination of sound emission times, or coordination of sound sensing times.

In another aspect, a non-transitory computer readable media for acoustic mapping, the non-transitory computer readable media, when read by one or more processors, is configured to execute operations comprises: (A) using, or direct usage of, an emitter to emit an acoustic test signal, which emitter is disposed in a first location in an enclosure; (B) using, or direct usage of, a sensor to measure an acoustic response corresponding to the acoustic test signal, which sensor is disposed in a second location; and (C) using, or direct usage of, information pertaining to an inanimate alteration to generate an acoustic map indicative of an acoustic transfer function between the first location and the second location, which inanimate alteration is projected to affect the acoustic mapping of the enclosure.

In some embodiments, the emitter is included in a device ensemble housing that includes at least one sensor and/or at least one emitter. In some embodiments, the emitter is operatively coupled to a control system. In some embodiments, the operations further comprise controlling, or directing control of, at least one apparatus in the enclosure and/or in a facility in which the enclosure is disposed, which control is by the control system. In some embodiments, the at least one apparatus comprises a lighting device, a tintable window, another sensor, another emitter, a media display, a dispenser, a processor, a power source, a security system, a fire alarm system, a sound media, a heater, a cooler, a vent, or a heating ventilation and air conditioning system (HVAC). In some embodiments, the control system comprises a hierarchy of controllers. In some embodiments, the emitter is operatively coupled to a network. In some embodiments, the sensor is communicatively coupled to a network in a wired and/or wireless manner. In some embodiments, the emitter and/or the sensor are communicatively coupled to a network in a wired and/or wireless manner. In some embodiments, the network is configured to transmit power and/or data. In some embodiments, the network is configured to transit broadband cellular network technology communication of at least a third generation, fourth generation, or fifth generation cellular communication protocol. In some embodiments, the network is operatively coupled to a router, multiplier, antenna, and/or transceiver. In some embodiments, the network is disposed at least in an envelope of the enclosure and/or a building in which the enclosure is disposed. In some embodiments, the emitter comprises a buzzer. In some embodiments, the operations further comprise using, or directing usage of the emitter to emit sounds including discrete sounds of a sound spectrum. In some embodiments, the operations further comprise using, or directing usage of, the sensor to sense sounds including discrete sounds of a sound spectrum. In some embodiments, the operations further comprise using, or directing usage of, the emitter to emit sounds including sounds having a spectrum frequency from about 10 Hz to about 20 kHz. In some embodiments, the operations further comprise using, or directing usage of, the emitter to emit the first acoustic test signal and/or the second acoustic test signal according to a schedule. In some embodiments, the operations further comprise using, or directing usage of, the emitter to emit the first acoustic test signal and/or the second acoustic test signal when the enclosure is non-inhabited. In some embodiments, the operations further comprise using, or directing usage of, the emitter to emit the first acoustic test signal and/or the second acoustic test signal outside standard work hours in the enclosure and/or in a facility in which the enclosure is disposed. In some embodiments, the operations further comprise using, or directing usage of, the emitter to emit the second acoustic test signal according to a schedule that considers a change in a Building Information Modeling file of the enclosure and/or of the facility in which the enclosure is disposed. In some embodiments, the enclosure is at least part of a building, or a vehicle. In some embodiments, the enclosure comprises a room. In some embodiments, the enclosure is configured for one or more occupants. In some embodiments, the emitter is a first emitter, and wherein the operations further comprise using, or directing usage of, a second emitter disposed at a third location to emit at least one other acoustic test signal. In some embodiments, the third location is different from the first location and from the second location. In some embodiments, one or more of the locations is disposed in the enclosure. In some embodiments, one or more of the locations is disposed outside the enclosure. In some embodiments, generation of the acoustic map comprises the operation of utilizing sensor measurements responsive to the at least one other acoustic test signal. In some embodiments, the second location is in the enclosure. In some embodiments, the second location is outside of the enclosure. In some embodiments, the sensor is a first sensor, and wherein the operations further comprise using, or directing usage of, a second sensor to measure at least one other acoustic response corresponding to the first acoustic test signal, which second sensor is disposed at a third location different from the second location. In some embodiments, the third location is different from the first location. In some embodiments, one or more of the locations is disposed in the enclosure. In some embodiments, one or more of the locations is disposed outside the enclosure. In some embodiments, generation of the acoustic map comprises the operation of utilizing measurements of the second sensor. In some embodiments, the second sensor is at least two other sensors. In some embodiments, the second location differs from the third location horizontally and/or vertically. In some embodiments, the operations further comprise generating, or directing generation of, a second acoustic mapping at a second time after the inanimate alteration to detect the alteration in the acoustic transfer function. In some embodiments, the information is based at least in part on a Building Information Modeling file. In some embodiments, the information comprises a shape, or a material property of the one or more fixtures. In some embodiments, the inanimate alteration is of one or more fixtures and/or non-fixtures. In some embodiments, the alteration comprises an alteration in the enclosure. In some embodiments, the alteration comprises an alteration out of the enclosure. In some embodiments, the fixture comprises a wall, a window, a shelf, a lighting, or a door. In some embodiments, the non-fixtures comprise a desk, or a chair. In some embodiments, the inanimate alteration is of an inanimate object. In some embodiments, the operations further comprise storing, or directing storage of, the first acoustic map in a memory disposed in the enclosure, and/or in a building in which the enclosure is disposed. In some embodiments, the operations further comprise storing, or directing storage of, the first acoustic map in a memory disposed outside of the enclosure and/or outside of a building in which the enclosure is disposed. In some embodiments, storage of the first acoustic map comprises an operation of utilizing a network to which the sensor and emitter are coupled to. In some embodiments, the first acoustic map and/or the second acoustic map is generated by a processor of the one or more processors; which processor is included in, or is operatively coupled to, a control system. In some embodiments, the acoustic map is generated by a processor of the one or more processors; which processor is included in, or is operatively coupled to, a network to which the sensor and emitter are coupled to. In some embodiments, generation of the acoustic map further comprises the operation of utilizing, or directing utilization of, a Building Information Modeling file of the enclosure and/or of the facility in which the enclosure is disposed. In some embodiments, the first acoustic map is generated within at most about a day, 8 h, 4 h, 2 h, or 1 h. In some embodiments, the operations further comprise generation, or directing generation of, of the acoustic map utilizing information of (i) sound frequency sweeping, (ii) location, and (iii) coordination, of the emitter, of the sensor, of the at least one other emitter, and/or of the at least one sensor. In some embodiments, coordination comprises coordination of sound emission times, and/or coordination of sound sensing times.

In another aspect, an apparatus for acoustic mapping, the apparatus comprises at least one controller comprising circuitry, which at least one controller is configured to: (A) operatively couple to an emitter and to a sensor, (B) direct the emitter to emit an acoustic test signal, which emitter is disposed in a first location in an enclosure; (C) direct the sensor to measure an acoustic response corresponding to the acoustic test signal, which sensor is disposed in a second location; and (D) use, or direct usage of, information pertaining to an inanimate alteration to generate an acoustic map indicative of an acoustic transfer function between the first location and the second location, which inanimate alteration is projected to affect the acoustic mapping of the enclosure.

In some embodiments, the apparatus further comprises a device ensemble housing devices that include at least one sensor and/or at least one emitter, wherein the emitter is included in the device ensemble. In some embodiments, the emitter is operatively coupled to a control system. In some embodiments, the at least one controller is included, or is operatively coupled to, the control system. In some embodiments, the at least one controller is configured to control at least one apparatus in the enclosure and/or in a facility in which the enclosure is disposed, which controlling is by the control system. In some embodiments, the at least one apparatus comprises a lighting device, a tintable window, another sensor, another emitter, a media display, a dispenser, a processor, a power source, a security system, a fire alarm system, a sound media, a heater, a cooler, a vent, or a heating ventilation and air conditioning system (HVAC). In some embodiments, the control system comprises a hierarchy of controllers. In some embodiments, the emitter is operatively coupled to a network in a wired and/or wireless manner. In some embodiments, the sensor is communicatively coupled to a network in a wired and/or wireless manner. In some embodiments, the emitter and/or the sensor are communicatively coupled to a network in a wired and/or wireless manner. In some embodiments, the network is configured to transmit power and/or data. In some embodiments, the network is configured to transit broadband cellular network technology communication of at least a third generation, fourth generation, or fifth generation cellular communication protocol. In some embodiments, the network is operatively coupled to a router, multiplier, antenna, and/or transceiver. In some embodiments, the network is disposed at least in an envelope of the enclosure and/or a building in which the enclosure is disposed. In some embodiments, the emitter comprises a buzzer. In some embodiments, the at least one controller is configured to use, or direct usage of, the emitter to emit sounds including discrete sounds of a sound spectrum. In some embodiments, the at least one controller is configured to use, or direct usage of, the sensor to sense sounds including discrete sounds of a sound spectrum. In some embodiments, the at least one controller is configured to use, or direct usage of, the emitter to emit sounds including sounds having a spectrum frequency from about 10 Hz to about 20 kHz. In some embodiments, the at least one controller is configured to use, or direct usage of, the emitter to emit the first acoustic test signal and/or the second acoustic test signal according to a schedule. In some embodiments, the at least one controller is configured to use, or direct usage of, the emitter to emit the first acoustic test signal and/or the second acoustic test signal when the enclosure is non-inhabited. In some embodiments, the at least one controller is configured to use, or direct usage of, the emitter to emit the first acoustic test signal and/or the second acoustic test signal outside standard work hours in the enclosure and/or in a facility in which the enclosure is disposed. In some embodiments, the at least one controller is configured to use, or direct usage of, the emitter to emit the second acoustic test signal according to a schedule that considers a change in a Building Information Modeling file of the enclosure and/or of the facility in which the enclosure is disposed. In some embodiments, the enclosure is at least part of a building, or a vehicle. In some embodiments, the enclosure comprises a room. In some embodiments, the enclosure is configured for one or more occupants. In some embodiments, the emitter is a first emitter, and wherein the method further comprises using a second emitter disposed at a third location to emit at least one other acoustic test signal. In some embodiments, the third location is different from the first location and from the second location. In some embodiments, one or more of the locations is disposed in the enclosure. In some embodiments, one or more of the locations is disposed outside the enclosure. In some embodiments, the at least one controller is configured to generate the acoustic map utilizing sensor measurements responsive to the at least one other acoustic test signal. In some embodiments, the second location is in the enclosure. In some embodiments, the second location is outside of the enclosure. In some embodiments, the sensor is a first sensor, and wherein the at least one controller is configured to use a second sensor to measure at least one other acoustic response corresponding to the first acoustic test signal, which second sensor is disposed at a third location different from the second location. In some embodiments, the third location is different from the first location. In some embodiments, one or more of the locations is disposed in the enclosure. In some embodiments, one or more of the locations is disposed outside the enclosure. In some embodiments, the at least one controller is configured to generate, or direct generation of, the acoustic map utilizing measurements of the second sensor. In some embodiments, the second sensor is at least two other sensors. In some embodiments, the second location differs from the third location horizontally and/or vertically. In some embodiments, the at least one controller is configured to generate, or direct generation of, a second acoustic mapping at a second time after the inanimate alteration to detect the alteration in the acoustic transfer function. In some embodiments, the information is based at least in part on a Building Information Modeling file. In some embodiments, the information comprises a shape, or a material property of the one or more fixtures. In some embodiments, the inanimate alteration is of one or more fixtures and/or non-fixtures. In some embodiments, the alteration comprises an alteration in the enclosure. In some embodiments, the alteration comprises an alteration out of the enclosure. In some embodiments, the fixture comprises a wall, a window, a shelf, a lighting, or a door. In some embodiments, the non-fixtures comprise a desk, or a chair. In some embodiments, the inanimate alteration is of an inanimate object. In some embodiments, the at least one controller is configured to store the first acoustic map in a memory disposed in the enclosure, and/or in a building in which the enclosure is disposed. In some embodiments, the at least one controller is configured to store, or direct storage of, the first acoustic map in a memory disposed outside of the enclosure and/or outside of a building in which the enclosure is disposed. In some embodiments, the at least one controller is configured to store, or direct storage of, the first acoustic map in a network to which the sensor and emitter are coupled to. In some embodiments, the first acoustic map and/or the second acoustic map is generated by a processor that is part of, or is operatively coupled to, a control system. In some embodiments, the at least one controller is part of, or is operatively coupled to, a control system. In some embodiments, the acoustic map is generated by a processor and/or a controller that is part of, or is operatively coupled to, a network to which the sensor and emitter are coupled to. In some embodiments, the at least one controller is configured to generate, or direct generation of, the acoustic map utilizing a Building Information Modeling file of the enclosure and/or of the facility in which the enclosure is disposed. In some embodiments, the at least one controller is configured to generate, or direct generation of, the first acoustic map within at most about a day, 8 h, 4 h, 2 h, or 1 h. In some embodiments, the at least one controller is configured to generate, or direct generation of, the acoustic map utilizing information of (i) sound frequency sweeping, (ii) location, and (iii) coordination, of the emitter, of the sensor, of the at least one other emitter, and/or of the at least one sensor. In some embodiments, coordination comprises the at least one controller being configured to coordinate, or direct coordination of, sound emission times, or coordinate sound sensing times.

In another aspect, a method of acoustic mapping, the method comprises: (A) sensing a present sound event in an enclosure by using a plurality of sensors; (B) comparing the present sound event sensed by the plurality of sensors to historic sensed data by the plurality of sensors to generate a result; (C) using the result to determine any irregular sound event in the enclosure by comparing to a threshold; and (D) compensating for the irregular sound event according to a corresponding acoustic transfer function of the enclosure, which transfer function is determined utilizing at least one sensor of the plurality of sensors.

In some embodiments, the method further comprises localizing an origination of the irregular sound event based at least in part on relative magnitudes of the detected irregular sound event sensed by at least two, or by at least three of the plurality of sensors. In some embodiments, the method further comprises recognizing an event type of the irregular sound event, and generating a notification of the event type to a user. In some embodiments, recognizing the event type includes using machine learning to determine an identifying signature of the irregular sound event. In some embodiments, the recognized event type is associated with anticipated recurring sounds, and wherein the method further comprises preemptively adjusting acoustic properties in the enclosure to obtain an acoustic transfer function that mitigates effects of the anticipated recurring sounds. In some embodiments, the sound event comprises a gathering such as a meeting, a conference, or a party. In some embodiments, the sound event comprises a gun shot, earthquake, strong wind, or a cry. In some embodiments, the strong wind comprises tornado, hurricane, or tsunami initiated wind. In some embodiments, the event type comprises a safety event, a health event, and/or a security event. In some embodiments, the notification comprises an event category, a subtype, or an event location. In some embodiments, the event category comprises a gunshot and the subtype comprises a type of gun. In some embodiments, the event category comprises a cough and the subtype comprises a suspected type of a cough. In some embodiments, the event category comprises a weather phenomenon. In some embodiments, the threshold is comprised of a value. In some embodiments, the threshold is comprised of a function. In some embodiments, the function is a time dependent function. In some embodiments, the compensation is done in real time during the present sound event. In some embodiments, the compensation is automatic. In some embodiments, the compensation utilizes one or more acoustic modification devices operatively coupled to a network to which the plurality of sensors are operatively coupled to. In some embodiments, the acoustic modification devices comprise at least one sound emitter, sound dampener, actuator, lever, and/or vent. In some embodiments, the network is operatively coupled to a control system. In some embodiments, the control system comprises a hierarchy of controllers. In some embodiments, the acoustic transfer function is determined utilizing at least one emitter, the method further comprises: (E) using the emitter to emit an acoustic test signal, which emitter is disposed at a first location in the enclosure; (F) using the one sensor to measure an acoustic response corresponding to the acoustic test signal, which one sensor is disposed at a second location; and (G) storing an acoustic map indicative of the acoustic transfer function between the first location and the second location. In some embodiments, the emitter comprises a buzzer. In some embodiments, the method further comprises using the emitter to emit sounds including discrete sounds of a sound spectrum. In some embodiments, the at least one sensor is configured to detect sounds including continuous sounds of a sound spectrum. In some embodiments, the method further comprises using the emitter to emit sounds including sounds of a sound having a spectrum frequency of from about 10 Hz to about 20 kHz. In some embodiments, the method further comprises using the emitter to emit the acoustic test signal according to a schedule. In some embodiments, the method further comprises using the emitter to emit the acoustic test signal when the enclosure is non-inhabited. In some embodiments, the method further comprises using the emitter to emit the acoustic test signal outside standard work hours in the enclosure and/or in a facility in which the enclosure is disposed. In some embodiments, the method further comprises using the emitter to emit the acoustic test signal when the enclosure is forecasted to experience a quiet period of a length that is at least sufficient to generate the acoustic map. In some embodiments, the method further comprises using the emitter to emit the acoustic test signal according to a schedule that considers a change in a fixture of the enclosure and/or of the facility in which the enclosure is disposed. In some embodiments, the method further comprises using the emitter to emit the acoustic test signal according to a schedule that considers a change in a Building Information Modeling file of the enclosure and/or of the facility in which the enclosure is disposed. In some embodiments, the enclosure is at least part of a building, or a vehicle.

In another aspect, a non-transitory computer readable media for acoustic mapping, the non-transitory computer readable media, when read by one or more processors, is configured to execute operations comprises: (A) using, or direct usage of, a plurality of sensors to sense a present sound event in an enclosure; (B) comparing, or direct comparison of, the present sound event sensed by the plurality of sensors to historic sensed data by the plurality of sensors to generate a result; (C) using, or direct usage of, the result to determine any irregular sound event in the enclosure by comparing to a threshold; and (D) compensating, or direct compensation, for the irregular sound event according to a corresponding acoustic transfer function of the enclosure, which transfer function is determined utilizing at least the one sensor of the plurality of sensors.

In some embodiments, the operations comprise localizing an origination of the irregular sound event based at least in part on relative magnitudes of the detected irregular sound event sensed by at least two, or by at least three of the plurality of sensors. In some embodiments, the operations comprise recognizing, or directing recognition of, an event type of the irregular sound event, and (i) generating a notification of the event type to a user or (ii) directing generation of a notification of the event type to a user. In some embodiments, the operation of recognizing, or directing recognition of, the event type includes using machine learning to determine an identifying signature of the irregular sound event. In some embodiments, recognition of the event type is associated with anticipated recurring sounds, and wherein the operations further comprise preemptively adjusting, or directing adjustment of, acoustic properties in the enclosure to obtain an acoustic transfer function that mitigates effects of the anticipated recurring sounds. In some embodiments, the sound event comprises a gathering such as a meeting, a conference, or a party. In some embodiments, the sound event comprises a gun shot, earthquake, strong wind, or a cry. In some embodiments, the strong wind comprises a hurricane, a tornado, or a tsunami initiated wind. In some embodiments, the event type comprises a safety event, a health event, and/or a security event. In some embodiments, the notification comprises an event category, a subtype, or an event location. In some embodiments, the event category comprises a gunshot and the subtype comprises a type of gun. In some embodiments, the event category comprises a cough and the subtype comprises a suspected type of a cough. In some embodiments, the event category comprises a weather phenomenon. In some embodiments, the threshold is comprised of a value. In some embodiments, the threshold is comprised of a function. In some embodiments, the function is a time dependent function. In some embodiments, the compensation is done in real time during the present sound event. In some embodiments, the compensation is automatic. In some embodiments, the operation of compensation utilizes one or more acoustic modification devices operatively coupled to a network to which the plurality of sensors are operatively coupled to. In some embodiments, the operation of acoustic modification devices comprises adjusting at least one sound emitter, sound dampener, actuator, lever, and/or vent. In some embodiments, the network is operatively coupled to a control system. In some embodiments, the control system comprises a hierarchy of controllers. In some embodiments, the one or more processors are operatively coupled to, or are included in, the control system. In some embodiments, the acoustic transfer function is determined utilizing at least one emitter, wherein the operations further comprise: (E) using the emitter to emit an acoustic test signal, which emitter is disposed at a first location in the enclosure; (F) using the one sensor to measure an acoustic response corresponding to the acoustic test signal, which one sensor is disposed at a second location; and (G) storing an acoustic map indicative of the acoustic transfer function between the first location and the second location. In some embodiments, the emitter comprises a buzzer. In some embodiments, the operations further comprise using, or directing usage of, the emitter to emit sounds including discrete sounds of a sound spectrum. In some embodiments, the at least one sensor is configured to detect sounds including continuous sounds of a sound spectrum. In some embodiments, the operations further comprise using, or directing usage of, the emitter to emit sounds including sounds of a sound having a spectrum frequency of from about 10 Hz to about 20 kHz. In some embodiments, the operations further comprise using, or directing usage of, the emitter to emit the acoustic test signal according to a schedule. In some embodiments, the operations further comprise using, or directing usage of, the emitter to emit the acoustic test signal when the enclosure is non-inhabited. In some embodiments, the operations further comprise using, or directing usage of, the emitter to emit the acoustic test signal outside standard work hours in the enclosure and/or in a facility in which the enclosure is disposed. In some embodiments, the operations further comprise using, or directing usage of the emitter to emit the acoustic test signal when the enclosure is forecasted to experience a quiet period of a length that is at least sufficient to generate the acoustic map. In some embodiments, the operations further comprise using, or directing usage of, the emitter to emit the acoustic test signal according to a schedule that considers a change in a fixture of the enclosure and/or of the facility in which the enclosure is disposed. In some embodiments, the operations further comprise using, or directing usage of, the emitter to emit the acoustic test signal according to a schedule that considers a change in a Building Information Modeling file of the enclosure and/or of the facility in which the enclosure is disposed. In some embodiments, the enclosure is at least part of a building, or a vehicle.

In another aspect, an apparatus for acoustic mapping, the apparatus comprises at least one controller comprising circuitry, which at least one controller is configured to: (A) operatively couple to a plurality of sensors; (B) direct a plurality of sensors to sense a present sound event in an enclosure; (C) compare, or direct comparison of, the present sound event sensed by the plurality of sensors to historic sensed data by the plurality of sensors to generate a result; (D) use, or direct the use of, the result to determine any irregular sound event in the enclosure by comparing to a threshold; and (E) compensate, or direct compensation, for the irregular sound event according to a corresponding acoustic transfer function of the enclosure, which transfer function is determined utilizing at least the one sensor of the plurality of sensors.

In some embodiments, the at least one controller is configured to localize an origination of the irregular sound event based at least in part on relative magnitudes of the irregular sound event sensed by at least two, or at least three of the plurality of sensors. In some embodiments, the at least one controller is configured to recognize an event type of the irregular sound event, and to (i) generate a notification of the event type to a user or (ii) direct generation of a notification of the event type to a user. In some embodiments, the at least one controller is configured to recognize, or direct recognition of, the event type by use of machine learning to determine an identifying signature of the irregular sound event. In some embodiments, the at least one controller is configured to recognize, or direct recognition of, the event type associated with anticipated recurring sounds, and wherein the at least one controller is configured to preemptively adjust, or direct adjustment of, one or more acoustic properties in the enclosure to obtain an acoustic transfer function that mitigates effects of the anticipated recurring sounds. In some embodiments, the sound event comprises a gathering such as a meeting, a conference, or a party. In some embodiments, the sound event comprises a gun shot, earthquake, strong wind, or a cry. In some embodiments, the strong wind comprises hurricane, tornado, or tsunami initiated wind. In some embodiments, the event type comprises a safety event, a health event, and/or a security event. In some embodiments, the notification comprises an event category, a subtype, or an event location. In some embodiments, the event category comprises a gunshot and the subtype comprises a type of gun. In some embodiments, the event category comprises a cough and the subtype comprises a suspected type of a cough. In some embodiments, the event category comprises a weather phenomenon. In some embodiments, the threshold is comprised of a value. In some embodiments, the threshold is comprised of a function. In some embodiments, the function is a time dependent function. In some embodiments, the at least one controller is configured to compensate in real time during the present sound event. In some embodiments, the compensation is automatic. In some embodiments, the at least one controller is configured to compensate, or direct compensation, by the use of one or more acoustic modification devices operatively coupled to a network to which the plurality of sensors are operatively coupled to. In some embodiments, the at least one controller is configured to adjust, or direct adjustment of, at least one sound emitter, sound dampener, actuator, lever, and/or vent. In some embodiments, the network is operatively coupled to a control system. In some embodiments, the control system comprises a hierarchy of controllers. In some embodiments, the control system is operatively coupled to, or includes, the at least one controller. In some embodiments, the at least one controller is configured to determine the acoustic transfer function by use of at least one emitter, wherein the at least one controller is further configured to: (E) use the emitter to emit an acoustic test signal, which emitter is disposed at a first location in the enclosure; (F) use the one sensor to measure an acoustic response corresponding to the acoustic test signal, which one sensor is disposed at a second location; and (G) store an acoustic map indicative of the acoustic transfer function between the first location and the second location. In some embodiments, the emitter comprises a buzzer. In some embodiments, the at least one controller is configured to use, or direct usage of, the emitter to emit sounds including discrete sounds of a sound spectrum. In some embodiments, the at least one controller is configured to use, or direct usage of, the at least one sensor to detect sounds including continuous sounds of a sound spectrum. In some embodiments, the at least one controller is configured to use, or direct usage of, the emitter to emit sounds including sounds of a sound having a spectrum frequency of from about 10 Hz to about 20 kHz. In some embodiments, the at least one controller is configured to use, or direct usage of, the emitter to emit the acoustic test signal according to a schedule. In some embodiments, the at least one controller is configured to use, or direct usage of, the emitter to emit the acoustic test signal when the enclosure is non-inhabited. In some embodiments, the at least one controller is configured to use, or direct usage of, the emitter to emit the acoustic test signal outside standard work hours in the enclosure and/or in a facility in which the enclosure is disposed. In some embodiments, the at least one controller is configured to use, or direct usage of, the emitter to emit the acoustic test signal when the enclosure is forecasted to experience a quiet period of a length that is at least sufficient to generate the acoustic map. In some embodiments, the at least one controller is configured to use, or direct usage of, the emitter to emit the acoustic test signal according to a schedule that considers a change in a fixture of the enclosure and/or of the facility in which the enclosure is disposed. In some embodiments, the at least one controller is configured to use, or direct usage of, the emitter to emit the acoustic test signal according to a schedule that considers a change in a Building Information Modeling file of the enclosure and/or of the facility in which the enclosure is disposed. In some embodiments, the enclosure is at least part of a building, or a vehicle.

In another aspect, an apparatus for acoustic (e.g., sound) conditioning (in a facility), the apparatus comprises at least one controller configured to: (i) operatively couple to at least one sounds sensor disposed in a facility; (ii) direct the at least sound sensor to collect sound measurements over a first time; and (iii) use, or direct usage of, the sound measurements to condition the sound in at least a portion of the facility at a second time after the first time.

In some embodiments, the at least one controller is configured to user, or direct usage of the sound measurements at least in part by using artificial intelligence, wherein the artificial intelligence optionally comprises machine learning. In some embodiments, the artificial intelligence is using a learning set comprising (i) historical sound measurements in the facility, (ii) historical sound measurements in another facility, or (iii) synthesized sounds measurements. In some embodiments, the artificial intelligence is based at least in part on artificial intelligence computational schemes. In some embodiments, at least one of the artificial intelligence computational schemes has a weight different than at least one other of the artificial intelligence computational schemes. In some embodiments, the at least one controller is configured to damp, or direct damping of, sound in the facility, and optionally wherein the at least one controller is configured to damp, or direct damping of, sound in the at least the portion of the facility. In some embodiments, the at least one controller is configured to damp, or direct damping of, sound in the facility at least in part by being configured to direct vibrating at least one window of the facility, and wherein the window is optionally disposed in the at least the portion of the facility. In some embodiments, the at least one controller is configured to damp, or direct damping of, sound in the facility at least in part by being configured to direct imposing a passive and/or an active damping aid. In some embodiments, the at least one controller is configured to use, or direct usage of the sound measurements at least in part by using measurements of at least one other sensor. In some embodiments, the at least one sounds sensor is disposed in a first enclosure of the facility, and wherein the at least one other sensor is disposed in the first enclosure. In some embodiments, the at least one sounds sensor is disposed in a first enclosure of the facility, and wherein the at least one other sensor is disposed in a second enclosure of the facility different from the first enclosure. In some embodiments, the at least one sounds sensor is disposed in a first enclosure of the facility, and wherein the at least one other sensor is disposed in a second enclosure of the facility different from the first enclosure. In some embodiments, the at least one sounds sensor is disposed in a first enclosure of the facility, and wherein the at least one other sensor comprises a first sensor and a second sensor, and wherein the first sensor is disposed in the first enclosure, and wherein the second sensor is disposed in a second enclosure of the facility different from the first enclosure. In some embodiments, the at least one other sensor is of the same type as the at least one sound sensor. In some embodiments, the at least one other sensor is of a different type as the at least one sound sensor. In some embodiments, the at least one controller is configured to use, or direct usage of, (i) measurements of the at least one sounds sensor and (ii) measurements of the at least one other sensor synergistically and/or symbiotically. In some embodiments, the at least one controller is configured to use, or direct usage of, (i) measurements of the at least one sounds sensor based and (ii) measurements of the at least one other sensor. In some embodiments, the at least one other sensor is configured to measure an attribute comprising: temperature, electromagnetic radiation, pressure, gas, volatile organic compounds, particulate matter, or movement. In some embodiments, the gas comprises carbon dioxide, carbon monoxide, nitrogen monoxide, nitrogen dioxide, radon, phosgene, oregano halogens, halogen, formaldehyde, or water. In some embodiments, the at least one other sensor is configured to measure color temperature. In some embodiments, the at least one other sensor is configured to measure an attribute comprising: gas type, gas velocity, gas pressure, or gas concentration. In some embodiments, the at least one other sensor is configured to measure an attribute comprising: electromagnetic radiation wavelength, electromagnetic radiation wavelength phase, electromagnetic radiation frequency, or electromagnetic radiation amplitude. In some embodiments, the at least one other sensor is configured to measure an attribute comprising: visible, infrared, ultraviolet, or radio frequency. In some embodiments, the radio frequency comprises ultrawide bandwidth. In some embodiments, the at least one other sensor comprises an accelerometer. In some embodiments, at least one sounds sensor comprises a sensor disposed in a device ensemble. In some embodiments, (A) the device ensemble comprises (i) sensors, (ii) a sensor and an emitter, or (iii) a sensor and a transceiver, and/or (B) the device ensemble is disposed in, or attached to, a fixture of the facility. In some embodiments, at least one other sensor comprises a sensor disposed in a device ensemble. In some embodiments, (A) the device ensemble comprises (i) sensors, (ii) a sensor and an emitter, or (iii) a sensor and a transceiver, and/or (B) the device ensemble is disposed in, or attached to, a fixture of the facility. In some embodiments, the at least one controller is configured to generate, or direct generation of, sound mapping of at least a portion of the facility. In some embodiments, the at least one controller is configured to damp, or direct damping of, sound in at least a portion of the facility in an intermittent basis, or on a continuous basis. In some embodiments, the intermittent basis is based at least in part on activity scheduling in the at least the portion of the facility, and/or on a detected activity in the at least the portion of the facility. In some embodiments, the at least one controller comprises circuitry, memory, and/or control logic. In some embodiments, the at least one controller comprises a hierarchical control system comprising at least three levels of hierarchy.

In another aspect, a non-transitory computer readable program instructions for acoustic (e.g., sound) conditioning (in a facility), the non-transitory computer readable program instructions, when read by one or more processors operatively coupled to the at least one sound sensor, cause the one or more processors to execute, or direct execution of, operations comprising any operation the apparatus disclosed above.

In some embodiments, the one or more processors include: a processor disposed in a fixture of the facility, a processor disposed in an envelope of the facility, and/or a processor as part of a controller. In some embodiments, the one or more processors include: a microprocessors, or a graphical processing unit.

In another aspect, a method of acoustic (e.g., sound) conditioning (in a facility), the method comprising any operation of the apparatus disclosed above.

In another aspect, a system for acoustic (e.g., sound) conditioning (in a facility), the system comprises a network configured to operatively couple to the at least one sounds sensor, the network further configured to transmit one or more signals associates with any operation of the apparatus disclosed above.

In some embodiments, the network is configured to transmit a control automation protocol. In some embodiments, the network is configured to transmit power and communication on a single cable. In some embodiments, the network is configured to transmit cellular communication abiding by at least a fourth generation and/or a fifth generation cellular communication protocol. In some embodiments, the network is configured to transmit control communication, cellular communication, media, and/or other data. In some embodiments, the network is operatively coupled to one or more devices comprising: a sensor, an emitter, a controller, a communication interface, a power supply, controlled entrances, lighting, memory, ventilation system, heating system, cooling system, or a heating cooling and ventilation (HVAC) system. In some embodiments, the network is configured to facilitate conditioning the environment of the at least the portion of the facility. In some embodiments, the network is configured (i) to allow entry of authorized users and/or (ii) block entry of unauthorized users. In some embodiments, the network is configured as a secure network.

In another aspect, an apparatus for sound conditioning, the apparatus comprises a compartment housing an ensemble of devices comprising (A) the at least one sound sensor and (B) (i) a sensor of a different type, (ii) an emitter, or (iii) a transceiver, which device ensemble is configured to facilitate any operation of the apparatus disclosed above.

In some embodiments, the housing comprises at least one circuitry board having at least one circuitry operatively coupled to the devices. In some embodiments, the devices are configured to operatively coupled to a power and/or communication network. In some embodiments, the devices are configured for synergetic and/or symbiotic collaboration in controlling the facility. In some embodiments, the devices comprise a communication interface, an accelerometers, a graphical processing unit, a heat sink, a microcontroller, geolocation technology. In some embodiments, the compartment comprises one or more holes configured to facilitate operations of at least a portion of the devices disposed in the compartment. In some embodiments, the compartment comprises a body and a lid comprising the one or more holes.

In some examples, one or more devices (e.g., housed in a device ensemble such as a Digital Architectural Element) may include windows. In some examples, the one or more devices may include a controller configured to control functions of at least one of the windows.

In some examples, the one or more devices may include a device selected from the group consisting of an Internet of Things (IoT) device, a wireless device, a sensor, an antenna, a fifth generation communication protocol (5G) compatible device, an Ultra-Wide Band (UWB) device, a millimeter (mm) Wave device, a microphone, a speaker, and a microprocessor. In some examples, the method may (e.g., further) include installing the one or more devices in, or on, a structural element of the enclosure (e.g., building). The network may facilitate communication to, from, and/or inter communication of the devices.

In some examples, forming the network may be performed during construction of the building. In some examples, forming the network may include coupling the circuits to windows of the building.

In some examples, the one or more devices may be selected from the group consisting of Internet of Things (IoT) devices, wireless devices, sensors, antennas, fifth generation communication protocol (5G) compatible devices, microphones, microprocessors, and speakers. In some examples, the one or more devices may be is in, or on, a structure of the building.

In some examples, the one or more devices may include an optically switchable window. In some examples, the optically switchable window may include an electrochromic window. In some examples, the optically switchable window may include a digital display technology.

In another aspect, the present disclosure provides systems, apparatuses (e.g., controllers), and/or non-transitory computer-readable medium (e.g., software) that implement any of the methods disclosed herein.

In some embodiments, the network is a local network. In some embodiments, the network comprises a cable configured to transmit power and communication in a single cable. The communication can be one or more types of communication. The communication can comprise cellular communication abiding by at least a second generation (2G), third generation (3G), fourth generation (4G) or fifth generation (5G) cellular communication protocol. In some embodiments, the communication comprises media communication facilitating stills, music, or moving picture streams (e.g., movies or videos). In some embodiments, the communication comprises data communication (e.g., sensor data). In some embodiments, the communication comprises control communication, e.g., to control the one or more nodes operatively coupled to the networks. In some embodiments, the network comprises a first (e.g., cabling) network installed in the facility. In some embodiments, the network comprises a (e.g., cabling) network installed in an envelope of the facility (e.g., in an envelope of a building included in the facility).

In another aspect, the present disclosure provides systems, apparatuses (e.g., controllers), and/or non-transitory computer-readable medium or media (e.g., software) that implement any of the methods disclosed herein.

In another aspect, the present disclosure provides methods that use any of the systems, computer readable media, and/or apparatuses disclosed herein, e.g., for their intended purpose.

In another aspect, an apparatus comprises at least one controller that is programmed to direct a mechanism used to implement (e.g., effectuate) any of the method disclosed herein, which at least one controller is configured to operatively couple to the mechanism. In some embodiments, at least two operations (e.g., of the method) are directed/executed by the same controller. In some embodiments, at less at two operations are directed/executed by different controllers.

In another aspect, an apparatus comprises at least one controller that is configured (e.g., programmed) to implement (e.g., effectuate) any of the methods disclosed herein. The at least one controller may implement any of the methods disclosed herein. In some embodiments, at least two operations (e.g., of the method) are directed/executed by the same controller. In some embodiments, at less at two operations are directed/executed by different controllers.

In some embodiments, one controller of the at least one controller is configured to perform two or more operations. In some embodiments, two different controllers of the at least one controller are configured to each perform a different operation.

In another aspect, a system comprises at least one controller that is programmed to direct operation of at least one another apparatus (or component thereof), and the apparatus (or component thereof), wherein the at least one controller is operatively coupled to the apparatus (or to the component thereof). The apparatus (or component thereof) may include any apparatus (or component thereof) disclosed herein. The at least one controller may be configured to direct any apparatus (or component thereof) disclosed herein. The at least one controller may be configured to operatively couple to any apparatus (or component thereof) disclosed herein. In some embodiments, at least two operations (e.g., of the apparatus) are directed by the same controller. In some embodiments, at less at two operations are directed by different controllers.

In another aspect, a computer software product (e.g., inscribed on one or more non-transitory medium) in which program instructions are stored, which instructions, when read by at least one processor (e.g., computer), cause the at least one processor to direct a mechanism disclosed herein to implement (e.g., effectuate) any of the method disclosed herein, wherein the at least one processor is configured to operatively couple to the mechanism. The mechanism can comprise any apparatus (or any component thereof) disclosed herein. In some embodiments, at least two operations (e.g., of the apparatus) are directed/executed by the same processor. In some embodiments, at less at two operations are directed/executed by different processors.

In another aspect, the present disclosure provides a non-transitory computer-readable program instructions (e.g., included in a program product comprising one or more non-transitory medium) comprising machine-executable code that, upon execution by one or more processors, implements any of the methods disclosed herein. In some embodiments, at least two operations (e.g., of the method) are directed/executed by the same processor. In some embodiments, at less at two operations are directed/executed by different processors.

In another aspect, the present disclosure provides a non-transitory computer-readable medium or media comprising machine-executable code that, upon execution by one or more processors, effectuates directions of the controller(s) (e.g., as disclosed herein). In some embodiments, at least two operations (e.g., of the controller) are directed/executed by the same processor. In some embodiments, at less at two operations are directed/executed by different processors.

In another aspect, the present disclosure provides a computer system comprising one or more computer processors and a non-transitory computer-readable medium or media coupled thereto. The non-transitory computer-readable medium comprises machine-executable code that, upon execution by the one or more processors, implements any of the methods disclosed herein and/or effectuates directions of the controller(s) disclosed herein.

In another aspect, the present disclosure provides a non-transitory computer readable program instructions that, when read by one or more processors, causes the one or more processors to execute any operation of the methods disclosed herein, any operation performed (or configured to be performed) by the apparatuses disclosed herein, and/or any operation directed (or configured to be directed) by the apparatuses disclosed herein.

In some embodiments, the program instructions are inscribed in a non-transitory computer readable medium or media. In some embodiments, at least two of the operations are executed by one of the one or more processors. In some embodiments, at least two of the operations are each executed by different processors of the one or more processors.

In another aspect, the present disclosure provides networks that are configured for transmission of any communication (e.g., signal) and/or (e.g., electrical) power facilitating any of the operations disclosed herein. The communication may comprise control communication, cellular communication, media communication, and/or data communication. The data communication may comprise sensor data communication and/or processed data communication. The networks may be configured to abide by one or more protocols facilitating such communication. For example, a communications protocol used by the network (e.g., with a BMS) can be a building automation and control networks protocol (BACnet). For example, a communication protocol may facilitate cellular communication abiding by at least a 2nd, 3rd, 4th, or 5th generation cellular communication protocol.

The content of this summary section is provided as a simplified introduction to the disclosure and is not intended to be used to limit the scope of any invention disclosed herein or the scope of the appended claims.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

These and other features and embodiments will be described in more detail with reference to the drawings.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings or figures (also “FIG.” and “FIGS.” herein), of which:

FIG. 1 shows various network linking topologies coupling a network in an enclosure;

FIG. 2 schematically shows a control system architecture;

FIG. 3 schematically shows a control system architecture;

FIG. 4 schematically shows a block diagram showing various devices (e.g., a digital architectural element), and their connectivity to a network.

FIG. 5 shows a schematic architectural diagram depicting an enclosure layout;

FIG. 6 shows a schematic architectural diagram depicting an enclosure layout;

FIGS. 7A-7B schematically show sensors and sound emits with propagating sounds;

FIGS. 8A-8B show plots of time dependent frequency sweeps;

FIGS. 9A-9B show plots of time dependent frequency sweeps;

FIGS. 10A-10B shows plots of sound levels depending on frequency;

FIG. 11 is a flowchart showing a testing operation relating to acoustic mapping;

FIG. 12 is a flowchart showing a fault detection operations;

FIGS. 13A, 13B, and 13C show fault detection matrices;

FIG. 14 is a flowchart showing relating to sound event detection;

FIG. 15 shows a schematic block diagram of an enclosure with sound related components;

FIGS. 16A-16B schematically show block diagrams of control systems;

FIGS. 17, 18, and 19 list digital architectural element features;

FIG. 20 depicts a digital architectural element having various functionalities;

FIG. 21 illustrates a control related flow chart;

FIG. 22 illustrates an example of a suite of functional modules;

FIG. 23 illustrates an example physical representation a digital architectural element and its placement in a framing;

FIG. 24 shows an example of a portion of a data and power distribution system having a digital architectural element (DAE);

FIG. 25 illustrates a DAE that can support a plurality of communication types;

FIG. 26 illustrates a system of components that may be incorporated in or associated with a DAE;

FIG. 27 schematically depicts a processing system;

FIG. 28 schematically shows an electrochromic device;

FIG. 29 schematically shows a cross section of an Integrated Glass Unit (IGU);

FIG. 30 shows various components of a device ensemble; and

FIG. 31 shows a graph of sound measurements as a function of time.

The figures and components therein may not be drawn to scale. Various components of the figures described herein may not be drawn to scale.

### DETAILED DESCRIPTION

The following detailed description is directed to certain embodiments or implementations for the purposes of describing the disclosed aspects. However, the teachings herein can be applied and implemented in a multitude of different ways. In the following detailed description, references are made to the accompanying drawings. Although the disclosed implementations are described in sufficient detail to enable one skilled in the art to practice the implementations, it is to be understood that these examples are not limiting; other implementations may be used and changes may be made to the disclosed implementations without departing from their spirit and scope. Furthermore, while some disclosed embodiments may focus on electrochromic windows, the concepts disclosed herein may apply to other types of switchable optical devices, tintable windows, or smart windows, including, for example, liquid crystal devices and suspended particle devices, among others. For example, a liquid crystal device or a suspended particle device, rather than an electrochromic device, could be incorporated into some or all of the disclosed implementations.

The conjunction “or” is intended herein in the inclusive sense where appropriate unless otherwise indicated; for example, the phrase “A, B or C” is intended to include the possibilities of “A,” “B,” “C,” “A and B,” “B and C,” “A and C,” and “A, B, and C.”

When ranges are mentioned, the ranges are meant to be inclusive, unless otherwise specified. For example, a range between value 1 and value 2 is meant to be inclusive and include value 1 and value 2. The inclusive range will span any value from about value 1 to about value 2. The term “adjacent” or “adjacent to,” as used herein, includes “next to,” “adjoining,” “in contact with,” and “in proximity to.”

As used herein, including in the claims, the conjunction “and/or” in a phrase such as “including X, Y, and/or Z”, refers to in inclusion of any combination or plurality of X, Y, and Z. For example, such phrase is meant to include X. For example, such phrase is meant to include Y. For example, such phrase is meant to include Z. For example, such phrase is meant to include X and Y. For example, such phrase is meant to include X and Z. For example, such phrase is meant to include Y and Z. For example, such phrase is meant to include a plurality of Xs. For example, such phrase is meant to include a plurality of Ys. For example, such phrase is meant to include a plurality of Zs. For example, such phrase is meant to include a plurality of Xs and a plurality of Ys. For example, such phrase is meant to include a plurality of Xs and a plurality of Zs. For example, such phrase is meant to include a plurality of Ys and a plurality of Zs. For example, such phrase is meant to include a plurality of Xs and Y. For example, such phrase is meant to include a plurality of Xs and Z. For example, such phrase is meant to include a plurality of Ys and Z. For example, such phrase is meant to include X and a plurality of Ys. For example, such phrase is meant to include X and a plurality of Zs. For example, such phrase is meant to include Y and a plurality of Zs. The conjunction “and/or” is meant to have the same effect as the phrase “X, Y, Z, or any combination or plurality thereof.” The conjunction “and/or” is meant to have the same effect as the phrase “one or more X, Y, Z, or any combination thereof.”

The term “operatively coupled” or “operatively connected” refers to a first element (e.g., mechanism) that is coupled (e.g., connected) to a second element, to allow the intended operation of the second and/or first element. The coupling may comprise physical or non-physical coupling (e.g., communicative coupling). The non-physical coupling may comprise signal-induced coupling (e.g., wireless coupling). Coupled can include physical coupling (e.g., physically connected), or non-physical coupling (e.g., via wireless communication). Operatively coupled may comprise communicatively coupled.

An element (e.g., mechanism) that is “configured to” perform a function includes a structural feature that causes the element to perform this function. A structural feature may include an electrical feature, such as a circuitry or a circuit element. A structural feature may include an actuator. A structural feature may include a circuitry (e.g., comprising electrical or optical circuitry). Electrical circuitry may comprise one or more wires. Optical circuitry may comprise at least one optical element (e.g., beam splitter, mirror, lens and/or optical fiber). A structural feature may include a mechanical feature. A mechanical feature may comprise a latch, a spring, a closure, a hinge, a chassis, a support, a fastener, or a cantilever, and so forth. Performing the function may comprise utilizing a logical feature. A logical feature may include programming instructions. Programming instructions may be executable by at least one processor. Programming instructions may be stored or encoded on a medium accessible by one or more processors. Additionally, in the following description, the phrases “operable to,” “adapted to,” “configured to,” “designed to,” “programmed to,” or “capable of” may be used interchangeably where appropriate.

In some embodiments, an enclosure comprises an area defined by at least one structure. The at least one structure may comprise at least one wall. An enclosure may comprise and/or enclose one or more sub-enclosure. The at least one wall may comprise metal (e.g., steel), clay, stone, plastic, glass, plaster (e.g., gypsum), polymer (e.g., polyurethane, styrene, or vinyl), asbestos, fiber-glass, concrete (e.g., reinforced concrete), wood, paper, or a ceramic. The at least one wall may comprise wire, bricks, blocks (e.g., cinder blocks), tile, drywall, or frame (e.g., steel frame).

In some embodiments, the enclosure comprises one or more openings. The one or more openings may be reversibly closable. The one or more openings may be permanently open. A fundamental length scale of the one or more openings may be smaller relative to the fundamental length scale of the wall(s) that define the enclosure. A fundamental length scale may comprise a diameter of a bounding circle, a length, a width, or a height. A surface of the one or more openings may be smaller relative to the surface the wall(s) that define the enclosure. The opening surface may be a percentage of the total surface of the wall(s). For example, the opening surface can measure about 30%, 20%, 10%, 5%, or 1% of the walls(s). The wall(s) may comprise a floor, a ceiling, or a side wall. The closable opening may be closed by at least one window or door. The enclosure may be at least a portion of a facility. The facility may comprise a building. The enclosure may comprise at least a portion of a building. The building may be a private building and/or a commercial building. The building may comprise one or more floors. The building (e.g., floor thereof) may include at least one of: a room, hall, foyer, attic, basement, balcony (e.g., inner or outer balcony), stairwell, corridor, elevator shaft, façade, mezzanine, penthouse, garage, porch (e.g., enclosed porch), terrace (e.g., enclosed terrace), cafeteria, and/or Duct. In some embodiments, an enclosure may be stationary and/or movable (e.g., a train, an airplane, a ship, a vehicle, or a rocket). The enclosure may comprise a building such as a multi-story building. The multi-story building may have at least about 2, 8, 10, 25, 50, 80, 100, 120, 140, or 160 floors that are controlled by the control system. The number of controlled by the control system may be any number between the aforementioned numbers (e.g., from 2 to 50, from 25 to 100, or from 80 to 160). The floor may be of an area of at least about 150 m², 250 m², 500 m², 1000 m², 1500 m², or 2000 square meters (m²). The floor may have an area between any of the aforementioned floor area values (e.g., from about 150 m² to about 2000 m², from about 150 m² to about 500 m² from about 250 m² to about 1000 m², or from about 1000 m² to about 2000 m²).

Certain disclosed embodiments provide a network infrastructure in the enclosure (e.g., a facility such as a building). The network infrastructure is available for various purposes such as for providing communication and/or power services. The communication services may comprise high bandwidth (e.g., wireless and/or wired) communications services. The communication services can be to occupants of a facility and/or users outside the facility (e.g., building). The network infrastructure may work in concert with, or as a partial replacement of, the infrastructure of one or more cellular carriers. The network infrastructure can be provided in a facility that includes electrically switchable windows. Examples of components of the network infrastructure include a high speed backhaul. The network infrastructure may include at least one cable, switch, physical antenna, transceivers, sensor, transmitter, receiver, radio, processor and/or controller (that may comprise a processor). The network infrastructure may be operatively coupled to, and/or include a wireless network. The network infrastructure may comprise wiring. One or more sensors can be deployed (e.g., installed) in an environment as part of installing the network and/or after installing the network. The network may be a local network. The network may comprise a cable configured to transmit power and communication in a single cable. The communication can be one or more types of communication. The communication can comprise cellular communication abiding by at least a second generation (2G), third generation (3G), fourth generation (4G) or fifth generation (5G) cellular communication protocol. The communication may comprise media communication facilitating stills, music, or moving picture streams (e.g., movies or videos). The communication may comprise data communication (e.g., sensor data). The communication may comprise control communication, e.g., to control the one or more nodes operatively coupled to the networks. The network may comprise a first (e.g., cabling) network installed in the facility. The network may comprise a (e.g., cabling) network installed in an envelope of the facility (e.g., such as in an envelope of an enclosure of the facility. For example, in an envelope of a building included in the facility).

In another aspect, the present disclosure provides networks that are configured for transmission of any communication (e.g., signal) and/or (e.g., electrical) power facilitating any of the operations disclosed herein. The communication may comprise control communication, cellular communication, media communication, and/or data communication. The data communication may comprise sensor data communication and/or processed data communication. The networks may be configured to abide by one or more protocols facilitating such communication. For example, a communications protocol used by the network (e.g., with a BMS) can comprise a building automation and control networks protocol (BACnet). The network may be configured for (e.g., include hardware facilitating) communication protocols comprising BACnet (e.g., BACnet/SC), LonWorks, Modbus, KNX, European Home Systems Protocol (EHS), BatiBUS, European Installation Bus (EIB or Instabus), zigbee, Z-wave, Insteon, X10, Bluetooth, or WiFi. The network may be configure to transmit the control related protocol. A communication protocol may facilitate cellular communication abiding by at least a 2^{nd}, 3^{rd}, 4^{th} or 5^{th} generation cellular communication protocol. The (e.g., cabling) network may comprise a tree, line, or star topologies. The network may comprise interworking and/or distributed application models for various tasks of the building automation. The control system may provide schemes for configuration and/or management of resources on the network. The network may permit binding of parts of a distributed application in different nodes operatively coupled to the network. The network may provide a communication system with a message protocol and models for the communication stack in each node (capable of hosting distributed applications (e.g., having a common Kernel). The control system may comprise programmable logic controller(s) (PLC(s)).

In various embodiments, a network infrastructure supports a control system for one or more windows such as electrochromic (e.g., tintable) windows. The control system may comprise one or more controllers operatively coupled (e.g., directly or indirectly) to one or more windows. While the disclosed embodiments describe electrochromic windows as one type of referred to herein as “optically switchable windows,” “tintable windows”, or “smart windows”, the concepts disclosed herein may apply to other types of switchable optical devices comprising a liquid crystal device, an electrochromic device, suspended particle device (SPD), NanoChromics display (NCD), Organic electroluminescent display (OELD), suspended particle device (SPD), NanoChromics display (NCD), or an Organic electroluminescent display (OELD). The display element may be attached to a part of a transparent body (such as the windows). The tintable window may be disposed in a (non-transitory) facility such as a building, and/or in a transitory vehicle such as a car, RV, buss, train, airplane, helicopter, ship, or boat.

In some embodiments, a building management system (BMS) is a computer-based control system installed in a building that controls (e.g., monitors) the building's mechanical and electrical equipment such as one or more ventilation, lighting, power system, elevator, fire system, and/or security system. Controllers (e.g., nodes and/or processors) described herein may be suited for integration with a BMS. A BMS may consist of hardware, including interconnections by communication channels to processor(s) (e.g., computer(s)) and/or associated software for maintaining conditions in the building, e.g., according to preferences set by at least one user. The user can be an occupant, an owner, a lessor, and/or a building manager. For example, a BMS may be implemented using a local area network, such as Ethernet. The software can be based at least in part on, for example, internet protocols and/or open standards. One example is software from Tridium, Inc. (of Richmond, Va.). One communication protocol commonly used with a BMS is BACnet (building automation and control networks).

In some embodiments, a BMS is disposed in an enclosure such as a facility. The facility can comprise a building such as a multistory building. The BMS may functions at least to control the environment in the facility (e.g., in the building). The control system and/or BMS may control at least one environmental characteristic of the enclosure. The at least one environmental characteristic may comprise temperature, humidity, fine spray (e.g., aerosol), sound, electromagnetic waves (e.g., light glare, color), gas makeup, gas concentration, gas speed, vibration, volatile compounds (VOCs), debris (e.g., dust), or biological matter (e.g., gas borne bacteria and/or virus). The gas(es) may comprise oxygen, nitrogen, carbon dioxide, carbon monoxide, hydrogen sulfide, nitrogen dioxide, inert gas, Nobel gas (e.g., radon), cholorophore, ozone, formaldehyde, methane, or ethane. For example, a BMS may control temperature, carbon dioxide levels, and/or humidity within an enclosure. Mechanical devices that can be controlled by a BMS and/or control system may comprise lighting, a heater, air conditioner, blower, or vent. To control the enclosure (e.g., building) environment, a BMS and/or control system may adjust (e.g., turn on and off) one or more of the devices it controls, e.g., under defined conditions. A (e.g., core) function of a modern BMS and/or control system may be to maintain a comfortable environment for the occupants of the enclosure, e.g., while minimizing energy consumption (e.g., while minimizing heating and cooling costs/demand). A modern BMS and/or control system can be used to control (e.g., monitor), and/or to optimize the synergy between various systems, for example, to conserve energy and/or lower enclosure (e.g., facility) operation costs.

In some embodiments, the control system is operatively (e.g., communicatively) coupled to an ensemble of devices (e.g., sensors and/or emitters). The ensemble facilitates the control of the environment and/or the alert. The control may utilize a control scheme such as feedback control, or any other control scheme delineated herein. The ensemble may comprise at least one sensor configured to sense electromagnetic radiation. The electromagnetic radiation may be (humanly) visible, infrared (IR), or ultraviolet (UV) radiation. The at least one sensor may comprise an array of sensors. For example, the ensemble may comprise an IR sensor array (e.g., a far infrared thermal array such as the one by Melexis). The IR sensor array may have a resolution of at least 32×24 pixels. The IR sensor may be coupled to a digital interface. The ensemble may comprise an IR camera. The ensemble may comprise a sound detector. The ensemble may comprise a microphone. The ensemble may comprise any sensor and/or emitter disclosed herein. The ensemble may include CO₂, VOC, temperature, humidity, electromagnetic light, pressure, and/or noise sensors. The sensor may comprise a gesture sensor (e.g., RGB gesture sensor), an acetometer, or a sound sensor. The sounds sensor may comprise an audio decibel level detector. The sensor may comprise a meter driver. The ensemble may include a microphone and/or a processor. The ensemble may comprise a camera (e.g., a 4K pixel camera), a ultra wide band (UWB) sensor and/or emitter, a Bluetooth (BLE) sensor and/or emitter, a processor. The camera may have any camera resolution disclosed herein. One or more of the devices (e.g., sensors) can be integrated on a chip. The sensor ensemble may be utilized to determine presence of occupants in an enclosure, their number and/or identity (e.g., using the camera). The sensor ensemble may be utilized to control (e.g., monitor and/or adjust) one or more environmental characteristics in the enclosure environment (e.g., as disclosed herein). The sounds sensor may comprise a microphone. The sounds sensor may comprise an acoustic noise sensor. For example, the sound sensor may comprise a PUI Audio TOM 1545-P-R sensor. The sound sensor may be omnidirectional. The sound sensor may have a sensitivity of at most about −34 dB, −38 dB, −40 dB, −42 dB, −46 dB, —or 48 dB. The sound sensor may require a power supply of at most about 1.0 Volts (V), 1.5V, or 2.0V. The sound sensor may have a FLS of at most about 10 millimeters (mm), 9 mm, 6 mm, or 4 mm. The sounds sensor may have an impedance of at most about 0.1 Kilo Ohms (kOhm), 0.5 kOhm, 1.0 kOhm, 1.5 kOhm, 2.0 kOhm, 2.2 kOhm, 2.5 kOhm, or 3.0 kOhm.

In some embodiments, a plurality of devices may be operatively (e.g., communicatively) coupled to the control system. The plurality of devices may be disposed in a facility (e.g., including a building and/or room). The control system may comprise the hierarchy of controllers. The devices may comprise an emitter, a sensor, or a window (e.g., IGU). The device may be any device as disclosed herein. At least two of the plurality of devices may be of the same type. For example, two or more IGUs may be coupled to the control system. At least two of the plurality of devices may be of different types. For example, a sensor and an emitter may be coupled to the control system. At times the plurality of devices may comprise at least 20, 50, 100, 500, 1000, 2500, 5000, 7500, 10000, 50000, 100000, or 500000 devices. The plurality of devices may be of any number between the aforementioned numbers (e.g., from 20 devices to 500000 devices, from 20 devices to 50 devices, from 50 devices to 500 devices, from 500 devices to 2500 devices, from 1000 devices to 5000 devices, from 5000 devices to 10000 devices, from 10000 devices to 100000 devices, or from 100000 devices to 500000 devices). For example, the number of windows in a floor may be at least 5, 10, 15, 20, 25, 30, 40, or 50. The number of windows in a floor can be any number between the aforementioned numbers (e.g., from 5 to 50, from 5 to 25, or from 25 to 50). At times the devices may be in a multi-story building. At least a portion of the floors of the multi-story building may have devices controlled by the control system (e.g., at least a portion of the floors of the multi-story building may be controlled by the control system). The building may comprise an area of at least about 1000 square feet (sqft), 2000 sqft, 5000 sqft, 10000 sqft, 100000 sqft, 150000 sqft, 200000 sqft, or 500000 sqft. The building may comprise an area between any of the above mentioned areas (e.g., from about 1000 sqft to about 5000 sqft, from about 5000 sqft to about 500000 sqft, or from about 1000 sqft to about 500000 sqft). The building may comprise an area of at least about 100 m², 200 m², 500 m², 1000 m², 5000 m², 10000 m², 25000 m², or 50000 m². The building may comprise an area between any of the above mentioned areas (e.g., from about 100 m² to about 1000 m², from about 500 m² to about 25000 m², from about 100 m² to about 50000 m²). The facility may comprise a commercial or a residential building. The commercial building may include tenant(s) and/or owner(s). The residential facility may comprise a multi or a single family building. The residential facility may comprise an apartment complex. The residential facility may comprise a single family home. The residential facility may comprise multifamily homes (e.g., apartments). The residential facility may comprise townhouses. The facility may comprise residential and commercial portions. The facility may comprise at least about 1, 2, 5, 10, 50, 100, 150, 200, 250, 300, 350, 400, 420, 450, 500, or 550 windows (e.g., tintable windows). The windows may be divided into zones (e.g., based at least in part on the location, façade, floor, ownership, utilization of the enclosure (e.g., room) in which they are disposed, any other assignment metric, random assignment, or any combination thereof. Allocation of windows to the zone may be static or dynamic (e.g., based on a heuristic). There may be at least about 2, 5, 10, 12, 15, 30, 40, or 46 windows per zone.

The window systems and associated components disclosed in these embodiments can facilitate high bandwidth (e.g., gigabit) communication and associated data processing. These communications and data processing may employ optically switchable window systems components and facilitate various window and non-window functions as described herein and in International Patent Application Serial No. PCT/US18/29476, filed Apr. 25, 2018; U.S. Provisional patent application Ser. No. 62/666,033, filed May 2, 2018; and International Patent Application Serial No. PCT/US18/29406, filed Apr. 25, 2018. Some of the optically switchable window system components include components of a communications network and power distribution system for powering window transitions as described in U.S. patent application Ser. No. 15/365,685, filed Nov. 30, 2016.

In some embodiments, the network comprises a communication network. Example components for enhancing functionality of a communications network that serves optically switchable windows may include: (1) a control panel with a high bandwidth switching and/or routing capability (e.g., one gigabit or faster Ethernet switch); (2) a backbone that includes control panels and high bandwidth links (e.g., 10 gigabit or faster Ethernet capability) between the control panels; (3) a digital element (e.g., device ensemble) including sensors, display drivers, and/or logic for various functions that employ high data rate processing. The digital element can be configured as a digital wall interface or a digital architectural element such as a digital mullion insert; (4) an enhanced functionality window controller that includes an access point for wireless communication, e.g., a Wi-Fi access point; and (5) high bandwidth data communication links between the control panels and digital elements and/or enhanced functionality window controllers, the data communication links configured, for example, as trunk lines or to follow paths that at least partially overlap with the paths of trunk lines.

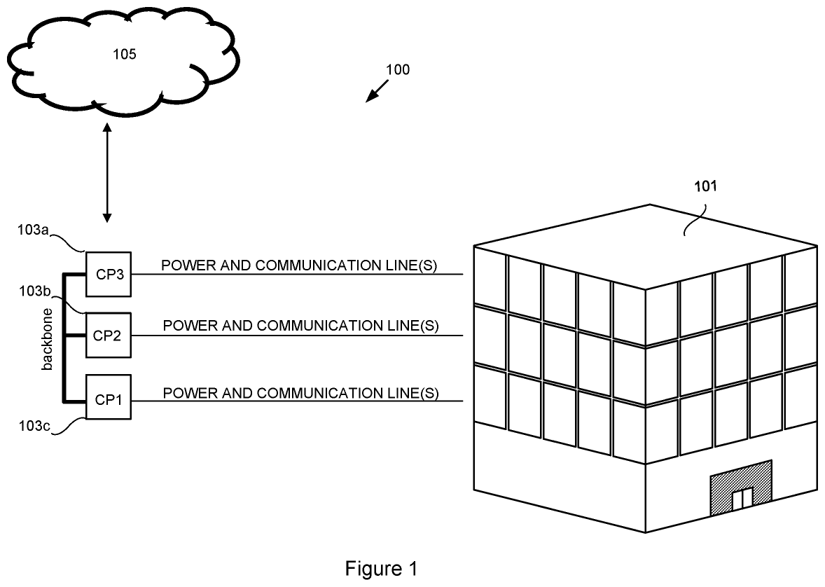

FIG. 1 shows a (e.g., simplified) top level view of a system 100 that includes a building 101 that includes a number of (e.g., EC) windows. A subset of the (e.g., EC) windows is connected by way of (e.g., EC window) power and communications lines to a “Control Panel” (CP) 103a. In the illustrated example, the building's windows are grouped in three subsets, each connected to a respective CP of 103a-c, but it will be appreciated that fewer or more than three CP's may be contemplated for any given building. In the illustrated example, the three CPs 103a-c are communicatively coupled by a (e.g., high bandwidth such as 10 Gigabits per second (Gbps)) communication backbone, and to an external network 105.

In some embodiments, the network links provide data transmission to other elements (e.g., devices) such as digital wall interfaces, enhanced functionality window controllers, digital architectural elements, and the like. A hierarchical network may be used wherein a distributed network includes at least two of a master controller, an intermediate controller (that can be floor controllers and/or network controllers), and a local controller (e.g., end or leaf controllers such as window controllers). A master controller may or may not be in physical proximity to a BMS. A master controller may be operatively coupled to a BMS. At least one floor (e.g., each floor) of a building may have one or more intermediate controllers. At least one device (e.g., window) may have its own local controller. A local controller may control at least 1, 2, 3, 4, 5, 6, 7, 8, 9, or 10 devices. The control system may or may not have intermediate controller(s). The control system may have 1, 2, 3, or more hierarchal control levels. A local controller may control a plurality of devices. The devices may comprise a (e.g., smart) window, a sensor, an emitter, an antenna, a receiver, or a transceiver, for example.

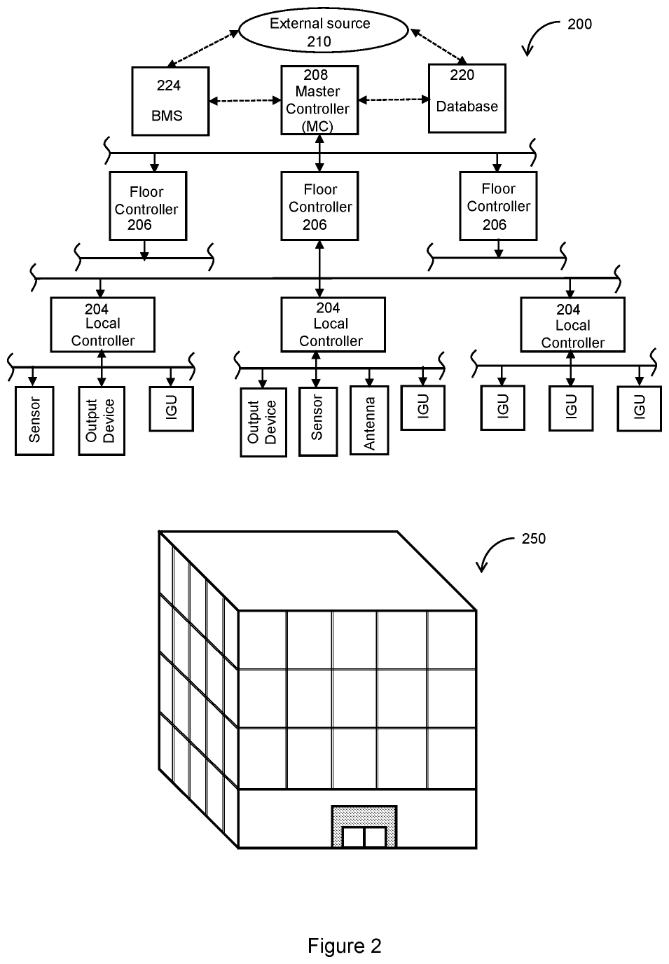

FIG. 2 shows an example of a control system architecture 200 comprising a master controller 208 that controls intermediate (e.g., floor) controllers 206, that in turn control local controllers 204. In some embodiments, a local controller controls one or more integrated glass units (IGUs), one or more sensors, one or more output devices (e.g., one or more emitters), one or more antennas, or any combination thereof. FIG. 2 shows an example of a configuration in which the master controller is operatively coupled (e.g., wirelessly and/or wired) to a building management system (BMS) 224 and to a database 220. Arrows in FIG. 2 represent communication pathways. A controller may be operatively coupled (e.g., directly/indirectly and/or wired and wirelessly) to an external source 210. The external source may comprise a network. The external source may comprise one or more sensor or output devices. The external source may comprise a cloud-based application and/or database. The communication may be wired and/or wireless. The external source may be disposed external to the facility. For example, the external source may comprise one or more sensors and/or antennas disposed, e.g., on a wall or on a ceiling of the facility. The communication may be mono-directional or bidirectional. In the example shown in FIG. 2, all communication arrows are meant to be bidirectional.

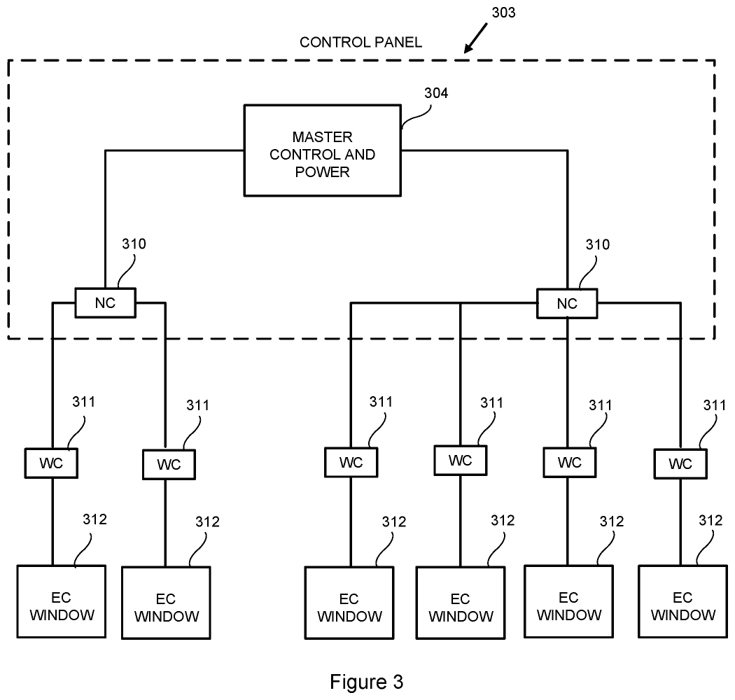

FIG. 3 illustrates a block diagram of a control panel 303 interfacing with a plurality of EC windows 312. In the illustrated example, the control panel 303 includes a master control and power module 304 and to network controllers (NC's) 310. It will be appreciated that the control panel 303 may include fewer or more NC's 310 than illustrated. Each NC 310 is respectively coupled with two or more window controllers (WC's) 311, each window controller 311 being associated with a respective EC window 312. The control system in FIG. 3 is an example of the more general control system illustrate in FIG. 2.

In some embodiments, a controller network may provide data transmission for standard window controllers (WC2's) dedicated to controlling optically switchable windows. In addition, the controller network may provide data transmission supporting enhanced functionality window controllers (WC3's) that may have a Wi-Fi access point, cellular capability, etc. In some embodiments, enhanced functionality window controllers connect to a controller network bus to send and receive data relating to controlling optically switchable windows assigned to the window controllers. Additionally, the enhanced functionality window controllers may connect to a high bandwidth line such as a gigabit Ethernet line to send and receive data relating to non-window functions such as Wi-Fi and/or cellular communications.

In some embodiments, the enclosure includes at least one digital architectural element (e.g., device ensemble) disposed in each of a plurality of separate areas (e.g., rooms). In some embodiments, the enclosure (e.g., room) includes a plurality of digital architectural elements (e.g., device ensembles). A digital architectural element (DAE) may contain a sensor, an emitter, processor (e.g., a microcontroller and/or a non-volatile memory), network interface, and/or peripheral interface. The term DAE can refer to any device, device ensemble, or interface, configured to be mounted to and/or retained in, or on, any structural component in an enclosure (e.g., framework, beam, joist, wall, ceiling, floor, window, fascia, transom, and/or casement of an enclosure. A DAE may include, for example, a window-mullion interface, a digital wall interface, and/or a ceiling-mounted interface. Examples of DAE sensor include light sensor. The DAE may include image capture sensor such as a camera, audio sensor such as voice coil and/or microphone, air quality sensor, and proximity sensor (e.g., certain IR and/or RF sensor). The network interface may be a high bandwidth interface such as a gigabit (or faster) Ethernet interface. Examples of DAE peripherals include video display monitors, add-on speakers, mobile devices, battery chargers, and the like. Examples of peripheral interfaces include standard Bluetooth modules, ports such as USB ports and network ports, etc. Ports may include any of various proprietary ports for third party devices.

In some embodiments, the DAE operates in conjunction with other hardware and/or software provided for an optically switchable window system, e.g., to a media display construct coupled to window, and/or to a display projected on the window. In some embodiments, the DAE includes a controller (e.g., any controller disclosed herein). Examples of display constructs, windows, control system, network, and related touch screen, can be found in U.S. Provisional patent application Ser. No. 62/975,706, filed on Feb. 12, 2020, titled “TANDEM VISION WINDOW AND MEDIA DISPLAY,” that is incorporated herein by reference in its entirety.

In some embodiments, a DAE includes one or more signal generating devices such as a speaker, a light source (e.g., an LED), a beacon, an antenna (e.g., a Wi-Fi or cellular communications antenna), and the like. The signal generating device can be an emitter. In some embodiments, a DAE includes an energy storage component and/or a power harvesting component. For example, a DAE may contain one or more batteries and/or capacitors, e.g., as energy storage devices. the DAE may include a photovoltaic cell. In one example, a DAE has one or more user interface components (e.g., a microphone or a speaker), one more sensors (e.g., a proximity sensor), and a network interface (e.g., for a high bandwidth communications).

In some embodiments, a DAE is designed, or configured to, attach to (or otherwise be collocated with) a structural element of an enclosure (e.g., a building). In some embodiments, a DAE has an appearance that blends in with the structural element with which it is associated. For example, a DAE may have a shape, size, and/or color that blends with the associated structural element. For example, a DAE may not be easily visible to occupants of a building; e.g., the element is fully or partially camouflaged in the surrounding in which it is disposed. However, such element may interface with other component(s) that do not blend in, such as one or more video display monitors, touch screens, projectors, and the like.

In some embodiments, the building structural elements to which DAE may be attached include any of various building structures. In some embodiments, building structures to which DAEs attach are installed and/or constructed during building construction, in some cases early in building construction when the building skeleton or envelope is constructed. In some embodiments, the building structural elements for DAEs are elements that serve a building structural function. Such elements may be permanent, e.g., not easily removable from a building. Examples include columns, piers (e.g., elevator, communication, or electrical piers), walls, partitions (e.g., office space partitions), doors, beams, stairs, façades, moldings, mullions and/or transoms. In various examples, the structural elements are located on a perimeter of the enclosure. In some embodiments, the DAE is provided as separate modular unit or as a housing (e.g., box) that attach to the building structural element. In some cases, a DAE is provided in a façade for building structural element. For example, a DAE may be provided as a cover for a portion of a mullion, transom, or door. In one example, a DAE is configured as a mullion or disposed in or on a mullion. If it is attached to a frame portion (e.g., mullion), the DAE may be bolted on, snapped to, or otherwise attached to the rigid parts of the mullion. In some embodiments, a DAE can snap onto a structural element of the enclosure. In some embodiments, a DAE serves as a molding, e.g., a crown molding. In some embodiments, a DAE is modular; e.g., it serves as a module for part of a larger system such as a communications network, a power distribution network, and/or computational system. The computation system can employ an external video display and/or other user interface component(s).

In some embodiments, the DAE is a digital frame portion (e.g., mullion portion) designed to be deployed on one or more frame portions (e.g., mullions) in an enclosure. In some embodiments, digital frame portions are deployed in a regular or periodic fashion. For example, digital frame portions may be deployed on every (e.g., second, fourth, sixth, or tenth) successive frame.

In some embodiments, the DEA has a network connection. In some embodiments, the DEA houses one or more devices (e.g., digital and/or analog components). In some embodiments, in addition to the (e.g., high bandwidth) network connection (port, switch, and/or router) and housing, the DAE includes one or more of the following digital and/or analog components. The devices (e.g., digital and/or analog components) may include: a camera, a proximity or movement sensor, an occupancy sensor, a color temperature sensor, an infrared sensor, an ultraviolet sensor, a visible light sensor, a biometric sensor, a speaker, a microphone, an air quality sensor, a hub for power and/or data connectivity, display video driver, a Wi-Fi access point, an antenna, a location service (e.g., Bluetooth, Global Positioning System, or ultra-wide band) via beacons or other mechanism, a power source, a light source, a processor, a memory, and/or a circuitry (e.g., ancillary processing device). One or more cameras may include a sensor and/or processing logic for imaging features in the visible, IR, or other wavelength region; various resolutions of the camera are possible including high definition (HD) and greater. The DAE may include one or more of the devices disclosed herein.

The camera and/or display construct may have at its fundamental length scale 2000, 3000, 4000, 5000, 6000, 7000, or 8000 pixels. The camera and/or display construct may have at its fundamental length scale any number of pixels between the aforementioned number of pixels (e.g., from about 2000 pixels to about 4000 pixels, from about 4000 pixels to about 8000 pixels, or from about 2000 pixels to about 8000 pixels). A fundamental length scale may comprise a diameter of a bounding circle, a length, a width, or a height. The fundamental length scale may be abbreviated herein as “FLS.” The camera and/or display construct may comprise a high resolution display. For example, the camera and/or display construct may have a resolution of at least about 550, 576, 680, 720, 768, 1024, 1080, 1920, 1280, 2160, 3840, 4096, 4320, or 7680 pixels, by at least about 550, 576, 680, 720, 768, 1024, 1080, 1280, 1920, 2160, 3840, 4096, 4320, or 7680 pixels (at 30 Hz or at 60 Hz). The first number of pixels may designate the height of the display and the second pixels may designates the length of the display. For example, the camera and/or display construct may have a resolution of 1920×1080, 3840×2160, 4096×2160, or 7680×4320. The camera and/or display construct may be a standard definition, enhanced definition, high definition display, or an ultra-high definition.

One or more proximity or movement sensors may include an infrared sensor (abbreviated herein as an “IR” sensor). In some embodiments, a proximity sensor is a radar or radar-like device that detects distances from and between objects using a ranging function. Radar sensors can also be used to distinguish between closely spaced occupants via detection of their biometric functions, for example, detection of their different breathing movements. When radar or radar-like sensors are used, better operation may be facilitated when disposed unobstructed or behind a plastic case of a DAE. One or more occupancy sensors may include a multi-pixel thermal imager, which when configured with an appropriate computer implemented algorithm can be used to detect and/or count the number of occupants in a room. In some embodiments, data from a thermal imager or thermal camera is correlated with data from a radar sensor to provide a better level of confidence in a particular determination being made. In some embodiments, thermal imager measurements can be used to evaluate other thermal events in a particular location, for example, changes in air flow caused by open windows and doors, the presence of intruders, and/or fires. One or more color temperature sensors may be used to analyze the spectrum of illumination present in a particular location and to provide outputs that can be used to implement changes in the illumination as needed or desired, for example, to alter (e.g., improve) an occupant's health, comfort, or mood. One or more biometric sensors (e.g., for fingerprint, retina, or facial recognition) may be provided as a stand-alone sensor or be integrated with another sensor such as a camera.

One or more speakers and associated power amplifiers may be included as part of a DAE or separate from it. In some embodiments, two or more speakers and an amplifier are configured as a sound bar; e.g., a bar-shaped device containing multiple speakers. The device may be designed (e.g., configured) to provide high fidelity sound. One or more microphones and/or logic for detecting and processing sounds, may be provided as part of a DAE or separate from it. The microphone(s) may be configured to detect internally and/or externally generated sounds. Internal may refer to internal to the enclosure. External my refer to external to the enclosure. In some embodiments, processing and analysis of the sounds is performed by logic (embodied in software, firmware, and/or hardware) in one or more digital structural element and/or by logic in one or more other devices coupled to the network, for example, in one or more controllers coupled to the network. In some embodiments, based at least in part on the analysis, the logic is configured to (e.g., automatically) adjust a sound output of one or more speaker to mask and/or cancel sounds, frequency variations, echoes, and other factors detected by one or more microphone, e.g., that negatively impact (or potentially could negatively impact) occupants present in a location within the enclosure (e.g., the building). In some embodiments, the sounds comprise sounds generated by, but not limited to: indoor machinery, indoor office equipment, outdoor construction, outdoor traffic, and/or airplanes.

In some embodiments, the DAE comprises one or more air quality sensors. The one or more air quality sensors (optionally able to measure one or more of the following air components: volatile organic compounds (VOC), carbon dioxide temperature, humidity) may be used in conjunction with a heating, ventilation, and air-conditioning system (HVAC system) to adjust (e.g., improve) air circulation.

In some examples, the DAE may include a connectivity and/or power hub. One or more hubs for power and/or data connectivity to sensor(s), speakers, microphone, and the like may be provided by the DAE. The hub may comprise a USB hub, or a Bluetooth hub. The hub may include one or more ports such as USB ports, High Definition Multimedia Interface (HDMI) ports, or any other port, plug, or socket disclosed herein. For example, the DAE may include a connector dock for external sensors, light fixtures, peripherals (e.g., a camera, microphone, speaker(s)), network connectivity, power sources, etc.

In some embodiments, one or more video drivers may be provided in the DAE. The driver may be utilized for a media display (e.g., a transparent OLED media display construct) on or proximate to a window (such as an integrated glass unit (IGU)) associated with the DAE element. The driver may be operatively coupled (e.g., wireless, physically wired, and/or optically coupled) to the DAE. For example, the optical signal may be launched into the window by optical transmission, such as a switchable Bragg grating that includes a display with a light engine and lens that focuses on glass waveguides that transmits through the glass and travels perpendicularly to line of sight.

One or more Wi-Fi access points and antenna(s), which may be part of the Wi-Fi access point or serve a different purpose. In some embodiments, the DAE or a faceplate that covers all or a portion of the DAE, may serve as an antenna. Various approaches may be employed to insulate the DAE and use it to transmit and/or receive directionally. A prefabricated antenna may be employed in the enclosure. A window antenna may be employed. Examples of antennas and their integration in a facility and deployment may be found in International Patent Application Serial No. PCT/US17/31106, filed May 4, 2017, which is incorporated herein by reference in its entirety.

One or more power sources such as an energy storage device (e.g., a rechargeable battery and/or a capacitor), and the like may be provided. The power source may be renewable or non-renewable. The plurality of power sources may comprises renewable or nonrenewable power sources. In some embodiments, a power harvesting device is included; e.g., a photovoltaic cell or panel of cells. This may allow the device to be self-contained or partially self-contained. The light harvesting device may be transparent or opaque, e.g., depending on where it is attached. For example, a photovoltaic cell may be attached to, e.g., and partially or fully cover, the exterior of a digital mullion. For example, a transparent photovoltaic cell may be cover a display and/or user interface (e.g., a dial, button, etc.), e.g., on the DAE.

One or more processors may be configured to provide various embedded or non-embedded applications. The processor may comprise a microcontroller. In some embodiments, the processor is low-powered mobile computing unit (MCU) with memory and configured to run a lightweight secure operating system hosting applications and data. In some embodiments, the processor is an embedded system, system on chip, or an extension. One or more ancillary processing devices (such as a graphical processing unit, an equalizer, or other audio processing device) may be used to interpret audio signals. In some embodiments, the speaker, microphone, and associated logic are configured to use acoustic information to characterize the acoustic map of the enclosure, its air quality, and/or air conditions. As an example, an algorithm may issue ultrasonic pulses, and detect the transmitted and/or reflected pulses coming back to a microphone. The algorithm may be configured to analyze the detected acoustic signal, sometimes using a transmitted vs. received differential audio signal, to determine air density, particulate deflection, and the like, e.g., to characterize air quality in the enclosure.

In some embodiments, the DAE is coupled to a signal (e.g., sound) equalizer. In some cases, the equalizer can facilitate adjustment of room acoustics using, e.g., real time, time delay reflectometry. The equalizer (and associated components) can compensate for unwanted audio artifacts, e.g., produced by interactions of the sound waves with items that are in the enclosure (e.g., a room) or otherwise in close proximity with an occupant. In some embodiments, a signal pulse is generated by a speaker associated with the DAE. One or more microphones can pick up the pulse (e.g., directly) and as reflected and/or attenuated by items in the room (e.g., wall roughness, or shelf angle). Based at least in part (i) on the time delay between emitting and detecting the pulse, and/or (ii) on tonal quality of the detected pulse, the system can infer boundaries of the enclosure (e.g., room boundaries), etc. In some embodiments, a user's mobile device (e.g., smart phone, pad, or laptop) enables optimizing speaker outputs for the acoustical environment of various locations in a room. During a set up mode, the user (e.g., with the mobile device enabled), may move around an enclosure and use the mobile device to detect the acoustical response. Based at least in part on the location and the detected acoustic response, the DAE can determine how to optimize speaker output. The optimization may be after the acoustic profile of the room is mapped. The optimization may be a corrective action. The optimization may comprise (e.g., controllably and/or automatically) adjusting one or more sound absorbers, diffusers, and/or deflectors in specific areas that affect the sound map in the enclosure. The optimization may be automatically controlled. The optimization may comprise altering a white noise level, a fixture (e.g., wall or ceiling) roughness, adjustable shelve(s) (e.g., vents), and/or speaker output. For example, the DAE can be programmed to tune its speaker output based on various factors such as where the user is located in the enclosure. The DAE (e.g., device ensemble) can, in some embodiments, detect the user location using any of a number of proximity techniques, such as those described in International Patent Application Serial No. PCT/US17/31106, filed May 4, 2017, which is incorporated herein by reference in its entirety.

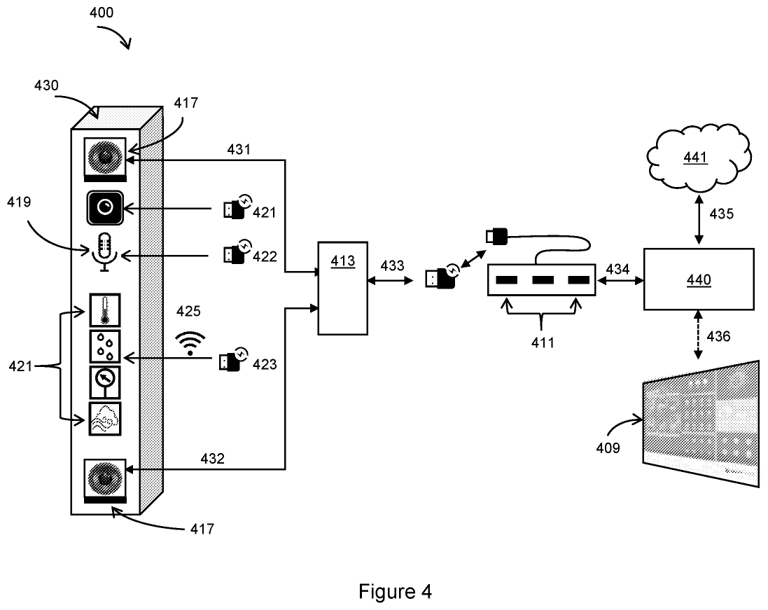

FIG. 4 schematically shows an example of components related to a digital architectural element (DAE). In the illustrated example, an arrangement 400 includes a DAE 430 and a processor (e.g., computer) 440. The processor 440 is connected (e.g., via Ethernet connection) to an external network 441. The external network can include internet and/or a cloud-based content and/or service provider. The connection of the processor to the external network may include an appropriate modem, router, switch and/or a high bandwidth backbone such as the 10 Gigabyte backbone. The processor 440 may also be connected to a display 409 (e.g., video display) via, in this example, a High-Definition Multimedia Interface (HDMI) link. The processor 440 is connected to ports 411 (e.g., USB, Wi-Fi, Bluetooth, or any other port, and/or socket disclosed herein), e.g., to make available additional internal and/or external resources for the DAE 430. A DAE may include any device disclosed herein (e.g., various sensors and peripheral elements). In the example illustrated in FIG. 4, DAE 430 includes speakers 417, microphone 419, and various sensors 421 such as temperature, humidity, pressure, and gas flow sensors. Any one or more of these components may be coupled to the computer or processor 440 via the ports 411. Ay of the device may be reversibly plugged in and out of the electronic circuitry of the DAE, e.g., via connectors 421-423. Any of the devices may communicate via wired or wireless (e.g., 425) communication. The communication may be to the network, to the processor 411, or to any other processor configure to receive the communication. The communication can be monodirectional or bidirectional. In the example shown in FIG. 4, bidirectional communication is designated by bidirectional arrows, e.g., 431-436. The DAE is coupled an equalizer 413 configured to provide tone control to adjust for acoustics of the enclosure in which the DAE is disposed. The DAE may be also referred to herein as “device ensemble,” “ensemble of devices,” or a “device assembly.”

In some embodiments, a plurality of transducers such as sound emitters (e.g., speakers) and sound sensors (e.g., microphones) are disposed in the facility to acoustically map enclosure (e.g., acoustic) environments. The sound transducers may each have known locations. The sounds transducers may be communicative coupled together via a network, e.g., a communications and power network. The sound emitters and sensors may use (i) sound frequency sweeping, (ii) their location (e.g., relative and/or absolute location), and (iii) mutual timing coordination, to generate the acoustic mapping of the enclosure (e.g., facility). In some embodiments, the acoustic mapping can be done automatically, in situ, and/or in real time during a sound event (e.g., a conference). The acoustic mapping may be done outside of the sound event (e.g., after work hours). Any change in the enclosure (e.g., facility) affecting the acoustic mapping can be accounted for in initial acoustic mapping and/or updated testing. In one example, acoustic mapping allows one to know how well various enclosure (e.g., facility) environments (e.g., rooms) are isolated from noise generated in other areas of an enclosure (e.g., other rooms), allowing areas that are not sufficiently isolated to be identified for corrective action (e.g., sound optimization). From this data, insufficiently acoustically isolated enclosure environments can be made more so by taking any of the corrective measures disclosed herein. For example, by adding or configuring sound absorbers, diffusers, and/or deflectors in specific areas.

In some embodiments, a two-dimensional or three-dimensional virtual representation of an environment (e.g., an enclosure such as a building including separate rooms and/or zones where occupants may gather) helps define the areas of interest for which acoustic properties are to be determined and managed. Such a representation may utilize a model such as a Building Information Modeling (BIM) model (e.g., an Autodesk Revit file), e.g., to derive a representation of (e.g., basic) fixed structures and movable items such as doors, windows, and elevators. The model may be annotated with representations of other elements (e.g., fixtures and non-fixtures) which may be permanent or non-permanent elements. The installed locations of transducers (e.g., speakers and microphones), which may or may not include sensor ensembles (e.g., DAE) integrating both a speaker (e.g., buzzer) and a microphone, may be annotated in the model. A user may annotate the model to include information regarding requested acoustic properties, e.g., for corresponding zones (e.g., rooms) in the model. For example, a zone may be designated as a one-person office which implies requesting a high degree of acoustic isolation (e.g., so that use of a speaker-phone can be conducted in the office without sound interference from outside the office and so that the sounds made by the user of the office and the sounds from the speaker-phone itself do not become distractions for people outside the office). Modifications within an enclosure may alter the areas of interest. For example, office cubicles may be introduced and/or reconfigured in ways that change the acoustic properties (e.g., transfer function(s) defining an acoustic attenuation) of one of more zones in ways that could be undesirable. The roughness and/or material of fixture surface facing the enclosure interior may be altered (e.g., to alter the sound map in the enclosure). Angle of various shelves may be altered to change the sound map.

In some embodiments, the enclosure comprises one or more sound transducers (e.g., emitters such as speakers) and/or sound sensors. The sound transducers and/or sensors may be installed to occupy regularly spaced locations. In some embodiments, an interplay between emitters and sensors can be attuned to the expected acoustics of an enclosure. In some embodiments, the emitters and sensors are spaced according to an occupant density in a building to achieve a finer acoustic tuning in more heavily occupied spaces. In some embodiments, the emitters and sensors are spaced according to area of interest in a building to achieve a finer and/or rougher acoustic tuning according to the area of interest requirements. Transducer locations may be chosen toward the top and sides of a particular zone so that the interplay between emitters and sensors can be used to create a 3D acoustic mapping.

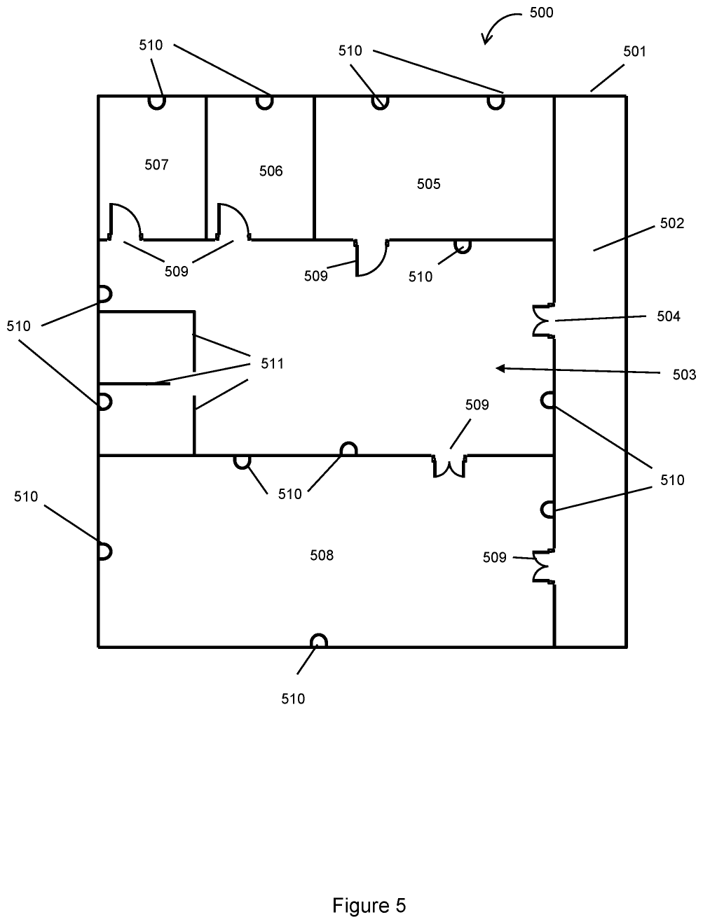

FIG. 5 shows an example representation 500 of an enclosure as a floor 501 of a (e.g., multi-story) building. For example, an outer hallway 502 has access to an office suite 503 via a main door 504. The office suite includes inner offices 505, 506, and 507 and a conference room 508. Doors 509 provide access to inner offices 505-507 and conference room 508 as shown. A plurality of digital architectural elements (e.g., device ensembles) 510 are installed, e.g., throughout office suite 503. Each ensemble 510 may include at least one sound emitter (e.g., speaker or buzzer) and at least one sound sensor (e.g., microphone) integrated into a common housing. Each ensemble 510 may be mounted in a window frame portion (e.g., mullion), on a wall surface, or suspended from a ceiling, for example. The sound transducers of the ensembles (e.g., 510) may be capable of testing and monitoring a respective zone which may vary depending on surrounding structures such as fixtures (e.g., walls, windows, and doors) and non-fixtures (e.g., furniture and movable partitions for cubicles). As shown in FIG. 5, a center area of suite 503 includes partitions 511 for cubicles. In the real office corresponding to representation 500, acoustic properties may be acquired using a data collection process that establishes an initial acoustic map that is valid for the office configuration at the time of data collection.

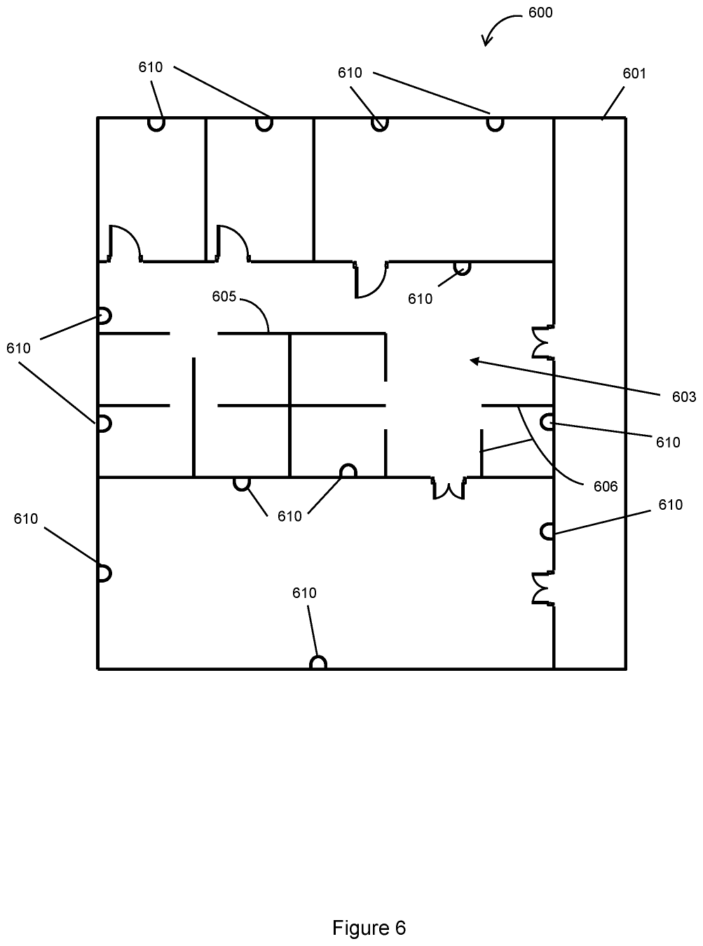

FIG. 6 shows an example representation 600 of floor 601 that is floor 501 shown in the example of FIG. 5, after being reconfigured is ways that impact the acoustic properties of interest. For example, as compared to FIG. 5, groups of cubicle partitions 605 and 606 are added to office suite 603. Sensor ensembles 610 are shown as having the same configuration as in FIG. 5, although some reconfiguration of emitters/sensors could occur (e.g., additional emitter/sensor locations). For example, alteration of fixtures and/or non-fixtures may follow additions and/or relocation of DAE(s). Revised acoustic properties may be acquired to establish an updated acoustic map that is valid for the enclosure configuration, e.g., at the time of an updated data collection. For example, a processing system may be configured to analyze (e.g., compare) the sound emitted by the emitter and the sound sensed by the sound sensor, and based on the locations of these emitters and sensors, form the acoustic mapping of the environment. Changes in fixtures and/or non-fixtures may happen during use of an enclosure (e.g., office). The changes may or may not have a noticeable and/or measurable effect on the acoustics of the enclosure. In some embodiments, a notification and/or a report is issued to a user (e.g., building or office manager) only when a difference between the updated acoustic map and the initial acoustic map is greater than a threshold (e.g., predetermined difference). The threshold may be a value or a function (e.g., time dependent function and/or space dependent function).

In some embodiments, a communication network, e.g., that of a facility, is communicatively coupled to a plurality of sound emitters (e.g., speakers) and a plurality of sound sensors (e.g., microphones) disposed in the facility. The emitters may be configured to emit sound in a (e.g., wide) range of frequencies and/or at a sound intensity (e.g., sound pressure level or power). The frequency may be at least about 1 Hertz (Hz), 10 Hz, 100 Hz, 1 kHz, 10 kHz, 20 kHz, or 50 kHz. The frequency may be at most about 10 Hz, 100 Hz, 1 kHz, 10 kHz, 20 kHz, or 50 kHz. The frequency may be between any of the aforementioned frequency values (e.g., from about 1 Hz to about 50 kHz, from about 10 Hz to about 20 kHz, from about 100 Hz to about 50 kHz). The frequency range may comprise (i) a continuous frequency range or (ii) a discrete frequency range. The sound intensity may be predetermined. The sound intensity may comprise a range of sound intensities. In some embodiments, the sound may or may not be perceptible to the human ear. The sensors are configured to receive the sound(s) and convert it to an electrical signal. The emitter(s) and sensor(s) may be utilized for creation and/or alteration of an acoustic transfer function. The emitter(s) and sensor(s) may be utilized for detection of faults and/or changes in an acoustic transfer function (e.g., due to a new obstruction, and/or fixture change).

In some embodiments, data collection for acoustic mapping utilizes a first sound sensor at a first location, a second sound sensor at a second location different from the first location, and a sound emitter at a third location. The third location may be different from the first and second locations. The locations may differ in X, Y, and/or Z Cartesian coordinates. In some embodiments, the third location may coincide with one of the first and second locations. In some embodiments, a greater number of sensors and emitters is used with a greater number of (e.g., predetermined) locations, e.g., in order to obtain a greater mapping resolution (e.g., with the distribution of sensors and emitters providing appropriate overlap of zones so that test signals from an emitter can be sensed at a greater number of sensors). Testing may be performed at a time of low occupancy in the facility, e.g., at night, on a weekend, and/or on a holiday. A time for the sound sweeping subroutine may be scheduled using a calendar function. Network interaction between modules or nodes (e.g., device ensembles) may be used to coordinate a sound sweeping subroutine among the various emitters and sensors. For example, sequential frequency sweeping may be performed by selected (e.g., some or all) emitters in the facility. The sweeping of sound frequencies may extend to any frequency range delineated herein (e.g., from about 10 Hz to about 20 kHz, or from about 1 Hz to about 50 kHz). In some embodiments, a first sound emitter may emit a sound at a frequency range (e.g., using frequency sweeping), and (e.g., selected or all) sensor(s) in the facility may be programmed to “listen” and sense the emitted sound frequencies. The sound emitter may be in an enclosure (e.g., room), and the sound sensors may be in the same enclosure (e.g., room) and/or in a different enclosure (e.g., anywhere else in the facility) where a sound may be detectable. For example, at least a portion of the emitters may be included in window frames of the facility envelope, e.g., in a transom and/or mullion, as shown for example in U.S. patent application Ser. No. 16/608,157, filed on Oct. 24, 2019, titled “DISPLAYS FOR TINTABLE WINDOWS,” which is incorporated herein by reference in its entirety. For example, at least a portion of the emitters may be located farther within the interior of the facility. A second sound emitter may emit a sound at a frequency range (e.g., using frequency sweeping), and (e.g., selected or all) sensor(s) in the facility may be programmed to “listen” and sense the emitted sound frequencies. This process may be continued with other sound emitter(s) until all requested emitters have completed their frequency sweep, and each of the sound sensors have measured a respective acoustic response corresponding to each acoustic test signal. Using the known locations of the emitters and sensors in conjunction with the emitter and sensor data, a sound attenuation (e.g., acoustic transfer function) map can be generated for the enclosure (e.g., facility). The testing/mapping may be performed per enclosure or enclosure portion (e.g., per room, per group of rooms, per floor, per group of floors, per building, or per facility). All the emitters (e.g., speakers) and sensors (e.g., microphones) may have known locations in the enclosure. The locations may be determined at the time of installation (e.g., by a traveler such as an installer or a robot such as a wheeled robot or a drone), obtained from an architectural planning, computer aided design (CAD) file (e.g., Revit file), detected using an autolocation procedure (e.g., as disclosed in U.S. Provisional patent application Ser. No. 62/958,653, titled “SENSOR AUTOLOCATION,” filed on Jan. 8, 2020, which is incorporated herein by reference in its entirety), and/or detected using an ultra-wideband radio chip facilitating relative location finding, for example. The amount of time required for data collection according to the frequency mapping procedure and to generate a corresponding mapping of the facility may be at most a day, 8 h, 4 h, 2 h, or 1 h.

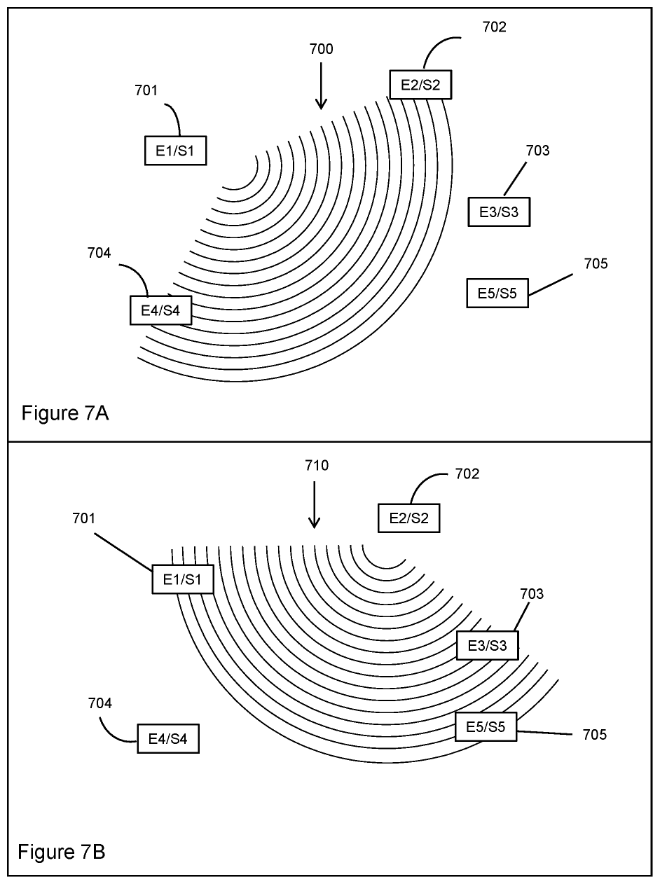

FIG. 7A shows an example of device ensembles 701-705, each containing a respective sound emitter and sound sensor. It should be understood however, that not every DAE must include a sensor and an emitter. For example, a DAE may comprise a sound emitter and be devoid of a sound sensor. For example, a DAE may comprise a sound sensor and be devoid of a sound emitter. In the example shown in FIG. 7, ensemble 701 includes a collocated sound emitter E1 and sound sensor S1. Ensemble 702 includes a collocated sound emitter E2 and a sound sensor S2. Ensemble 703 includes a collocated sound emitter E3 and a sound sensor S3. Ensemble 704 includes a collocated sound emitter E4 and a sound sensor S4. Ensemble 705 includes a collocated sound emitter E5 and a sound sensor S5. FIG. 7A depicts an example of a sound pressure wave 700 propagating from emitter E1 (in ensemble 701) to sound sensors S2, S3, S4, and S5 (in ensembles 702-705, respectively) during a respective test signal. Thus, a plurality of sound paths (e.g., through respective zones or rooms in the enclosure) may be interrogated simultaneously. FIG. 7B shows an example of a succeeding step in the acoustic mapping process, wherein a sound pressure wave 710 propagates from sound emitter E2 (in ensemble 702) to sound sensors S1, S3, S4, and S5 during a second test signal.

In some embodiments, each testing signal uses a frequency sweeping signal which is continuous in a frequency range. A transfer function defining the acoustic attenuation from one location (e.g., zone) to another may be determined as a change in sound intensity according to sound frequency (e.g., some frequencies are attenuated more quickly than others), in a space (e.g., a space of the enclosure). Moreover, the transducers and support electronics (e.g., drivers) may have frequency dependencies in their performance, and human hearing may not be equally sensitive across all audible frequencies. Therefore, an acoustic mapping taking frequency into account may be used. For example, a tone with a (e.g., continuous and/or discrete) frequency sweep (e.g., ramping) between a first frequency and a second frequency may be used. In some embodiments, discrete frequency steps may be used (e.g., discrete frequencies that are detectibly separable from each other). The discrete steps may follow continuously or may be spaced apart in time. The sound sweeping may be partially continuous (e.g., continuous ramping in a first frequency range) and partially discrete (e.g., discrete steps in a second frequency range).

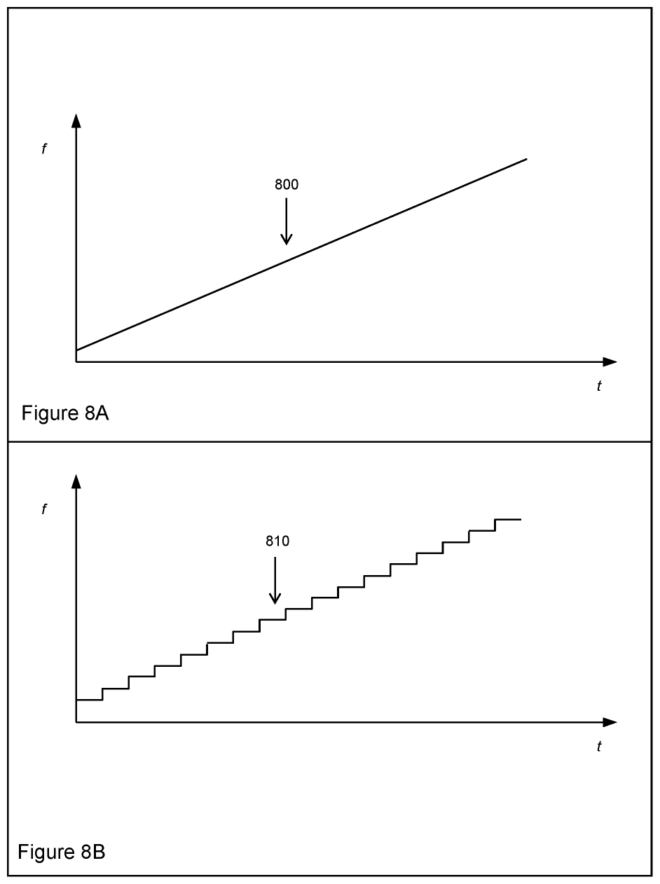

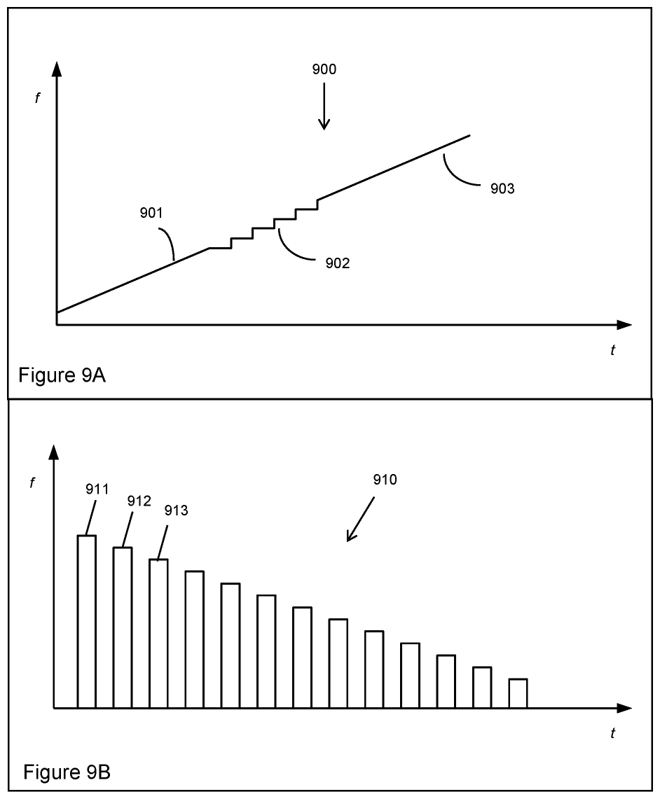

FIG. 8A shows an example of a frequency ramp 800 conducted over a testing interval for a particular sound emitter. Ramp 800 begins at a first time at a minimum frequency and increases over time to a maximum frequency. In some embodiments, a frequency ramp begins at the maximum frequency and decreases over the testing interval to the minimum frequency. FIG. 8B shows a testing signal 810 having discrete steps of increasing frequency during a testing interval. Likewise, the discrete steps may be decreasing from the maximum frequency to the minimum frequency during the testing interval. When discrete steps are used, the frequency progression may follow any arbitrary ordering of frequencies. At least two of the discrete frequency steps may be of different durations and/or different frequency spans (e.g., one spanning 5 Hz, and the other spanning 10 Hz). At least two (e.g., all) of the discrete frequency steps may be of the same duration and/or the same frequency span (e.g., both spanning 10 Hz). FIG. 8B shows an example in which all of the discrete frequency steps are of the same duration and of the same frequency span. FIG. 9A shows an example of a combined continuous and discrete testing signal 900 having an initial continuously-increasing ramp phase 901, an intermediate discrete phase 902, and a final continuously-increasing ramp phase 903. FIG. 9B shows an example of a testing sequence 910 with discrete steps (e.g., 911, 912, and 913) spaced in time. Although monotonically-decreasing frequencies are shown, an increasing or arbitrary ordering of (e.g., increasing and decreasing) frequencies may be used.

In some embodiments, the sound intensity generated by a sound emitter as it sweeps through various frequencies, is kept substantially constant. In some embodiments, the sound intensity is a function of the emitted frequency (e.g., following a loudness curve according to the sensitivity of human hearing). At each emitted frequency, the sensor(s) may measure an intensity (e.g., sound pressure level (SPL), and/or sound power expressed in dB). A difference between the emitted intensity and the detected intensity at each frequency may specify an acoustic transfer function between a respective pair of a sound emitter and a sound sensor, for example. In some embodiments, the corresponding attenuation (e.g., in dB) at various frequencies enables analysis of how well various frequencies are activated and/or damped by the fixtures (e.g., wall) and non-fixtures (e.g., table) of the enclosure. An acoustic map may be comprised of a compilation of attenuation data for a pair of a sound emitter and a sound sensor, which may enable analysis of whether different zones (or locations) provide the requested acoustic attenuation for intended uses of the space, and/or to detect any changes in suitability of the space over time.

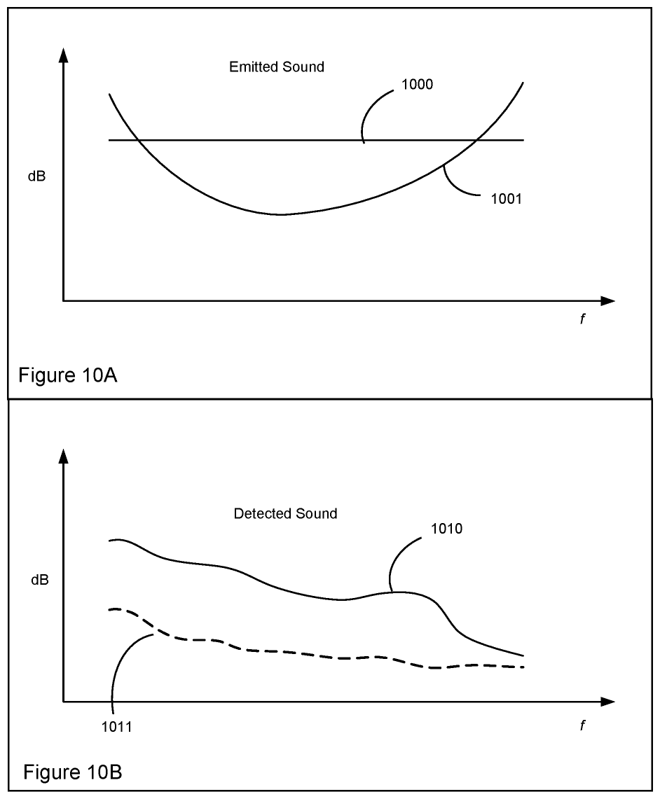

FIG. 10A shows an example of sound intensity diagrams for sounds emitted according to a sweeping of the frequency of a test tone during a testing interval. A plot 1000 shows a constant sound intensity whereby all emitted frequencies are produced at the same SPL or power. A plot 1001 shows a variable sound intensity generally following an “equal loudness contour” wherein midrange frequencies (e.g., from about 1 kHz to about 4 kHz, corresponding to the greatest sensitivity of human hearing) have a lowest emitted intensity and the frequencies at the low end and at the high end have a higher emitted intensity. FIG. 10B shows an example of a sound intensity diagram for sounds received at different sensors according to the sweeping of the test tone frequency from one emitter. A plot 1010 shows a received intensity according to frequency for a sensor (e.g., microphone) at a first location, and a plot 1011 shows a received intensity according to frequency for a sensor at a second location. In this example, differences in a distance traveled, intervening objects, and/or reflective surfaces for the respective sound paths from the emitter to each of the sensors results in a lower overall sound intensity for plot 1011. In a similar manner, a received intensity for the same testing signal may change at a later time for one particular sensor due to modifications of the fixtures and/or non-fixtures present within the enclosure.

In some embodiments, generating an acoustic mapping is done based on experimental results alone, e.g., (I) without considering a map (e.g., a 3D map) of the space, such as a BIM (e.g., Revit) file of the facility, and/or (II) without any other information regarding fixtures and non-fixtures in the enclosure. In some embodiments, when a Building Information Modeling (BIM) (e.g., Revit) file is available it is used to identify (e.g., important) acoustic paths and expected acoustic properties. The BIM file may assist in determining a testing sequence, e.g., using (I) emitter and sensor locations, and/or (II) how the acoustic zones align with fixtures and non-fixtures in the enclosure. A BIM file may be created before or upon construction of the facility. Since the BIM file may not be constantly updated (e.g., it may be cumbersome and/or time consuming to update), a testing sequence may be determined without consulting a BIM file. Selections of emitters and sensors to participate in a testing sequence may be preselected, automatically generated (e.g., by at least one controller), and/or user selected. A testing sequence may correspond to an indicated size of portion of a facility (e.g., multi-story building or a floor). A testing sequence may be conducted, e.g., at a user selected time and zone(s) (e.g., point of interest). A testing sequence may be automatically or manually triggered, e.g., after a big change has occurred in the facility (e.g., wall restructuring, and/or revised placement of furniture). In some embodiments, an initial acoustic map is generated for a facility upon installation of the digital architectural elements and processor network. Based at least in part on an initial acoustic map and the desired acoustic performance (e.g., isolation) between different areas within the enclosure, alterations of and/or additions to, the fixtures and/or non-fixtures in the enclosure may be made in order to achieve the requested acoustic performance.

In some embodiments, a sound map is generated for the enclosure. After a testing time and a testing sequence have been identified, data collection may proceed by selecting a first sound emitter for producing a test tone. The sound emitter may be commanded to generate the test tone while one or more sensors are commanded to monitor for reception of the test tone. As the test tone (e.g., frequency sweep) proceeds, the sound sensors may record a measured intensity at which the test tone is received. Subsequently, the sound emitters are sequentially triggered while corresponding sound sensors monitor the received intensities. In some embodiments, after collecting the received sound intensities for all the test tones, the sound attenuation data is mapped for the areas (e.g., zones) of interest in the enclosure. In some embodiments, the acoustic map comprises transfer functions according to the sound attenuation along (e.g., each) relevant sound path. A newly generated acoustic map can be analyzed relative to (e.g., compared to) a previous map (e.g., the initial acoustic map or an acoustic map from a (e.g., the most) recent performance of the texting sequence). If significant (e.g., above a threshold) changes are found between the successive acoustic mappings, then an electronic notification and/or report may be generated to inform a user (e.g., facility owner, tenant, and/or building manager) of the changed situation, e.g., so that mitigating actions can be taken. In some embodiments, generation of an acoustic map includes sound simulation(s) according to a model of the enclosure (e.g., Revit file and information concerning contents such as furniture). An accurate sound simulation may take an extensive amount of time (e.g., in the order of days, depending on the requested resolution), computing power, and/or cost. In some embodiments, acoustic mapping relies on experimental results without use of a previously generated physical simulation (e.g., using physics modeling considering enclosure fixture and non-fixture structure, material, and surface texture, and sound interacting with those). In some embodiments, a mapping function may run a simulation of lower complexity (e.g., without considering (e.g., surface) material properties of the facility fixtures and/or non-fixtures).

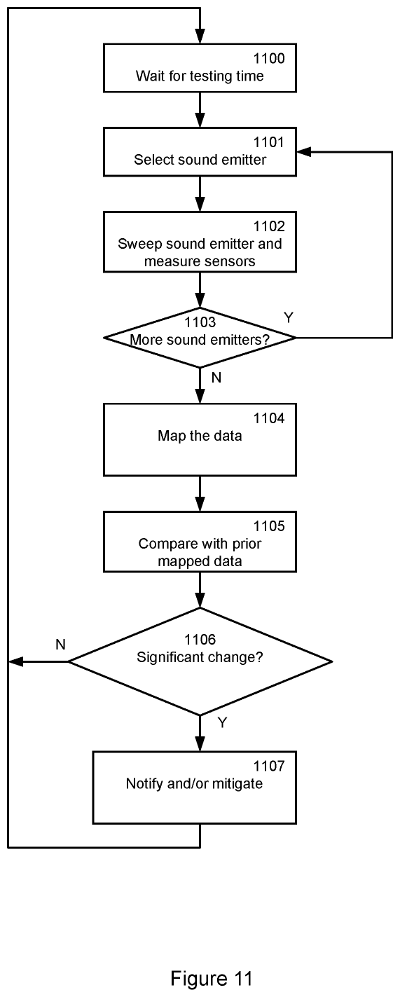

FIG. 11 shows a scheme for performing a testing sequence and detecting changes in acoustic properties in an enclosure. In block 1100, based on a testing sequence and selected conditions for initiating the testing (e.g., a scheduled time) the process waits for the arrival of the testing time. The testing sequence begins in block 1101 with the selection of an emitter to be activated. In block 1102, a test tone (e.g., frequency sweep) is emitted by the sound emitter and corresponding sound is measured by relevant sensors and recorded (e.g., frequency, optionally intensity, and optionally time). A check is performed in block 1103 to determine whether there are more sound emitters to be included in a testing sequence. If so, then a return is made to block 1101 to proceed to the next sound emitter. If not (e.g., all the sound emitters have been activated) then the collected data is used to create an acoustic map in block 1104. In block 1105, the acoustic map is analyzed (e.g., compared) with an acoustic map as created from a historic (e.g., prior) data collection. A check is performed in block 1106 to determine whether the analysis indicates that a significant (e.g., above a threshold) change has occurred. For example, a significant change may be detected when a transfer function (e.g., attenuation of sound intensity) associated with a particular sound path has changed by an amount greater than a predetermined difference (e.g., a threshold specified as a particular value in dB). If there is not a significant change, then the procedure returns to block 1100 to wait for a time at which a next testing event will occur (e.g., according to a schedule). If there is a significant change, then actions may be taken in block 1107 to deliver a notification (e.g., report) to a person and/or to mitigate a deteriorated acoustic property by reconfiguring, adding, or removing a fixture or non-fixture that impacts the associated sound path. The scheduling of the time event may depend at least in part on a calendar, a time interval in which low sound activity in the enclosure is projected (e.g., night time, out of working hours, closure, holiday, and/or vacation). The scheduling of the time event may depend at least in part on a projected or occurred change in a fixture and/or non-fixture in the enclosure. The scheduling of the time event may depend at least in part on a user request.

In some embodiments, changes in measured sound attenuation from one testing sequence to another are used to distinguish between changes caused by faults occurring in a sound transducer (e.g., speaker or microphone) and changes caused by altered acoustic properties along the sound paths. For example, a first sound emitter (e.g., first buzzer) in a first ensemble located at a first known location emits sounds, and the emitted first sound is picked up at a second sound sensor of a second ensemble and optionally at a third sound sensor in a third location (e.g., and in other additional sounds sensors at other ensembles) at other known locations. If detection of the signal of the first buzzer at the second sound sensor (e.g., and at the third, and at other sounds sensors) undergoes a detectable (e.g., and significant above a threshold) change from past detection of the first buzzer signal, then there is a high likelihood that (i) there is a fault in the buzzer, or (ii) there is a sound affecting change in/adjacent to the first ensemble (e.g., due to an obstruction and/or fixture change). This likelihood increases when a second sound emitter (e.g., second buzzer) in another ensemble located at another known location emits sounds, and the emitted second sound is picked up at the second sound sensor of the second ensemble and optionally at the third sound sensor in the third location (e.g., and in other additional sounds sensors at other ensembles) at other known locations, without change. As another example, a second sound emitter (e.g., second buzzer) in the second ensemble emits sounds, and optionally a third sound emitter (e.g., third buzzer) in the third ensemble emits sounds (e.g., and buzzers in the other ensembles emit sound). The sounds are picked up in a first sound sensor of the first ensemble (e.g., and at the third, and at other sounds sensors). If detection of the signals of the second buzzer (e.g., and other buzzer(s)) at the first sound sensor undergoes a detectable (e.g., and significant above a threshold) change from past detection of that buzzer signal(s), then there is a high likelihood that (i) there is a fault in the first sound sensor, or (ii) there is a change in, or adjacent to, the first ensemble (e.g., due to an obstruction and/or fixture change). This likelihood increases when another sound sensor in another ensemble located at another known location senses the sound emitter(s) sounds without change. When performing the foregoing operations, a likelihood of a single outcome is more probable as follows:
A: When the first buzzer appears to emit altered signals (as picked up by the second, third, and/or other sound sensors), and the first sensor picks up other buzzer signals substantially the same as in the past, then there is a high likelihood that the first buzzer is faulty, and
B: When the first sensor appears to detect altered signals (emitted by the second, third, and/or other buzzers), and the first buzzer emits buzzing sounds (as detected by the second, third, and/or other sensors) substantially the same as in the past, then there is a high likelihood that the first sensor is faulty.
C: When the first buzzer appears to emit altered signals (as picked up by the second, third, and/or other sound sensors), and when the first sensor appears to detect altered signals (emitted by the second, third, and/or other buzzers), then there is a high likelihood that there is a change in the transfer function due to an obstruction and/or change in fixture adjacent to the first ensemble.

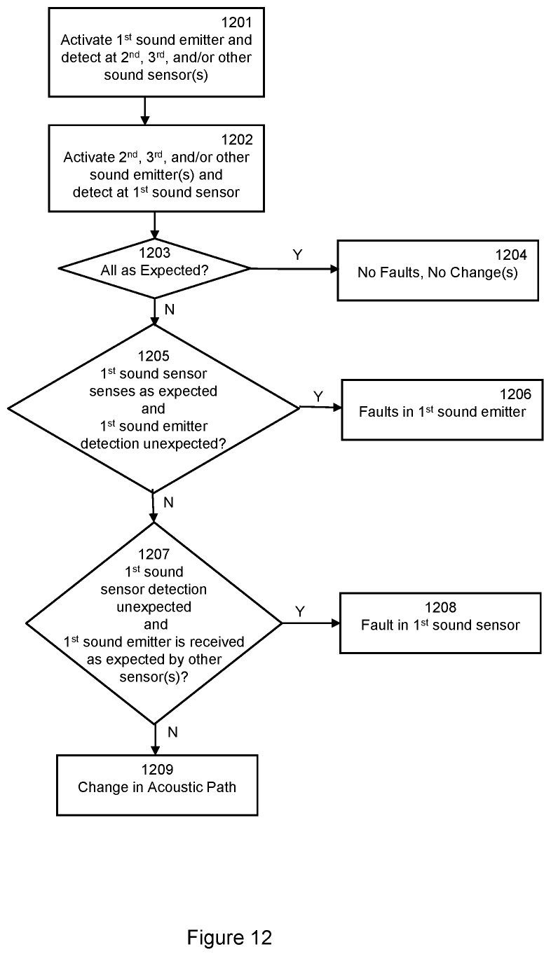

FIG. 12 shows an example of a flowchart depicting operations for acoustic mapping and fault detection. In block 1201, a first sound emitter is activated and corresponding sound is detected at one or more sound sensors at other locations (each paired sensor defining a respective sound path). The detected sounds are measured (e.g., a sound intensity is recorded at respective frequencies in a frequency swept signal). In block 1202, second, third, and/or other sound emitters are activated at second, third, and/or other locations respectively, which sound emitted is detected by a first sound sensor co-located with the first sound emitter (e.g., in a same device ensemble or digital architectural element). In a block 1203, the detected (e.g., measured and recorded) sounds (e.g., frequencies and/or intensities) are compared to an initial or other previously measured mapping of the corresponding sound paths. If each sound intensity is (e.g., substantially) as expected (e.g., the same as its previous measurement), then the process determines at block 1204 that there are no sensor/emitter (e.g., transducer) faults and there have been no changes in the acoustic properties of the sound paths. If a substantial change in sound detection is found (e.g., a particular sound intensity differs from its previous measurement by greater than a predetermined threshold difference) then a check is performed in block 1205 to determine whether the first sound sensor detected other sounds (e.g., from other sound emitters) as expected while the detections of the first emitter were unexpected (e.g., differed from previous tests by more than the threshold difference). If so, then the process determined at block 1206 that there is high likelihood of a fault in the first emitter. Otherwise, a check is performed in block 1207 to determine whether the first sound sensor detected unexpected attenuation of other sounds (e.g., from other sound emitters) while the detections of the first emitter (e.g., at the other sensors) were as expected. If so, then the process determines at block 1208 that there is a high likelihood of fault in the first sensor. Otherwise, it at block 1209 there is a determination of a high likelihood that there has been a change in the acoustic properties of the corresponding sound path. In cases any of the above high likelihood determination (e.g., at blocks 1206, 1208, and/or 1209), the system may send a notification or direct initiation of an appropriate corrective action that can be taken. For example, a technician can be sent to verify the situation of the suspected sensor, emitter, and/or surrounding. For example, a technician can be sent to replace the suspected sensor, and/or emitter. For example, a technician can be sent to record a change in the surrounding (e.g., in a BIM such as a Revit file).

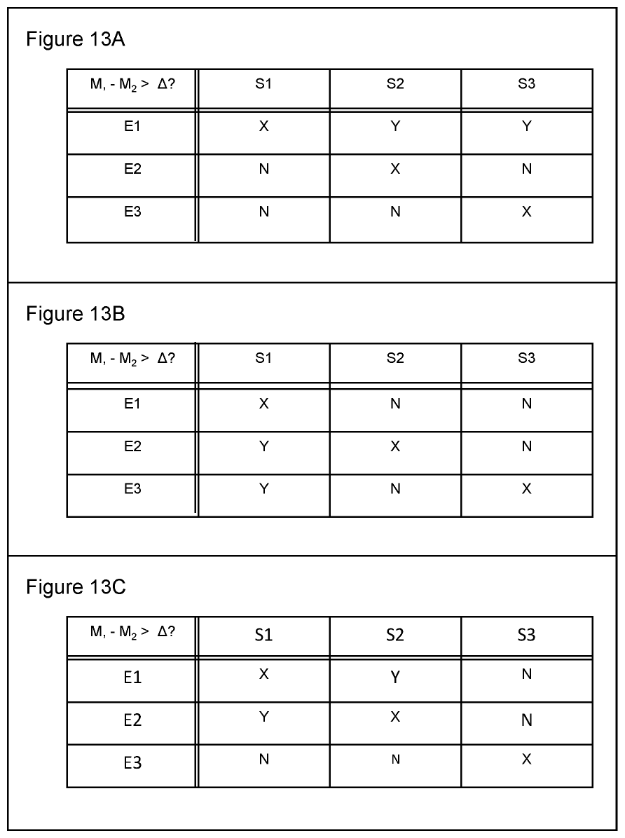

FIGS. 13A, 13B, and 13C show examples of decision matrices as embodiments in the flowchart of FIG. 12. For each respective pairing between a sound emitter E1, E2, and E3 and a sound sensor S1, S2, or S3, a cell in each matrix contains a “Y” (e.g., Yes) to indicate that an unexpected change has occurred (e.g., a difference between measured intensities M₁ and M₂ of certain sound frequency(ies) at first and second respective testing times is greater than a threshold difference Δ, designated by “M, −M₂>Δ”) or an “N” (e.g., No) if an unexpected change is not detected. The letter “X” signifies a non-applicable matrix rubric.

In FIG. 13A, a test signal emitted by sound emitter E1 at a first location results in unexpected changes in the sound sensed by sound sensors S2 and S3 at second and third locations. A change in a sensor refers to an alteration in a sound emitted by an emitter that is sensed by the sensor, as compared to historic measurement(s) of a sound previously emitted by the emitter, which was sensed by that sensor. A test signal emitted by sound emitter E2 at the second location results in no changes in the sound as sensed at sound sensors S1 and S2 at the first and second locations. Thus, one test signal along the first acoustic path between the first and second locations resulted in a change and another test signal sent in the opposite direction resulted in no change. Therefore, it is likely that sound emitter E1 and/or sensor S1 is faulty. By considering the third location, a determination with high likelihood may be made as to which sound emitter is faulty. A faulty sound emitter emits a faulty sound in frequency and/or intensity. Since the emitted test signal from emitter E1 also resulted in a changed result at sensor S3, and since the emitted test signal from emitter E3 resulted in no change at sensor S1, it may be deduced that sound emitter E1 is faulty with high likelihood.

FIG. 13B shows an example of a test signal emitted by sound emitter E1 at a first location results in no change in the sound sensed by sound sensors S2 and S3 (as compared to historic measurements). A test signal emitted by sound emitter E2 at the second location results in an unexpected change in the sound sensed by sound sensor S1. Thus, one test signal along the first acoustic path between the first and second locations resulted in no change and another test signal sent in the opposite direction resulted in an unexpected change. Therefore, it is likely that sound emitter E1 and/or sound sensor S1 is faulty. Since the emitted test signal from sound emitter E1 resulted in no change in the sound sensed by sound sensor S3, and since the emitted test signal from sound emitter E3 resulted in an unexpected change in the sound sensed by sound sensor S1, it may be deduced that sound sensor S1 is faulty with high likelihood.

FIG. 13C shows an example of a test signal emitted by sound emitter E1 results in an unexpected change in the sound sensed by sound sensor S2 but no change in the sound sensed by sound sensor S3. A test signal emitted by sound emitter E2 results in an unexpected change in the sound sensed by sound sensor S1 but no change in the sound sensed by sound sensor S3. Therefore, it is unlikely that either sound emitter E1 or sound sensor S1 is faulty. Since a signal emitted by sound emitter E1 is sensed at sound sensor S3 with no detected change (as compared to historic detection) and since a signal emitted by sound emitter E3 is sensed at sensor S1 with no detected change (as compared to historic detection), it is unlikely that sound emitter E1 or sound sensor S1 would be faulty. Thus, there is a high likelihood that a change has been made (e.g., in the surrounding) that affects the acoustic path.

In some embodiments, an ability to differentiate between a faulted transducer and an actual change in acoustic properties is obtained (e.g., with high likelihood) without requiring a co-location pairing of emitters and sensors. Emitters and sensors may be separately and/or arbitrarily placed, provided that there is sufficient overlap of their operational zones (e.g., each emitter can be receivable by one or more sensors and the sensor is able to receive by one or more emitters). Acoustic mapping may proceed, for example, by considering measured attenuation between each respective pairing of an emitter and a sensor at locations within a normally receivable range. When a significant change between present and past (e.g., historic) attenuation measurements is found for any particular pairing, then the sensors at locations where the same emitter is receivable may be analyzed (e.g., evaluated and/or checked) to determine whether they detected a similar change. The lack of a similar change may indicate the possibility of a fault in the sensor of the particular pairing. In addition, other measurements from the sensor of the particular pairing made in response to other emitters may be analyzed (e.g., evaluated and/or checked) to determine whether they detected a similar change. A similar change for all measurements made by the sensor of the particular pair may indicate the possibility of a fault in that sensor. Furthermore, a possible emitter fault may be detected by checking whether it is true that (A) all the sensors within a receivable range of the particular emitter detected a similar change, and (B) all the sensors detected no substantial change for (e.g., any) other emitters. In some embodiments, a suspicion or detection of a fault may be reported (e.g., via an immediate notification or a periodic report). When no potential fault conditions are discovered, then updated acoustic properties may be analyzed (e.g., and if detected, also reported and/or updated in the BIM).

In some embodiments, the availability of a mapping of acoustic properties in an enclosure enable the detection and/or characterization of predetermined sound events (e.g., loud and/or abrupt sounds being detected for building safety, health, and/or security purposes). For example, a location of a sound event and/or a classification of the sound may be (e.g., automatically) detected. While a single sensor (e.g., microphone) may be able to record a sound that is then compared to prototypical sound samples for possible classification, the localization may only be within a range of the microphone, and the classification accuracy may limited. Using the network of overlapping sensor zones and the mapping of acoustic properties of an environment, the localization and/or classification of a sound event may be greatly improved. The sound event may have a (e.g., predetermined) sound signature. The sound event may be an emergency event. The sound event may be a plea for help. In some embodiments, the occurrence of the event have two or more level of classification. For example, a general even type (e.g., cough, wind, breakage, gun-shot, or explosion), and event type. In some embodiments, on origin (e.g., point or area) of the sound may be detectable. For example, an occurrence of a gun-shot, the type of gun-shot, and an origin of gun-shot (e.g., floor, room, location w/i a room, or window) can be detected (e.g., wherever there is sufficient acoustic mapping resolution). For example, a sound event may be recognizable as cough, which may be characterized according to cough type (e.g., dry vs. wet cough, deep vs shallow), and location of cough origin (e.g., floor, room, or location w/i a room) depending on mapping resolution. In some embodiments, a cough detection differentiates between types of coughs, e.g., Covid-19 cough, pneumonia cough, or common cold cough. Other types of sound events (e.g., screams) may be enumerated as accompanied by a prototypical pattern or other kinds of acoustical recognition. For example, an abrupt and/or intense sound due to: wind (e.g., due to hurricane, tornado, tsunami, typhoon, or derecho), earthquake (e.g., Tectonic, volcanic, collapse, or explosion), explosion, breakage (e.g., of a fixture such as window or wall), or volcanic eruption. At times steps may be detected (e.g., running direction of a person can be tracked). In some embodiments, a potential sound event is detected in response to a sound of interest (e.g., an irregular (e.g., loud and/or abrupt) sound burst) detected (e.g., substantially) simultaneously at two or more sensors. The relative detected sound intensities at the sensors may be used to interpolate a location where the sound was generated (e.g., having a generation signature) and/or where it is most intense. In some embodiments, before, during, and/or after, attempting to classify the sound event, it is compensated according to the known acoustical transfer function(s) of the sound paths, e.g., from the interpolated location of the sound to the locations of the sensors. For example, the acoustic transfer function may involve greater attenuation at certain frequencies and/or intensities. The compensation may include applying an inverse transfer function which boosts a sound signal at the frequencies attenuated by the sound path. Compensated sound signals from different sensors may be combined prior to classification (e.g., pattern recognition or matching) to further improve the accuracy of recognition. When a predetermined sound event is recognized, it may be reported to a user and/or some types of events may have corresponding automatic mitigating actions that may be taken (e.g., activating an alarm). The sound event may be (e.g., automatically and/or manually) notified to (e.g., all) enclosure occupants (e.g., via their mobile devices and/or ID tags), to enclosure owners, to enclosure lessor, to enclosure lessee, to authorities (e.g., police, firefighters, hospitals). The notification may be an electronic notification (e.g., to e-mail and/or mobile devices of the notified personnel). A notification may be issued to an individual, to a population within the enclosure, and/or remotely (e.g., to authorities such as police, fire, health officials, building owner, tenants, building manager).

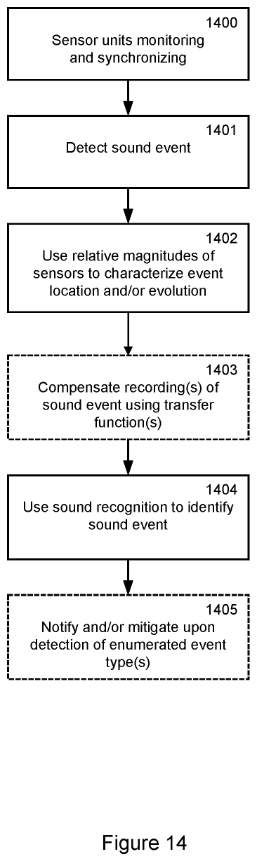

FIG. 14 shows an example of a flowchart for detecting irregular sound events. In block 1400, a network of sensors continuously monitors zones of an enclosure for sound signatures (e.g., loud and/or abrupt sounds). Sensor units may be synchronized such that when one sensor detects a potential sound event in block 1401 it subsequently notifies other (e.g., adjacent) sensor units that can confirm whether the potential sound event was likewise detected and/or manner of its evolution. When multiple sensors detected the event (e.g., including its evolution overtime), the relative sound intensity(ies) and/or frequency(ies) at each sensor location is used to interpolate a location for the sound event in block 1402 and/or its propagation (e.g., evolution) in space and/or time. Using the location of the sound event and the known locations of the sensor units, one or more corresponding sound paths are identified. The location and sound signature at the various sensors may aid in locating the source, or the location having the greatest event intensity. Sound sample data as recorded by the sensors can be optionally compensated according to the acoustical transfer function for each corresponding sound path in block 1403. In block 1404, sound recognition techniques are used to identify a type of sound event (e.g., optionally using classification of the compensated sound data and/or the originally detected sound data). In block 1405, a notification of the sound event is optionally generated and/or a corresponding mitigation action is taken according to the type of sound event.

In some embodiments, additional sensor(s) are added to the (e.g., deployed) sound sensors and emitters (speaker/microphone). An DAE can include a sound sensor and/or a sound emitter. In some embodiments, a sensor ensemble includes an accelerometer to detect motion of the enclosure structures. Accelerometer data may be used to correlate readings of different sensors. It may be used to subtract outside noises impacting at least a portion of the (e.g., the whole) facility. A sound emitter (e.g., speaker) can be disposed outside of the enclosure (e.g., facility) in an external ambient environment (e.g., to probe the effects that noise external to the enclosure may have on the interior acoustics of the enclosure). For example, an exterior emitter may be used to test the acoustics of a wall, a window, a ceiling, a floor and/or other building features. Based on such tests, a building owner, tenant, or system installer may make adjustments in space (e.g., locations for types of uses such as private offices, conference rooms, etc.) considering the sound mapping. The use of the enclosure may be adjusted for acoustic privacy and/or lack thereof depending on room type specification, and/or area or point of interest. The selection of locations for sound emitters and sensors (e.g., device ensembles) to be used for continuous monitoring may be adjusted according to a mapping based at least in part on exterior noises. Generally, mounting on lower side walls may be subject to hindrance by occupants and/or furniture while mounting toward the tops of walls may have little hindrance from occupants and/or furniture.

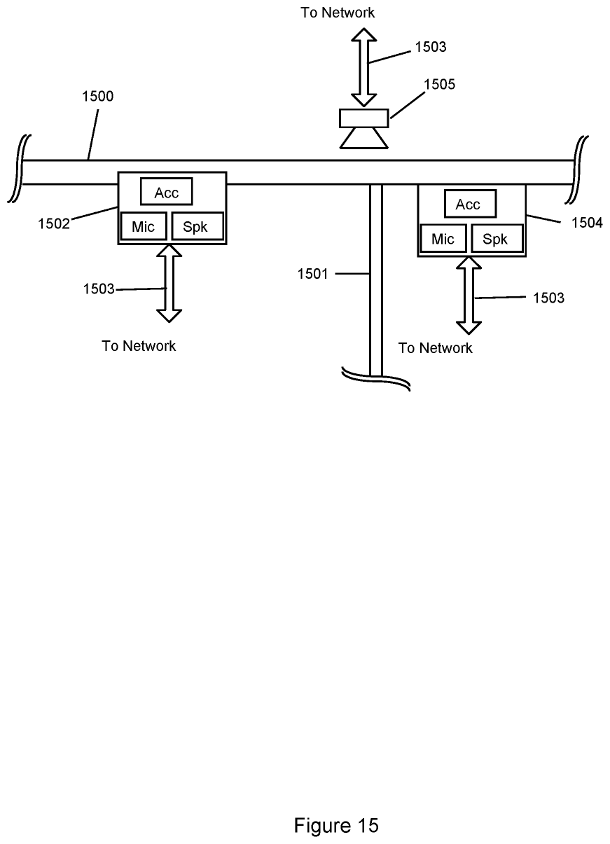

FIG. 15 shows a horizontal cross sectional example of digital architectural elements DAEs (e.g., device ensembles) and processing system for an enclosure with an exterior wall 1500 and an interior wall 1501. A DAE 1502 provides a first digital architectural element with network connection 1503 (arrows designating bidirectional communication) as part of a network of the enclosure (e.g., a control network as disclosed herein). A second DAE (digital architectural element) 1504 in another room separated by interior wall 1501 is also connected to the network by network connection 1503. An exterior emitter 1505 emplaced outside the enclosure is also connected in the network by network connection 1503. DAEs 1502 and 1504 each includes respective emitters (speaker abbreviated as “Spk”), sound sensors (e.g., microphone abbreviated as “Mic”), and accelerometers (abbreviated as “Acc”). Even though separated by interior wall 1501, sounds emitted by one DAE may be receivable at the other during a data collection event.

As explained herein, digital elements may be provided in various formats and housings that allow, as the purpose dictates, installation on building structural elements, which may include permanent elements (e.g., fixtures), and/or on building walls, floors, ceilings, mullion, transoms, any other frame portion, openings, or roofs. In various embodiments, the chassis or housing of a digital element is no greater than about 5 meters in any dimension, or no greater than about 3 meters in any dimension. The digital architectural element may have a housing with a lid. The lid (e.g., configured to face the interior of the enclosure) can have an aspect ratio that is 1:1. The lid can have an aspect ratio that differs from 1:1. The lid can have an aspect ratio of 1:X, where X is at least about 1, 2, 3, 4, 5, 6, or 8. In various embodiments, the housing is rigid or semi-rigid and encompasses some or all components of the DAE. In some cases, the housing provides a frame and/or scaffold for attaching one or more components including a speaker, a display, an antenna, and/or a sensor. In some embodiments, the housing provides external access to one or more ports or cables such as ports or cables for attaching to network links, video displays, mobile electronic devices, power, battery chargers, etc.

Window controller networks and associated digital elements may be installed during and/or upon construction (e.g., relatively early in the construction) of the enclosure (e.g., office buildings and other types of buildings). The network (e.g., control network) can be installed before any other network, e.g., before networks for other building functions such as Building Management Systems (BMSs), security systems, Information Technology (IT) systems of tenants, etc. The network can be installed before, during, and/or after construction of the enclosure.

In certain embodiments, sensors on a window network are installed close to where building occupants spend their time, thereby improving the sensors' effectiveness in providing occupant comfort. As discussed below, digital elements as described herein that are connected to a high bandwidth network may be deployed in various locations throughout a building. Examples of such locations include building structural elements in offices, lobbies, mezzanines, bathrooms, stairwells, terraces, and the like. Within any of these locations, digital elements may be positioned and/or oriented proximate to occupant positions, thereby collecting environment data that is most appropriate for triggering building systems to act in a way maintain or enhance occupant comfort.

In some embodiments, a digital architectural element (DAE) contains sensor(s), emitter(s), a circuitry (such as a processor (e.g., a microcontroller)), a network interface, and/or one or more peripheral interfaces. Examples of DAE sensor include light sensor, optionally including image capture sensor such as camera, audio sensor such as voice coils or microphones, air quality sensor, and/or proximity sensor (e.g., certain IR and/or RF sensors). The network interface may be a high bandwidth interface such as a gigabit (or faster) Ethernet interface. Examples of DAE peripherals include video display monitors, add-on speakers, mobile devices, battery chargers, and the like. Examples of peripheral interfaces include standard Bluetooth modules, ports such as USB ports network ports, power ports, image ports, etc. Ports may include any of various proprietary ports for third party devices.

In certain embodiments, the digital architectural element works in conjunction with other hardware and/or software provided for an optically switchable window system and/or a display on window. In certain embodiments, the digital architectural element includes a local (e.g., window) controller or other controller such as a master controller, a network controller, etc.

In certain embodiments, a digital architectural element includes one or more signal generating device such as a speaker, a light source (e.g., and LED), a beacon, an antenna (e.g., a Wi-Fi or cellular communications antenna), and the like. In certain embodiments, a digital architectural element includes an energy storage component and/or a power harvesting component. For example, an element may contain one or more batteries or capacitors as energy storage devices. Such elements may additionally include a photovoltaic cell. The DAE may include a power source, or may be operatively coupled to a power source (e.g., via a connector). In one example, a digital architectural element has one or more user interface components (e.g., a microphone or a speaker), and one more sensors (e.g., a proximity sensor), as well a network interface for a high bandwidth communications.

In various embodiments, a digital architectural element is designed or configured to attach to, or otherwise be collocated with, a structural element of building. In some cases, a digital architectural element has an appearance that blends in with the structural element with which it is associated. For example, a digital architectural element may have a shape, size, and color that blends with the associated structural element. In some cases, a digital architectural element is not easily visible to occupants of a building; e.g., the element is fully or partially camouflaged. However, such element may interface with other components that do not blend in such as video display monitors, touch screens, projectors, and the like.

The building structural elements to which digital architectural elements may be attached include any of various building structures. In certain embodiments, building structures to which digital architectural elements attach are structures that are installed during building construction, in some cases early in building construction. In certain embodiments, the building structural elements for digital architectural elements are elements that serve as a building structural function. Such elements may be permanent, i.e., not easy to remove from a building such as fixtures. Examples include walls, partitions (e.g., office space partitions), doors, beams, stairs, façades, moldings, mullions and transoms, etc. In various examples, the building structural elements are located on a building or room perimeter. In some cases, digital architectural elements are provided as separate modular units or boxes that attach to the building structural element. In some cases, digital architectural elements are provided as façades for building structural elements. For example, a digital architectural element may be provided as a cover for a portion of a mullion, transom, or door. In one example, a digital architectural element is configured as a mullion or disposed in or on a mullion. If it is attached to a mullion, it may be bolted on or otherwise attached to the rigid parts of the mullion. In certain embodiments, a digital architectural element can snap onto a building structural element. In certain embodiments, a digital architectural element serves as a molding, e.g., a crown molding. In certain embodiments, a digital architectural element is modular; i.e., it serves as a module for part of a larger system such as a communications network, a power distribution network, and/or computational system that employs an external video display and/or other user interface components.

In some embodiments, the digital architectural element is a digital mullion designed to be deployed on some but not all mullions in a room, floor, or building. In some cases, digital mullions are deployed in a regular or periodic fashion. For example, digital mullions may be deployed on every sixth mullion.

In certain embodiments, the DAE may be configured for a high bandwidth network connection (port, switch, router, etc.) and have a housing. The digital architectural element may include the following digital and/or analog component(s): a camera, a proximity and/or movement sensor, an occupancy sensor, a color temperature sensor, a biometric sensor, a speaker, a microphone, an air quality sensor, a hub for power and/or data connectivity, display video driver, a Wi-Fi access point, an antenna, a location service via beacons or other mechanism, a power source, a light source, a processor and/or ancillary processing device.

One or more cameras may include a sensor and processing logic for imaging features in the visible, IR (see use of thermal imager below), or other wavelength region; various resolutions are possible including high definition (e.g., HD) and greater such as at least about 2K, 4K, 6K, 8K, or 10K resolution (one thousand is abbreviated as “K”).

One or more proximity and/or movement sensors may include an infrared sensor, e.g., an IR sensor. In some embodiments, a proximity sensor is a radar or radar-like device that detects distances from and between objects using a ranging function. Radar sensors can also be used to distinguish between closely spaced occupants via detection of their biometric functions, for example, detection of their different breathing movements. When radar or radar-like sensors are used, better operation may be facilitated when disposed unobstructed or behind a plastic case of a digital architectural element.

One or more occupancy sensor may include a multi-pixel thermal imager, which when configured with an appropriate computer implemented algorithm can be used to detect and/or count the number of occupants in a room. In one embodiment, data from a thermal imager or thermal camera is correlated with data from a radar sensor to provide a better level of confidence in a particular determination being made. In embodiments, thermal imager measurements can be used to evaluate other thermal events in a particular location, for example, changes in air flow caused by open windows and doors, the presence of intruders, and/or fires.

One or more color temperature sensors may be used to analyze the spectrum of illumination present in a particular location and to provide outputs that can be used to implement changes in the illumination as needed or desired, for example, to improve an occupant's health or mood.

One or more biometric sensor (e.g., for fingerprint, retina, or facial recognition) may be provided as a stand-alone sensor or be integrated with another sensor such as a camera.

One or more speakers and associated power amplifiers may be included as part of a digital architectural element or separate from it. In some embodiments, two or more speakers and an amplifier may, collectively, be configured as a sound bar; e.g., a bar-shaped device containing multiple speakers. The device may be designed or configured to provide high fidelity sound.

One or more microphones and logic for detecting and processing sounds may be provided as part of a digital architectural element or separate from it. The microphones may be configured to detect one or both of internally or externally generated sounds. In one embodiment, processing and analysis of the sounds is performed by logic embodied as software, firmware, or hardware in one or more digital structural element and/or by logic in one or more other devices coupled to the network, for example, one or more controllers coupled to the network. In one embodiment, based on the analysis, the logic is configured to automatically adjust a sound output of one or more speaker to mask and/or cancel sounds, frequency variations, echoes, and other factors detected by one or more microphone that negatively impact (or potentially could negatively impact) occupants present in a particular location within a building. In one embodiment, the sounds comprise sounds generated by, but not limited to: indoor machinery, indoor office equipment, outdoor construction, outdoor traffic, and/or airplanes.

In embodiments, one or more microphones are positioned on, or next to, windows of a building; on ceilings of the building; and/or or other interior structures of the building. The logic may be configured in a singular or arrayed fashion to analyze and determine the type, intensity, spectrum, location and/or direction interior sounds present in a building. In one embodiment, the logic is functionally connected to other fixed or moving network connected devices that may be being used in a building, for example, devices such as computers, smart phones, tablets, and the like, and is configured to receive and analyze sounds or related signals from such devices.

In one embodiment, the logic is configured to measure and analyze real time delays in signals from microphones to predict the amount and type of sound needed to mask or cancel unwanted external and/or internal sound present at a particular location in the building. In one embodiment, the logic is configured to detect changes in the level and/or location of the unwanted external and/or internal sound where, for example, the changes can be caused by movements of objects and people within and outside a building, and to dynamically adjust the amount of the masking and/or canceling sound based on the changes. In one embodiment, the logic is configured to use signals from tracking sensors in a building and, according to the signals, to cause the masking and/or canceling sounds to be increased or decreased at a particular location in the building according to a presence and/or location of one or more occupant. In one embodiment, one or more of the speakers are positioned to generate masking and/or canceling sounds that propagate substantially in a plane of travel of unwanted sound, including in a horizontal plane, vertical plane, and/or combinations of the two.

In one embodiment, the logic comprises a calculation and/or an algorithm designed to acoustically map an interior of a building, to locate in-office noise source locations, and to improve speech privacy. In one embodiment, after an array of speakers and microphones is installed in a building, the logic may be used to perform an acoustical sweep so as to cause each speaker to generate sound that in turn is detected by each microphone. In one embodiment, time delays, sound level decreases, and spectrum differences in the detected sounds are used to calculate and map effective acoustical distances between speakers, microphones, and between them. In one embodiment, an acoustical transfer function of an interior of a building map may be obtained from the acoustical sweep. With such an acoustical map and set of transfer functions of one or more space within a building, the logic can make appropriate masking and/or canceling level determinations when sources of unwanted sounds generated in the spaces are present. When needed, the logic can adjust speaker generated sounds to correct for absorption of certain absorptive surfaces, for example, a sound that may otherwise be sound muffled bouncing off of a soft partition can be adjusted to sound crisp again. The acoustical map of a space can also be used to determine what is direct versus indirect sound and adjust time delays of masking and/or canceling sounds so that they arrive at a desired location at the same time.

One or more air quality sensor s (optionally able to measure one or more of the following air components: volatile organic compounds (VOC), carbon dioxide temperature, humidity) may be used in conjunction with HVAC to improve air circulation control. One or more hubs for power and/or data connectivity to sensor(s), speakers, microphone, and the like may be provided. The hub may be a USB hub, a Bluetooth hub, etc. The hub may include one or more ports such as USB ports, High Definition Multimedia Interface (HDMI) ports, etc. The element may include a connector dock for external sensors, light fixtures, peripherals (e.g., a camera, microphone, speaker(s)), network connectivity, power sources, etc.

One or more Wi-Fi access points and antenna(s), which may be part of the Wi-Fi access point or serve a different purpose. In certain embodiments, the architectural element itself or faceplate that covers all or a portion of the architectural element serves as an antenna. Various approaches may be employed to insulate the architectural element and make it transmit or receive directionally. Alternatively, a prefabricated antenna may be employed or a window antenna as described in International Patent Application Serial No. PCT/US17/31106, filed May 4, 2017, incorporated herein by reference in its entirety.

One or more power sources such as an energy storage device (e.g., a rechargeable battery or a capacitor), and the like may be provided. In some implementations, a power harvesting device is included; e.g., a photovoltaic cell or panel of cells. This allows the device to be self-contained or partially self-contained. The light harvesting device may be transparent or opaque, depending on where it is attached. For example, a photovoltaic cell may be attached to, and partially or fully cover, the exterior of a digital mullion, while a transparent photovoltaic cell may be cover a display or user interface (e.g., a dial, button, etc.) on the digital architectural element.

One or more light sources (e.g., light emitting diodes) configured with the processor to emit light under certain conditions such signaling when the device is active.

One or more processors may be configured to provide various embedded or non-embedded applications. The processor may be a microcontroller. In certain embodiments, the processor is low-powered mobile computing unit (MCU) with memory and configured to run a lightweight secure operating system hosting applications and data. In certain embodiments, the processor is an embedded system, system on chip, or an extension.

One or more ancillary processing devices such as a graphical processing unit, or an equalizer or other audio processing device configured to interpret audio signals.

In some embodiments, a camera of a digital architectural element is configured to capture images in the visible portion of the electromagnetic spectrum. In some cases, the camera provides images in high resolution, e.g., high definition, of at least about 720 pixels or at least about 1080 pixels in one dimension. The camera resolution may be any camera resolution disclosed herein. In certain cases, the camera may also capture images having information about the intensity of wavelengths outside the visible range. For example, a camera may be able capture infrared signals. In certain implementations, a digital architectural element includes a near infrared device such as a forward looking infrared (FLIR) camera or near-infrared (NIR) camera. Examples of suitable infrared cameras include the Boson™ or Lepton™ from FLIR Systems, of Wilsonville, OR. Such infrared cameras may be employed to augment a visible camera in a digital architectural element.

In some embodiments, the camera may be configured to map the heat signature of a room such that it may serve as a temperature sensor with three-dimensional awareness. In some implementations, such cameras in a digital architectural element enable occupancy detection, augment visible cameras to facilitate detecting a human instead of a hot wall, provide quantitative measurements of solar heating (e.g., image the floor or desks and see what the sun is actually illuminating), etc.

In some embodiments, the speaker, microphone, and associated logic are configured to use acoustic information to characterize air quality or air conditions. As an example, an algorithm may issue ultrasonic pulses, and detect the transmitted and/or reflected pulses coming back to a microphone. The algorithm may be configured to analyze the detected acoustic signal, sometimes using a transmitted vs. received differential audio signal, to determine air density, particulate deflection, and the like to characterize air quality.

In some embodiments, an enhanced functionality window controller (WC3) may include a Wi-Fi access point, and optionally also has cellular communications capability. It is often configured to connect to multiple networks (e.g., a Controller Area Network (CAN) bus and Ethernet).

In some embodiments, an enhanced functionality local (e.g., window) controller may have the basic structure and function as described above herein, but with an added gigabit Ethernet interface and a processor with enhanced computing power. As with more conventional window controllers, the enhanced functionality window controller may have a CAN bus interface or similar controller network. In some embodiments, the controller has video capability and/or may include features described in U.S. patent application Ser. No. 15/287,646, filed Oct. 6, 2016, which is incorporated herein by reference in its entirety.

In some embodiments, the enhanced functionality local (e.g., window) controller is implemented as a module having (i) a processor with sufficiently high processing power to handle video and other functions requiring significant processing power, (ii) an Ethernet connection, (iii) optionally video processing capabilities, (iv) optionally a Wi-Fi access point or other wireless communications capability, etc. This module may be attached to a base board having other, more conventional, window controller functionality such as a power amplifier or another baseboard that is used with a (e.g., ring) sensor. The sensor may be disposed externally or internally to the enclosure. The sensor may be disposed in the ambient environment external to the enclosure. The resulting device may be used to control an optically switchable window, or it may be used simply provide wireless communications, video, and/or other functions not necessarily associated with controlling the states of optically switchable windows.

In some embodiments, the enhanced functionality window controller is provisioned, controlled, alarmed, etc. by a CAN bus or similar controller network protocol, as with a conventional window controller described herein, but additionally it provides video, Wi-Fi, and/or other extra functions.

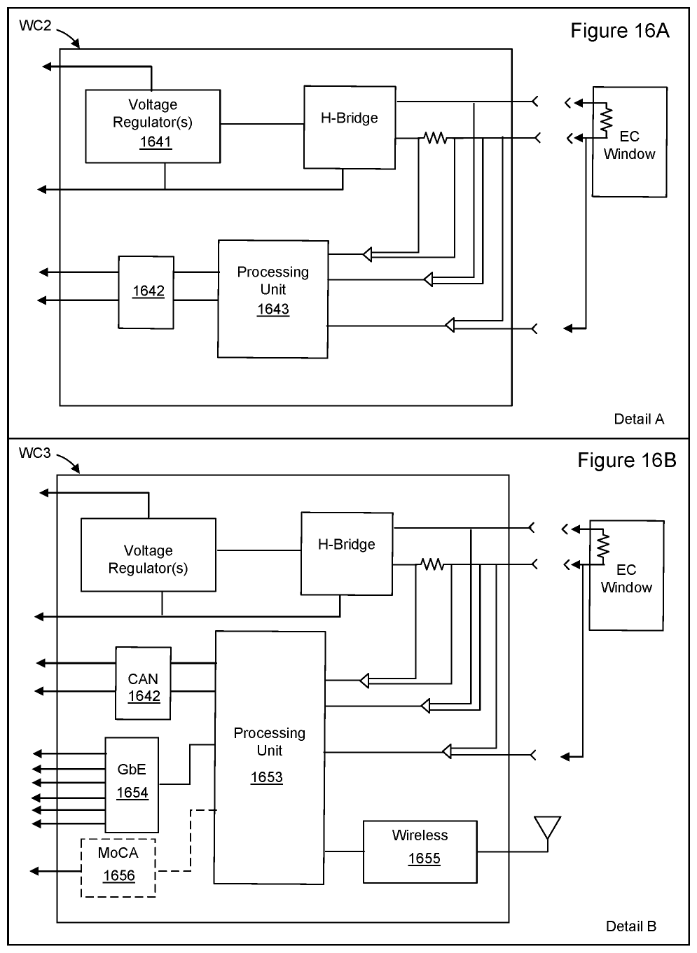

FIG. 16A illustrates an example of a comparison between a block diagram of a local controller that is a window controller WC2 (Detail A) and, according to some implementations a block diagram of a WC3 (Detail B). The WC2 block diagram is an example of a conventional window controller such as those available from View, Inc. of Milpitas, CA. Some of the depicted components include at least one voltage regulator 1641, a controller network interface, CAN 442 a processing unit (microcontroller) 1643, and various ports and connectors. Some of these components and example architectures are described in U.S. patent application Ser. No. 13/449,251, filed Apr. 17, 2012, and U.S. patent application Ser. No. 15/334,835, filed Oct. 26, 2016, which are incorporated herein by reference in their entireties.

FIG. 16B depicts an example of an enhanced functionality local controller that is a window controller, WC3. In the depicted embodiments, the conventional window controller (WC 2) and the enhanced functionality window controller (WC3) have a similar architecture and some common components. The enhanced functionality window controller WC3 has a more capable microcontroller 1653, a gigabit Ethernet interface 1654, a wireless (e.g., Wi-Fi, Bluetooth or cellular) interface 1655 and an optional MoCA interface 1656. The gigabit Ethernet interface may be a conventional unshielded twisted pair (e.g., UTP/CAT5-6) interface and/or a MoCA (GbE over coaxial cable) interface. In some embodiments, connection to the enhanced functionality window controller is via a conventional RJ45 modular connector (jack). In certain embodiments that support MoCA, the controller includes a separate adaptor feeding the jack. As an example, such adaptor may be an Actiontec (Actiontec Electronics, Inc. of Sunnyvale, CA) adaptor such as the ECB6250 MoCA 2.5 network adapter, e.g., an adaptor that provides data communication speeds up to about 2.5 Gbps.

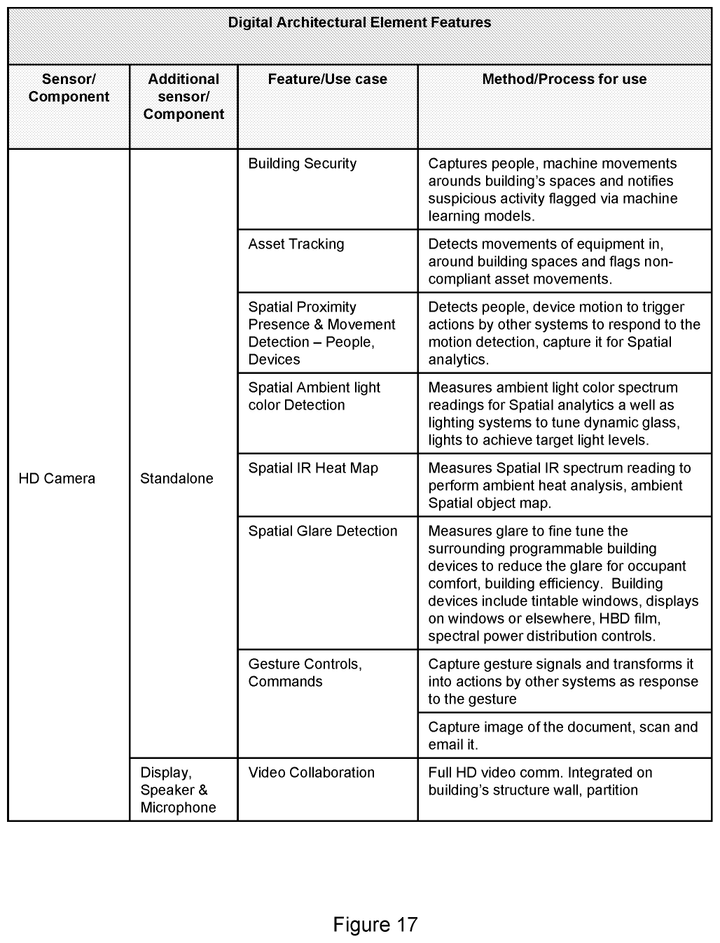

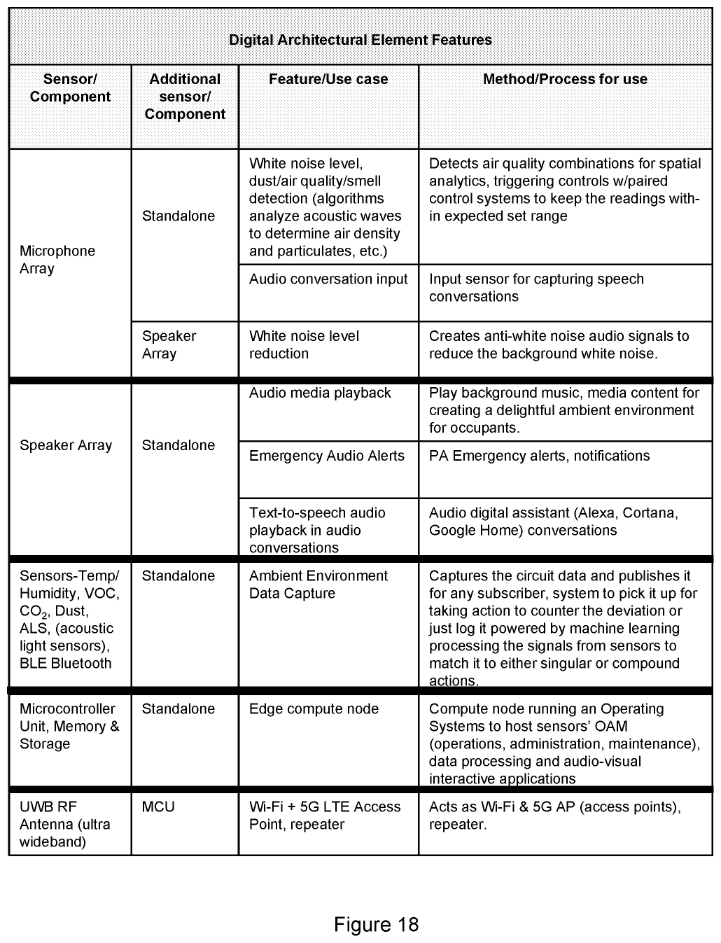

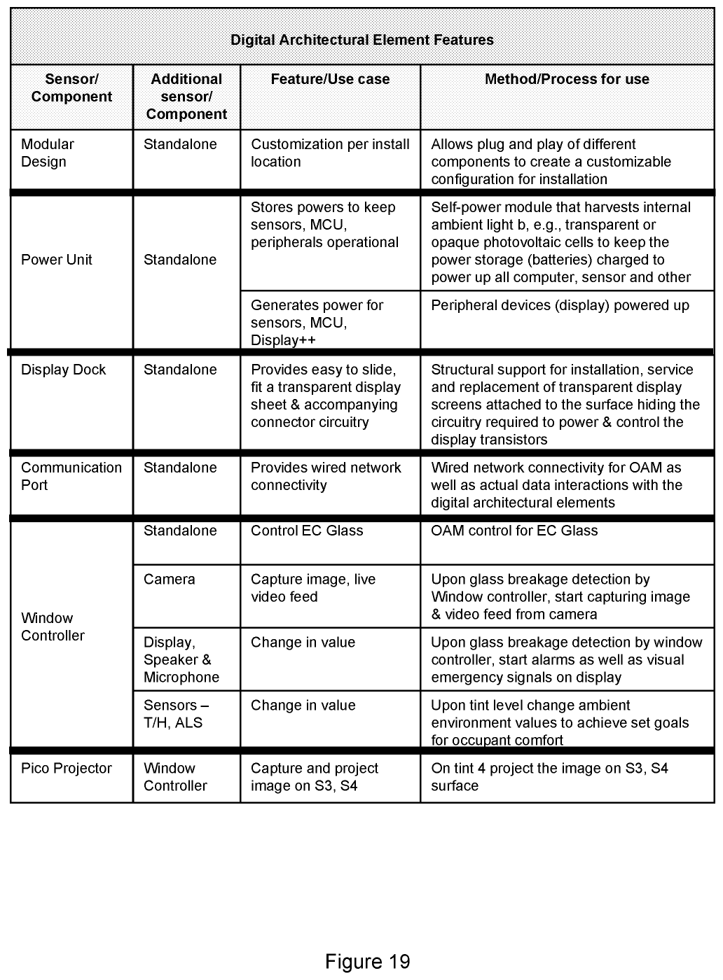

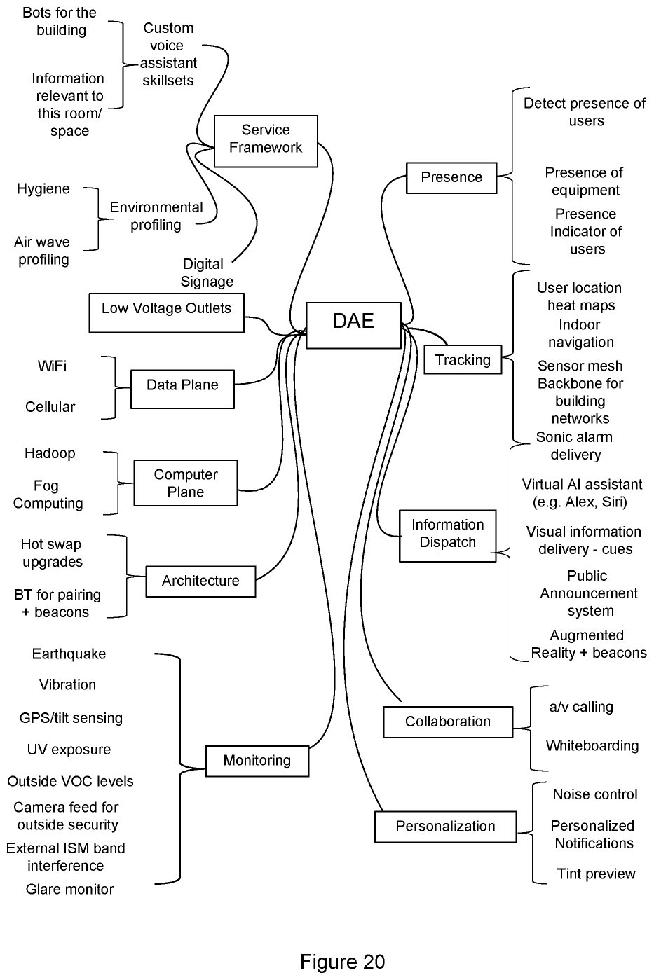

FIGS. 17 through 20 illustrate a number of examples of applications and uses of the digital architectural element and related elements contemplated by the present disclosure. It will be appreciated that the network and/or high bandwidth backbone described herein may be used for various functions, some of which are not related to controlling DAE, their components and/or windows. One such function is the providing of internet, local network, and/or computational services for tenants or other building occupants, construction personnel on site during the construction of the building, and the like. During construction, the network and computation resources provided by the backbone and digital elements may be used for more than commissioning windows. For example, they may be used to provide architectural information, construction instructions, and the like. In this way, construction personnel have ready access to construction information they need via a high bandwidth, on-site network.

In some embodiments, the network, communications, and/or computational services provided by the network and computational infrastructure as described herein are utilized in multi-tenant buildings or shared workspaces such as those provided by WeWork.com. For example, shared workspace buildings need only provide temporary connectivity and processing power as needed. A building network such as described herein affords central control and flexible assignment of computational resources to particular building locations. Such flexibility may allow assignment of different resources to different occupants (e.g., tenants).

Readings from sensor(s) in a digital element (e.g., a digital wall interface or a digital architectural element) may provide information about the enclosure environment, e.g., in the vicinity of the digital architectural element. Examples of such sensors include sensors for any one or more of temperature, humidity, volatile organic compounds (VOCs), carbon dioxide, dust, light level, glare, and color temperature. In certain embodiments, readings from one or more such sensors are input to an algorithm (e.g., comprising a calculation) that determines actions that other building systems should take, e.g., to offset the deviation in measured readings to get these readings to target values for occupant's comfort or building efficiency, depending on the contextual index of occupant's presence and other signals.

In some embodiments, a digital element may be provided on a roof of a building, optionally collocated with a sky sensor and/or a ring sensor such as described in U.S. patent application Ser. No. 15/287,646, filed Oct. 6, 2016, that is incorporated herein by reference in its entirety. Such element may be outfitted with some or all features presented elsewhere herein for a digital architectural element. Examples include sensors, antenna, radio, radar, air quality detectors, etc. In some implementations, the digital element on the roof or other building exterior location provides information about air quality and/; in this way, digital elements may provide information about the air quality both inside and outside of the enclosure, and/or about the weather. This allows decisions about window tint states and other environmental conditions to be made using a full set of information (e.g., when conditions outside the building are unhealthy (or at least worse than they are inside), a decision may be made prohibit venting air from outside).

In some embodiments, the light levels, glare, color temperature, and/or other characteristics of ambient or artificial light in a region of building are used to make decisions about whether to change the tint state of an electrochromic device. In certain embodiments, these decisions employ one or more algorithms or analyses as described in U.S. patent application Ser. No. 15/347,677, filed Nov. 9, 2016, and U.S. patent application Ser. No. 15/742,015, each which is incorporated herein by reference in its entirety. In one example, tinting decisions are made by using a solar calculator and/or a reflection model in conjunction with an algorithm for interpreting light information from sensors of the digital architectural element. The algorithm may in some cases use information about the presence of occupants, how many there are, and/or where they are located (data that can be obtained with a digital architectural element) to assist in making decisions about whether to tint a window and what tint state should be chosen. In some cases, for purposes of determining appropriate tint states, a digital architectural element is used in lieu of or in conjunction with a sky sensor such as described in U.S. patent application Ser. No. 15/287,646, filed Oct. 6, 2016, which is incorporated herein by reference in its entirety.

As an example of tint and glare control, sensors in a digital element may provide feedback about local light, temperature, color, glare, etc. in a room or other portion of a building. The logic associated with a digital element may then determine that the light intensity, direction, color, etc. should be changed in the room or portion of a building and may also determine how to effect such change. A change may be necessary for user comfort (e.g., reduce glare at the user's workspace, increase contrast, or correct a color profile for sensitive users) or privacy or security. Assuming that the logic determines that a change is necessary, it may then send instructions to change one or more lighting or solar components such as optically switchable window tint states, display device output, switched particle device film states (e.g., transparent, translucent, opaque), light projection onto a surface, artificial light output (color, intensity, direction, etc.), and the like. All such decisions may be made with or without assistance from building-wide tint state processing logic such as described in U.S. patent application Ser. No. 15/347,677, filed Nov. 9, 2016, and U.S. patent application Ser. No. 15/742,015, filed Jan. 4, 2018, each of which is incorporated herein by reference in its entirety.

An array of digital architectural elements in a building may form a mesh edge access network enabling interactions between building occupants and the building or machines in the building. When equipped with an appropriate network interface, a digital architectural element and/or a digital wall interface and/or an enhanced functionality window controller can be used as a digital compute mesh network node providing connectivity, communication, application execution, etc. within building structural elements (e.g., mullions) for ambient compute processing. It may be powered, monitoring and controlled in a similar or identical manner as an edge sensor node in a mesh network setup in the buildings. It may be used as gateway for other sensor nodes.

A non-exhaustive list of functions or uses for the high bandwidth window network and associated digital elements contemplated by the present disclosure includes: (a) Speaker phone—a digital wall interface or a digital architectural element may be configured to provide all the functions of a speaker phone; (b) Personalization of space—an occupant's preferences and/or roles may be stored and then implemented in particular locations where the occupant is present. In some cases, the preferences and/or roles are implemented only temporarily, when a user is at a particular location. In some cases, the preferences and/or roles remain in effect so long as the occupant is assigned a work space or living space; (c) Security—track assets, identify unauthorized presence of individuals in defined locations, lock doors, tint windows, untint windows, sound alarms, etc.; (d) Control HVAC, air quality; (e) communication with occupants, including public address notifications for occupants during emergencies; messages may be communicated via speakers in a digital element; (f) collaboration among occupants using live video; (g) Noise cancellation—E.g., microphone detects white noise, and the sound bar cancels the white noise; (h) Connecting to, streaming, or otherwise delivering video or other media content such as television; (i) Enhancements to personal digital assistants such as Amazon's Alexa, Microsoft's Cortana, Google's Google Home, Apple's Siri, and/or other personal digital assistants; (j) Facial or other biometric recognition enabled by, e.g., a camera and associated image analysis logic—determine the identification of the people in a room, not just count the number of people; (k) Detect color—color balancing with room lighting and window tint state; (I) Local environmental conditions detected and/or adjusted. Conditions may be determined using one or more of the following types of sensed conditions, for example: temperature & humidity, volatile organic compounds (VOC), CO₂, dust, smoke and lighting (light levels, glare, color temperature.

In some embodiments, data from at least two different sensors are used synergistically. The sensors can be of different type or of the same type. In some embodiments, data from at least two different device ensembles are used synergistically. The two different device ensemble can have the same sensors (e.g., the same sensor combination) or different sensors (e.g., a different sensor combination). The device ensemble may be deployed throughout an enclosure of the facility and/or across the facility.

In some embodiments, the window (e.g., tintable window) may have a pane configured to generate vibrations. In some embodiments, the window may contain, or may be operatively coupled to, a vibration generator. The vibration generator may be acoustic or mechanical. The vibration generator may comprise an actuator. The vibration generator may comprise a speaker. Vibration generators may operate synergistically. For example, a first window may include, or be operatively coupled to, a first vibration generator, and a second window may include, or be operatively coupled to, a second vibration generator. The first vibration generator and the second vibration generator may operate in tandem (e.g., synergistically or symbiotically). Operation of the first vibration generator may consider operation and/or status of the second vibration generator. Operation of the second vibration generator may consider operation and/or status of the first vibration generator. The consideration may include taking into account respective sensor(s) measurements (e.g., sensor(s) disposed in a framing of the window, or operatively coupled to the window). The sensor(s) may be incorporated in a device ensemble. The consideration may comprise using artificial intelligence (e.g., a learning module). The vibration generator and/or sensor(s) may be operatively coupled to the control system (e.g., of the facility). Operatively coupled may comprise electrically coupled, communicatively coupled, wirelessly coupled, and/or physically connected via wire(s). The consideration may comprise input of various sensors. At least two of the various sensor may be of the same type. At least two of the various sensors may be of a different type (e.g., different kind). At least two of the various sensors may be disposed in an enclosure (e.g., room) in which the first window and/or the second window is disposed. At one of the various sensors may be disposed in a different enclosure (e.g., room) from the one in which the first window and/or the second window is disposed. The sensor may be a sound sensor. The sound sensor may measure vibrations in the enclosure (e.g., room). The sounds sensor may measure vibrations arising from the window(s). The sound sensor may measure vibrations in the enclosure (e.g., different from the ones arising from the window(s)). The framing may comprise a mullion or a transom. The sensor may or may not be in direct contact with the window (e.g., whether an internally facing window-pane, or an externally facing windowpane).

In some embodiments, the artificial intelligence may comprise data analysis (e.g., data gathered by one or more sensors). The data analysis (e.g., analysis of the sensor measurements) may be performed by a machine based system (e.g., a circuitry). The circuitry may be of a processor. The sensor data analysis may utilize artificial intelligence. The sensor data analysis may rely on one or more models (e.g., mathematical models). In some embodiments, the sensor data analysis comprises linear regression, least squares fit, Gaussian process regression, kernel regression, nonparametric multiplicative regression (NPMR), regression trees, local regression, semiparametric regression, isotonic regression, multivariate adaptive regression splines (MARS), logistic regression, robust regression, polynomial regression, stepwise regression, ridge regression, lasso regression, elasticnet regression, principal component analysis (PCA), singular value decomposition, fuzzy measure theory, Borel measure, Han measure, risk-neutral measure, Lebesgue measure, group method of data handling (GMDH), Naive Bayes classifiers, k-nearest neighbors algorithm (k-NN), support vector machines (SVMs), neural networks, support vector machines, classification and regression trees (CART), random forest, gradient boosting, or generalized linear model (GLM) technique. The data analysis may comprise vector regression. The data analysis my comprise at least one software library. The software library may provide a regularizing gradient boosting framework The software library may be configured to provide a scalable, portable and/or distributed gradient boosting (GBM, GBRT, GBDT) library (e.g., XGBoost library). The software library may be configured to run on a single processor, as well as the distributed processing frameworks. The software library may be configured to offer clever penalization of trees, proportional shrinking of leaf nodes, Newton Boosting, extra randomization parameter, Implementation on single, distributed systems and out-of-core computation, and/or automatic Feature selection. The root-mean square error (RMSE) of the simulation as compared to real data may be at most about 5, 10, 15, 20, 25, 30, 35, 40, or 45.

In some embodiments, the control system may utilize a learning module (e.g., for environmental adjustment and/or forecasting such as for acoustic conditioning and/or forecasting). The learning module may comprise machine learning. The learning module may comprise a multilayer neural network (e.g., a deep learning algorithm). The learning module may include an unbounded number of layers of bounded size, e.g., to progressively extract higher-level features from the raw (e.g., sensor) input measurements. The layers in the multilayer neural network may be hierarchical (e.g., each layer's output may be a higher-level abstraction of inputs from previous layers). The learning module may utilize a heuristic technique (e.g., gross model and sensor data) that will accelerate outputting a reliable prediction as a result. The learning module may optimize for prediction accuracy and/or computational speed. The learning module may consider the neural network size (number of layers and number of units per layer), learning rate, and/or initial weights (e.g., of artificial neurons and/or algorithms (when several algorithms are utilized to generate the result)). The learning module may learn from measurements with respect to failure of tintable windows, by using sensor measurements (e.g., real time, historical, or synthetic sensor measurements).

In some embodiments, a learning module comprises a computational scheme, an algorithm and/or a calculation. The learning model may comprise machine learning, artificial intelligence (AI), and/or a statistical validation layer. The learning module can be trained to identify a threshold (e.g., value or function) for failure. Alternatively, the learning module may not be trained to identify a failure threshold. The learning module can be trained using historical, real-time, and/or synthesized data, used as a training set. A machine learning (ML) ensemble can be used to implement the learning module. The machine learning ensemble can include a plurality of models (e.g., at least about 2, 3, 4 5, 7, or 10 models) working together, e.g., using a voting scheme. At least two of the models in the plurality of models can be given different weights. At least two of the models in the plurality of models can be give the same weight. The ML ensemble can include at least one model. Usage of the ML ensemble may be automatic, scheduled, and/or controlled.

In some embodiments, the learning module incorporates a validation mechanism that is configured to perform data management. The learning module can utilize one or more models. One model (or model combination) may be more appropriate in a situation than another. For example, rare circumstances may require use of specific models. The model can use adaptive synthetic oversampling. The model can use deep learning techniques (e.g., convolutional neural networks). The model can use AI techniques that exclude deep learning algorithms and/or new AI techniques that include deep learning algorithms. The learning set may comprise real data. The learning set may comprise synthetic data. The synthetic data may be synthesized using real data. For example, the synthetic data may use a real data backbone to which different type of non-substantial information (e.g., noise) has been added. The non-substantial information (e.g., noise) may be characteristics to sensor measurements (e.g., of failed, failing, and/or properly functioning tintable windows). The learning model can use a temporal convolution neural network. The learning model can incorporate a computation scheme also utilized for analyzing visual imagery. The learning model can use data collected in a first enclosure (e.g., first facility), or from another second enclosure (e.g., from the same first facility of from another second facility). The second facility can be geographically separated (e.g., distant) from the first facility in which the first tintable window is disposed.

In some embodiments, the vibrations of the window are configured for sound dampening (e.g., reducing or block). The sounds may be noise (e.g., mechanical noise such as from a motor, or human generated noise). The noise may be external to the enclosure. The noise may be internal to the enclosure (e.g., arising from a motor in the enclosure). For example, the vibrations in the window (e.g., glass) may be configured to at least partially cancel out certain sound (e.g., certain vibrational frequencies). For example, the vibrations in the window (e.g., glass) may be configured to at least partially destructively interfere with sounds frequency (e.g., at least a portion of the frequencies are subject to destructive interference by vibrations created by the window). The vibrations may be optically measured (e.g., using a laser).

In some embodiments, vibrations generated in an enclosure (e.g., in a room) cause vibration of the window (e.g., of an internal pane of the window), which window vibrations may be measured and deciphered.

The presently disclosed logic and computational processing resources may be provided within a digital element such as a digital wall interface or a digital architectural element as described herein, and/or it may be provided via a network connection to a remote location such as another building using the same or similar resources and services, servers on the internet, cloud-based resources, etc.

Certain embodiments disclosed herein relate to systems for generating and/or using functionality for a building such as the uses described in the preceding “Applications and Uses” section. A programmed or configured system for performing the functions and uses may be configured to (i) receive input such as sensor data characterizing conditions within a building, occupancy details, and/or exterior environmental conditions, and (ii) execute instructions that determine the effect of such conditions or details on a building environment, and optionally take actions to maintain or change the building environment.

Many types of computing systems having any of various computer architectures may be employed as the disclosed systems for implementing the functions and uses described herein. For example, the systems may include software components executing on one or more general purpose processors or specially designed processors such as programmable logic devices (e.g., Field Programmable Gate Arrays (FPGAs)). Further, the systems may be implemented on a single device or distributed across multiple devices. The functions of the computational elements may be merged into one another or further split into multiple sub-modules. In certain embodiments, the computing system contains a microcontroller. In certain embodiments, the computing system contains a general purpose microprocessor. Frequently, the computing system is configured to run an operating system and one or more applications.

In some embodiments, code for performing a function or use described herein can be embodied in the form of software elements which can be stored in a nonvolatile storage medium (such as optical disk, flash storage device, mobile hard disk, etc.). At one level a software element is implemented as a set of commands prepared by the programmer/developer. However, the module software that can be executed by the computer hardware is executable code committed to memory using “machine codes” selected from the specific machine language instruction set, or “native instructions,” designed into the hardware processor. The machine language instruction set, or native instruction set, is known to, and essentially built into, the hardware processor(s). This is the “language” by which the system and application software communicates with the hardware processors. Each native instruction is a discrete code that is recognized by the processing architecture and that can specify particular registers for arithmetic, addressing, or control functions; particular memory locations or offsets; and particular addressing modes used to interpret operands. More complex operations are built up by combining these simple native instructions, which are executed sequentially, or as otherwise directed by control flow instructions.

The inter-relationship between the executable software instructions and the hardware processor is structural. In other words, the instructions per se are a series of symbols or numeric values. They do not intrinsically convey any information. It is the processor, which by design was preconfigured to interpret the symbols/numeric values, which imparts meaning to the instructions.

The algorithms used herein may be configured to execute on a single machine at a single location, on multiple machines at a single location, or on multiple machines at multiple locations. When multiple machines are employed, the individual machines may be tailored for their particular tasks. For example, operations requiring large blocks of code and/or significant processing capacity may be implemented on large and/or stationary machines.

In addition, certain embodiments relate to tangible and/or non-transitory computer readable media or computer program products that include program instructions and/or data (including data structures) for performing various computer-implemented operations. Examples of computer-readable media include, but are not limited to, semiconductor memory devices, phase-change devices, magnetic media such as disk drives, magnetic tape, optical media such as CDs, magneto-optical media, and hardware devices that are specially configured to store and perform program instructions, such as read-only memory devices (ROM) and random access memory (RAM). The computer readable media may be directly controlled by an end user or the media may be indirectly controlled by the end user. Examples of directly controlled media include the media located at a user facility and/or media that are not shared with other entities. Examples of indirectly controlled media include media that is indirectly accessible to the user via an external network and/or via a service providing shared resources such as the “cloud.” Examples of program instructions include both machine code, such as produced by a compiler, and files containing higher level code that may be executed by the computer using an interpreter.

The data or information employed in the disclosed methods and apparatus is provided in a digital format. Such data or information may include sensor data, building architectural information, floor plans, operating or environment conditions, schedules, and the like. As used herein, data or other information provided in digital format is available for storage on a machine and transmission between machines. Conventionally, data may be stored as bits and/or bytes in various data structures, lists, databases, etc. The data may be embodied electronically, optically, etc.

In certain embodiments, algorithms for implementing functions and uses described herein may be viewed as a form of application software that interfaces with a user and with system software. System software typically interfaces with computer hardware and associated memory. In certain embodiments, the system software includes operating system software and/or firmware, as well as any middleware and drivers installed in the system. The system software provides basic non-task-specific functions of the computer. In contrast, the modules and other application software are used to accomplish specific tasks. Each native instruction for a module is stored in a memory device and is represented by a numeric value.

As described herein, the presently disclosed techniques contemplate a network of digital architectural elements (DAE's) capable of collecting a rich set of data related to environmental, occupancy and security conditions of a building's interior and/or exterior. The digital architectural elements may include optically switchable windows and/or mullions or other architectural features associated with optically switchable windows. Advantageously, the digital architectural elements may be widely distributed throughout all or much of, at least, a building's perimeter. As a result, the collected data may provide a highly granular, detailed representation of environmental, occupancy and security conditions associated with much or all of a building's interior and/or exterior. For example, many or all of the building's windows may include, or be associated with, a digital architectural element that includes a suite of sensors such as light sensors and/or cameras (visible and/or IR), acoustic sensors such as microphone arrays, temperature and humidity sensors and air quality sensors that detect VOCs, CO2, carbon monoxide (CO) and/or dust.

In some implementations, automated or semi-automated techniques, including machine learning, are contemplated in which the building's environmental control, communications and/or security systems intelligently react to changes in the collected data. As an example, occupancy levels of a room in a building may be determined by light sensors cameras and/or acoustic sensors, and a correlation may be made between a particular change in level of occupancy and a desired change in HVAC function. For example, an increased occupancy level may be correlated with a need to increase airflow and/or lower a thermostat setting. As a further example, data from air quality sensors that detect levels of dust may be correlated with a need to perform building maintenance or introduce or exclude outside air from interior spaces. In one use case scenario for example, dust levels in a room were observed to rise when the occupants were moving about the room, and to decline with the occupants were seated. In such a scenario, a determination may be made that floor coverings need to be serviced (mopped, vacuumed). In another use case scenario, measured interior air-quality may be observed to (i) improve or (ii) degrade when a window is opened. In the case of (i), it may be determined that air circulation ducts or filters of an HVAC system should be serviced. In the case of (ii) it may be determined that exterior air-quality is poor, and that windows of the building should preferentially be maintained in a closed position. In yet a further use case scenario, a correlation may be drawn between the number of occupants in a conference room, and whether doors and/or windows are open or closed, with Co2 levels and/or rate of change of Co2 levels.

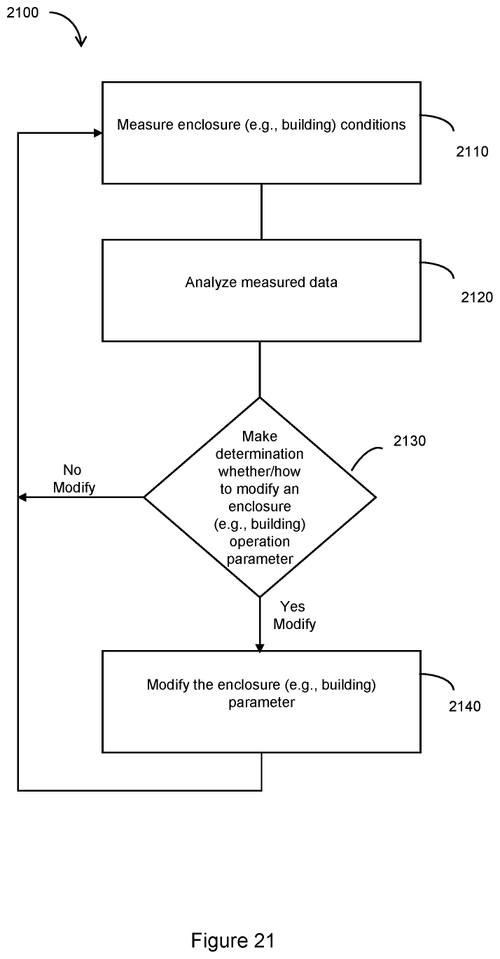

More generally, the present techniques contemplate measuring a plurality of “building conditions” and controlling “building operation parameters” of a plurality of “building systems” responsive to the measured building conditions, as illustrated in the example shown in FIG. 21. As used herein, an “enclosure (e.g., building) condition” may refer to a physical, measurable condition in an enclosure (e.g., building) or a portion of an enclosure (e.g., building). Examples include temperature, air flow rate, light flux and color, occupancy, air quality and composition (particulate count, gas concentration of carbon dioxide, carbon monoxide, water (i.e., humidity)). As used herein, a “enclosure (e.g., building) system” may refer to a system that can control or adjust an enclosure (e.g., building) operation parameter. Examples include an HVAC system, a lighting system, a security system, a window optical condition control system. An enclosure (e.g., building) operation parameter may refer to a parameter that can be controlled by one or more enclosure (e.g., building) systems to adjust or control an enclosure (e.g., building) condition. Examples include heat flux from or to heaters or air conditioners, heat flux from windows or lighting in a room, air flow through a room, and light flux from artificial lights or natural light through an optically switchable window.

Referring to FIG. 21, a method 2100 may include collecting inputs, block 2110, from a plurality of sensors. Some or all of the sensors may be disposed on or associated with a respective window, with a respective digital architectural element (associated or not associated with a window), and/or with a digital wall interface. The sensors may include visible and/or IR light sensors or cameras, acoustic sensors, temperature sensors, humidity sensors, and/or air quality sensors, for example. It will be appreciated that the collected inputs may represent a variety of environmental condition measurements that are temporally and/or spatially diverse. In some implementations, at least some of the inputs may include a combination of sensors. For example, separate sensors, specialized for respective measurements of CO₂, CO, dust and/or smoke may be contemplated, and a combination of inputs from the separate sensors may be analyzed (block 2120), e.g., for determination of air-quality control. As a further example, inputs relevant to a determination of occupancy levels in a room collected from separate sensors that measure, respectively, optical and acoustic signals may be analyzed (block 2120). As a yet further example, inputs may be received, nearly simultaneously, from spatially distributed sensors. For example, the sensors may be spatially distributed with respect to a given room or distributed between multiple rooms and/or floors of the building.

In some implementations, analysis of the measured data at block 2120 may take into account certain “context information” not necessarily obtained from the sensors. Context information may include: time of day and time of year, local weather and/or climatic information. Context information may include information regarding the building layout, and/or usage parameters of various portions of the building. The context information may be initially input by a user (e.g., a building manager). The context information may be updated from time to time, manually and/or automatically. Examples of usage parameters may include a building's operating schedule, and/or an identification of expected and/or permitted/authorized usages of individual rooms or larger portions (e.g., floors) of the building. For example, certain portions of the billing may be identified as lobby space, restaurant/cafeteria space, conference rooms, open plan areas, private office spaces, etc. The context information may be utilized in making a determination as to whether and/or how to modify building operation parameter, block 2130, and also for calibration and, optionally, adjustment of the sensors. For example, based on the context information, certain sensors may, optionally, be disabled in certain portions of the building in order to meet an occupant's privacy expectations. As a further example, sensors for rooms in which a considerable number of persons may be expected to congregate (e.g., an auditorium) may advantageously be calibrated or adjusted differently than sensors for rooms expected to have fewer occupants (e.g., private offices).

An objective of the analysis at block 2120 may be to determine that a particular building condition exists or may be predicted to exist. As a simple example, the analysis may include comparing a sensor reading such as a light flux or temperature measurement with a threshold. As a further, more sophisticated example, when an occupancy load in a room undergoes a change (because, for example, a meeting in a conference room convenes or adjourns) the analysis at block 2120 may, first, directly recognize the change as a result of inputs from acoustic and/or optical sensors associated with the room; second, the analysis may predict an environmental parameter that may be expected to change as a result of a change in occupancy load. For example, an increase in occupancy load can be expected to lead to increased ambient temperatures and increased levels of CO₂. Advantageously, the analysis at block 620 may be performed automatically on a periodic or continuous basis, using models or other algorithms that may be improved over time using, for example, machine learning techniques. In some implementations, the analysis may not explicitly identify a particular building condition (or combination of conditions) in order to determine that a building operation parameter should be adjusted.

Referring to block 2130 a determination as to whether or how to modify building operation parameter may be made based on the results of analysis block 2120. Depending on the determination, the building condition may or may not be changed. When a determination is made to not modify building operation parameter the method may return to block 2110. When a determination is made to modify an enclosure (e.g., building) for operation parameter, one or more enclosure (e.g., building) conditions may be adjusted, at block 2140, for purposes of improving occupant comfort or safety and/or to reduce operating costs and energy consumption, for example. For example, lights and/or HVAC service, may be set to a low power condition in rooms that are determined to be unoccupied. As a further example, a determination may be made that a fault or issue has arisen that requires attention of the enclosure (e.g., building) administration, maintenance and/or security personnel.

The determination may be made on a reactive and/or proactive basis. For example, the determination may react to changes in measured parameters, e.g., a determination may be made to increase HVAC flowrates when a rise in ambient CO₂ is measured. The determination may be made on a proactive basis, i.e., the building operation parameter may be adjusted in anticipation of an environmental change before the change is actually measured. For example, an observed change in occupancy loads may result in a decision to increase HVAC flowrates whether or not a corresponding rise in ambient CO₂ or temperature is measured.

In some implementations, the determination may relate to building operation parameters associated with HVAC (e.g., airflow rates and temperature settings), which may be controlled in one or more locations based on measured temperature, CO₂ levels, humidity, and/or local occupancy. In some implementations the determination may relate to building operation parameters associated with building security. For example, in response to an anomalous sensor reading, a security system alarm may be caused to trigger, selected doors and windows may be locked or unlocked, and/or a tint state of all or some windows may be changed. Examples of security-related building conditions include detection of a broken window, detection of an unauthorized person in a controlled area, and detection of unauthorized movement of equipment, tools, electronic devices or other assets from one location to another.

Other types of security-related building condition information can include information related to detection of the occurrence of the detection of sound outside and/or within the building. In one embodiment, the detected sound is analyzed for type of sound. In some embodiments, analysis is initiated via hardware, firmware, or software onboard to one or more digital structural element or elsewhere in a building, or even offsite. In some embodiments, sound outside or inside of a building causes conductive layers deposited on window glass of an electrochromic window to vibrate, which vibrations cause changes in capacitance between the conductive layers, and which changes of capacitance are converted into a signal indicative of the sound. Thus, some windows of the present invention can inherently provide the functionality of a sound and/or vibration sensor, however, in other embodiments, sound and/or vibration sensor functionality can be provided by sensors that have been added to windows with or without conductive layers, and/or by one or more sensors implemented in digital structural elements.

In one embodiment, an originating location of sound can be determined by analyzing differences in sound amplitude and/or sound time delays that different ones of sound and or vibration sensors experience. Types of sound detected and then analyzed include, but are not limited to: broken window sounds, voices (for example, voices of persons authorized or unauthorized to be in certain areas), sounds caused by movement (of persons, machines, air currents), and sounds caused by the discharge of firearms. In one embodiment, depending on the type of sound detected, one or more appropriate security or other action is initiated by one or more system within the building. For example, upon a determination that a firearm has been discharged at a location outside or inside of a building, a building management system makes an automated 911 call to summon emergency responders to the location.

In the case of sound generated by a firearm inside of a building, knowing the precise location (for example, room, floor, and building information) of the sound as well as the shooter who generated the sound is essential to a proper emergency response. However, in buildings with large open space floor plans and/or hallways, textual positional information that requires reference to a particular building's floor plan may delay the response. Rather than just textual positional information, in one embodiment visual positional information is provided. Visual positional information of sound can be provided by installed camera system, if so equipped, but in one embodiment, is provided by causing the tint state of one or more window determined to be the closest to sound generated by the firearm or the shooter to be changed to a distinctive tint state. For example, in one embodiment, upon sensing of a sound of interest, a tint of a tintable window closest to the sound of interest is caused to change to a tint that is darker than the tint of windows that are farther away from the sound, or vice versa. In this manner, if responders were unable to quickly be able to locate a particular room on a particular floor of a particular building, they might to be able to do so by visually looking for a window that has been distinctively tinted to be darker or lighter than other windows.

In some embodiments, a current location of a person associated with a particular sound may be different from their initial location, in which case, their change in location can be updated via detection of other sounds or changes caused by the person to the environment. For example, in the case of an active shooter situation, gas sensors in digital architectural elements or other predetermined locations can be used to monitor changes in air quality caused by the presence of exploded gunpowder, and to thereby provide responders with updates as to location of the shooter. Sound and other sensors could also be used to obtain the location of persons trying to quietly hide from and active shooter (for example, via infrared detection of their location). In one embodiment, to confuse an active shooter, sounds can be generated by speakers in digital architectural elements or other speakers in the shooters location to distract the shooter, or to mask noises made by hostages trying to hide from him. In one embodiment, speakers and/or microphones in digital architectural elements or other devices could be selectively made active to communicate with persons trying to hide from an active shooter. Apart from causing the tint of one or more windows to be made distinctive to help identify the location of sound, in some embodiments, the distinctive tint of the windows may need to be changed to some other tint, for example to provide more light to facilitate one or more persons entry or egress from a particular location or to provide less light to hinder visibility in a particular location.

Referring to FIG. 21, at block 2140, one or more enclosure (e.g., building) parameters may be modified responsive to the determination made at block 2130. The enclosure (e.g., building) parameter modification may be implemented under the control of a building management system in some embodiments, and may be implemented by one or more of the enclosure (e.g., building) systems such as HVAC, lighting, security, and window controller network, for example. It will be appreciated that the enclosure (e.g., building) parameter modification may be selectively made on a global (building-wide) basis or localized areas (e.g., individual rooms, suites of rooms, floors, etc.),

As mentioned, an enclosure (e.g., building) system that determines how to modify enclosure (e.g., building) operation parameters may employ machine learning. This means that a machine learning model is trained using training data. In certain embodiments, the process begins by training an initial model through supervised or semi-supervised learning. The model may be refined through on-going training/learning afforded by use in the field (e.g., while operating in a functioning building). Examples of training data (enclosure (e.g., building) conditions interplay with one another and/or with enclosure (e.g., building) operations parameters) include the following combinations of sensed or context data (X or inputs) and enclosure (e.g., building) operation parameters or tags (Y or output): (a) [X=occupancy (as measured by IR or camera/video), context, light flux (internal+solar); Y=ΔT/time (without cooling)]; (b) [X=occupancy (as measured by IR or camera/video), context; Y=ΔCO₂/time (with nominal ventilation)]; and (c) [X=occupancy (as measured by IR or camera/video), context, temperature, external relative humidity (RH); Y=ΔRH/time (with nominal ventilation)]. Part of the purpose of machine learning is to identify unknown or hidden patterns or relationships, so the learning typically uses a large number of inputs (X) for each possible output (Y).

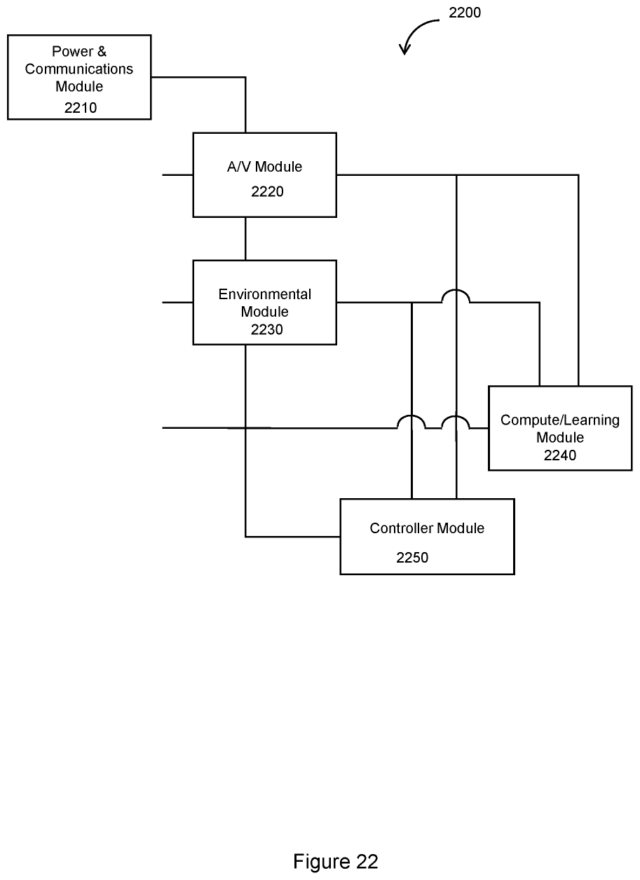

In some embodiments, execution of the process flow illustrated in FIG. 21 may be facilitated by provisioning digital architectural elements with a suite of functional modules for the collection and analysis of environmental data, communications and control. FIG. 22 illustrates an example of a suite of such functional modules, according to an implementation. In the illustrated embodiment, a digital architectural element 2200 includes a power and communications module 2210, an audiovisual (A/V) module 2220, an environmental module 2230, a compute/learning module 2240 and a controller module 2250.

The power and communications module 2210 may include one or more wired and/or wireless interfaces for transmission and reception of communication signals and/or power. Examples of wireless power transmission techniques suitable for use in connection with the presently disclosed techniques are described in U.S. Provisional patent application Ser. No. 62/642,478, filed Mar. 13, 2018, titled “WIRELESSLY POWERED AND POWERING ELECTROCHROMIC WINDOWS, filed Mar. 13, 2018, International Patent Application Serial No. PCT/US17/52798, filed Sep. 21, 2017, titled “WIRELESSLY POWERED AND POWERING ELECTROCHROMIC WINDOWS,” and U.S. patent application Ser. No. 14/962,975, filed Dec. 8, 2015, titled WIRELESS POWERED ELECTROCHROMIC WINDOWS, each assigned to the asset any of the present application, the contents of which are hereby incorporated by reference in their entirety into the present application. The power and communications module 2310 may be communicatively coupled with and distribute power to each of the audiovisual (A/V) module 2220, the environmental module 2230, the compute/learning module 2240 and the controller module 2250. The power and communications module 2210 may also be communicatively coupled with one or more other digital architectural elements (not illustrated) and/or interface with a power and/or control distribution node of the building.

The A/V module 2230 may include one or more of the A/V components described hereinabove, including a camera or other visual and/or IR light sensor, a visual display, a touch interface, a microphone or microphone array, and a speaker or speaker array. In some embodiments, the “touch” interface may additionally include gesture recognition capabilities operable to detect recognize and respond to non-touching motions of a person's appendage or a handheld object.

The environmental module 2230 may include one or more of the environmental sensing components described hereinabove, including temperature and humidity sensors, acoustic light sensors, IR sensors, particle sensors (e.g., for detection of dust, smoke, pollen, etc.), VOC, CO, and/or CO2 sensors. The environmental module 2230 may functionally incorporate a suite of audio and/or electromagnetic sensors that may partially or completely overlap the sensors (e.g., microphones, visual and/or IR light sensors) described above in connection with A/V module 2230. In some embodiments, a “sensor” as the term is used herein may include some processing capability, in order, for example, to make determinations such as occupancy (or number of occupants) in a region. Cameras, particularly those detecting IR radiation can be used to directly identify the number of people in a region. A sensor may provide raw (unprocessed) signals to the compute/learning module 2240 and/or to the controller module 2250.

The compute and/or learning module 2240 may include processing components (including general or special purpose processors and memories) as described hereinabove for the digital architectural element, the digital wall interface, and/or the enhanced functionality window controller. The compute and/or learning module may include a specially designed ASIC, digital signal processor, or other type of hardware, including processors designed or optimized to implement models such as machine learning models (e.g., neural networks). Examples include Google's “tensor processing unit” or TPU. Such processors may be designed to efficiently compute activation functions, matrix operations, and/or other mathematical operations required for neural network or other machine learning computation. For some applications, other special purpose processors may be employed such as graphics processing units (GPUs). In some cases, the processors may be provided in a system on a chip architecture.

The controller module 2250 may be or include a window control module incorporating one more features described in U.S. patent application Ser. No. 15/882,719, filed Jan. 29, 2018, titled “CONTROLLER FOR OPTICALLY-SWITCHABLE WINDOWS,” U.S. patent application Ser. No. 13/449,251, filed Apr. 17, 2012, titled “CONTROLLER FOR OPTICALLY-SWITCHABLE WINDOWS,” International Patent Application Serial No. PCT/US17/47664, filed Aug. 18, 2017, titled “ELECTROMAGNETIC-SHIELDING ELECTROCHROMIC WINDOWS,” U.S. patent application Ser. No. 15/334,835, filed Oct. 26, 2016, titled “CONTROLLERS FOR OPTICALLY-SWITCHABLE DEVICES,” and International Patent Application Serial No. PCT/US17/61054, filed Nov. 10, 2017, titled “POWER DISTRIBUTION NETWORKS FOR ELECTROCHROMIC DEVICES,” each assigned to the assignee of the present application and hereby incorporated by reference into the present application in their entireties.

For clarity of illustration, FIG. 22 presents the digital architectural elements 2200 as incorporating separate and distinct modules 2210, 2220, 2230, 2240 and 2250. It should be appreciated however that two or more modules may be structurally combined with each other and/or with features of the digital wall interface described hereinabove. Moreover, it is contemplated that, in a building installation including a number of digital architectural elements, not every digital architectural element will necessarily include all the described modules 2210, 2220, 2230, 2240 and 2250. For example, in some embodiments one or more of the described modules 2210, 2220, 2230, 2240 and 2250 may be shared by a plurality of digital architectural elements.

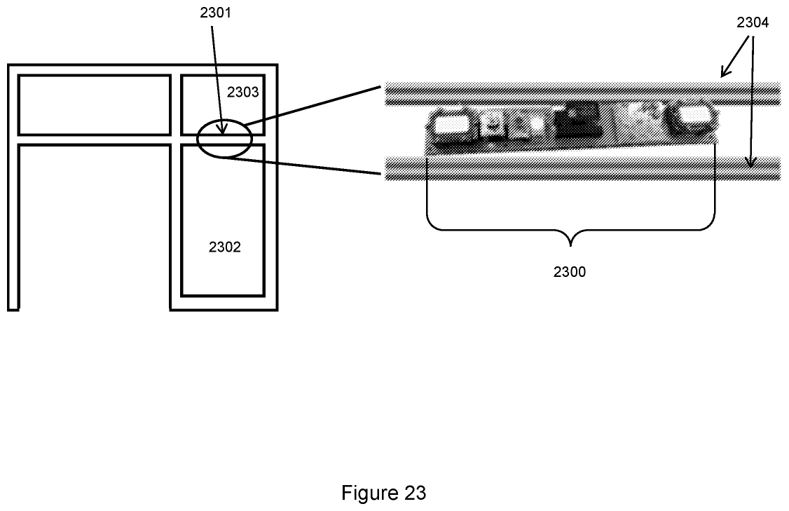

FIG. 23 illustrates an example of a digital architectural element 2300, according to some implementations. The DAE is disposed in a window frame portion 2301 (shown as 2304 in magnification) that borders windows 2302 and 2303. As may be observed in FIG. 23, it is contemplated that the functionality of the described modules 2210, 2220, 2230, 2240 and 2250 may be configured in a physical package having a size and form factor that can be readily accommodated by an architectural feature such as a typical window mullion.

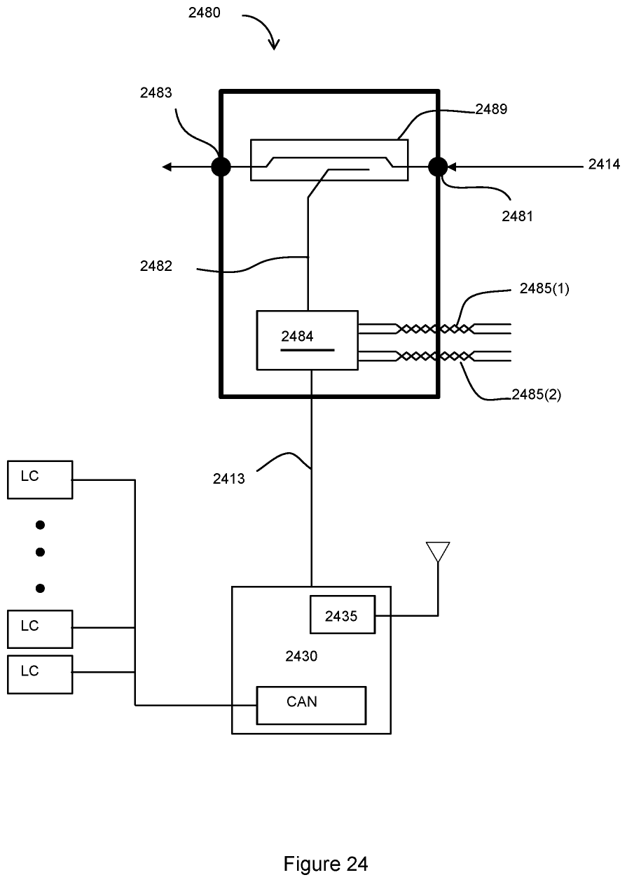

FIG. 24 shows an example of a portion of a data and power distribution system having a digital architectural element (such as a “smart frame” or similar communications/processing module) 2430 coupled by way of a drop line 2413 with a combination module 2480 that includes a directional coupler 2489 and a bias tee circuit 2484. The drop line 2413 may carry both power and data downstream (e.g., using a coaxial cable), to the DAE 2430, and carries data from the DAE 2430 upstream, to a control panel (not shown). Data from a control panel (or other upstream source) may be provided via a coaxial cable input port 2481. This data is provided to the directional coupler 2489 of combination module 2480. The directional coupler 2489 can extract some of the data signal and transmits it on a line 2482, which may be a cable, an electrical trace on a circuit board, etc., depending on the design of the combination module 2480. Data from the control panel that is not tapped off by the combination trunk tee exits via a coaxial cable output port 2483.

Line 2482 connects to the bias tee circuit 2484 in the combination module 2480. Two twisted pair conductors (or other power carrying lines) 2485(1) and 2485(2) are also connected to the bias tee circuit 2484. With these connections, the bias tee circuit couples the power and data onto drop line 2413, which may be a coaxial cable. The digital architectural element or other communications/processing element 2430 may, as depicted, include and/or connect to components for cellular communication (e.g., the illustrated antenna) and cellular or CBRS processing logic 2435 that. The processing logic 2435, in some embodiments, may be at least fifth generation communication protocol (5G) compatible. In certain embodiments, the digital architectural element or other communications/processing element 2430, as depicted, provides a CAN bus gateway that provides data and power to one or more CAN bus nodes such as window controllers, which control tint states of associated optically controllable windows.

In certain embodiments, during construction of a building, modules such as the combination module 2480 illustrated in FIG. 24 may be installed (e.g., liberally) throughout the building, including at some locations where they are not initially connected to digital architectural elements or other processing/communications modules. In such embodiments, the combination trunk tees may be used, after construction, to install digital processing devices, as needed by the building and/or tenants or other occupants.

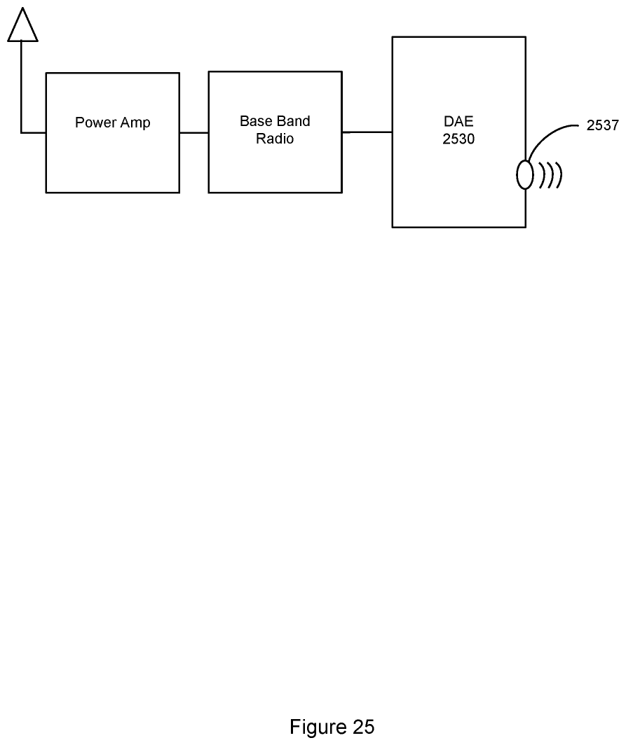

FIGS. 25, 26, and 27 present examples of block diagrams of versions of a digital architectural element, a digital wall interface, or similar device. For convenience, the following discussion will refer to a digital architectural element (DAE). FIG. 25 illustrates a DAE 2530 that can support multiple communication types, including, e.g., Wi-Fi communications with its own antenna 2537. Alternately or in addition the DAE 2530 may include or be coupled with cellular communications infrastructure such as, in the illustrated embodiment, a base band radio, an amplifier, and an antenna. Similarly, while not explicitly shown here, digital architectural element 2530 may support a citizen's band radio system (CBRS) employing a similar base band radio. From a communications and data processing perspective, the digital architectural element in this figure has the same general architecture as the full-featured digital architectural element. But it does not include a sensor and perhaps not ancillary components such as a display, microphone, and speakers.

In some embodiments, digital architectural elements support a modular style sensor configuration that allow for individual upgrade and replacement of sensors via plug and play insertion in a backbone type circuit board having a set of slots or sockets. In one embodiment, sensors used in the digital structural elements can be installed normal to the backbone in one of a multitude of slots/sockets standardized for maximum flexibility and functionality. In some embodiments, the sensors are modular and can be plug and play replaced via removal and insertion through openings in housing of the digital architectural elements. Failed sensors can be replaced or functionality/capabilities can be modified as needed. In one embodiment where digital architectural elements are installed during a construction phase of a project/building, use of plug and play sensors allows customization of digital architectural elements with one or more sensors that may not be needed when the project/building is ready for occupancy. For example, during construction, sensors could be installed to track construction assets within the site or monitor for unsafe (OSHA+) noise or air quality levels and/or a night camera could be installed to monitor movement on a construction site when the site would normally be unoccupied by workers. As desired or needed, after construction, these or other sensors could be removed, and quickly and easily replaced or supplemented during an occupancy phase, or at a later phase, when upgraded or sensors with new capabilities were needed or became available.

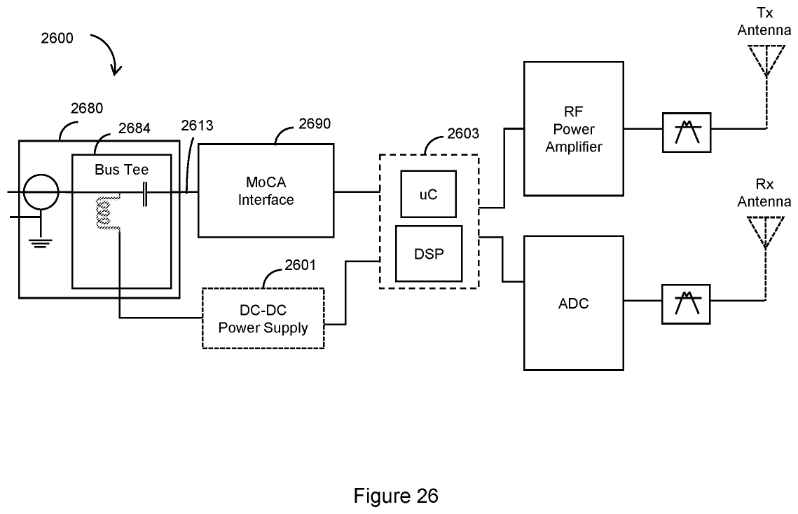

FIG. 26 illustrates a system 2600 of components that may be incorporated in or associated with a DAE. The system 2600 may be configured to receive and transmit data wirelessly (e.g., Wi-Fi communications, cellular communications, citizens band radio system communications, etc.) and/or to transmit data upstream and receive data downstream via, e.g., a coaxial drop line. In FIG. 26, elements of the system 2600 are presented at a relatively high level. The embodiment illustrated in FIG. 26 includes circuits that serve a similar function to the combination module 2480 (described in connection with FIG. 24) at the interface of the trunk line and the drop line, specifically, a module 2680 including a bias tee circuit 2684 takes power and data from separate conductors (trunk line) and puts them on one cable (a drop line 2613). Thus, for downstream transmission, a coaxial drop line may deliver both power and data to a MoCA interface 2690 of a digital architectural element on the same conductors.

As illustrated, the system 2600 includes the bias tee circuit 2684 coupled by way of the drop line 2613 to a MoCA interface 2690. The MoCA interface 2690 is configured to convert downstream data signals provided in a MoCA format on coaxial cable (the drop line in this case) to data in a conventional format that can be used for processing. Similarly, the MoCA interface 2690 may be configured to format upstream data for transmission on a coaxial cable (drop line 2613). For example, packetized Ethernet data may be MoCA formatted for upstream transmission on coaxial cable.

In the illustrated example, a DC-DC power supply 2601 receives DC electrical power from the bias tee circuit 2684 and transforms this relatively high voltage power to a lower voltage power suitable for powering the processing components and other components of digital architectural element 2630. In certain implementations, power supply 2601 includes a Buck converter. The power supply may have various outputs, each with a power or voltage level suitable for a component that it powers. For example, one component may require 12 volt power and a different component may require 3.3 volt power.

In some approaches, the bias tee circuit 2684, the MoCA interface 2690, and the power supply 2601 are provided in a module (or other combined unit) that is used across multiple designs of a digital architectural element or similar network device. Such a module may provide data and power to one or more downstream data processing, communications, and/or sensing devices in the digital architectural element. In the depicted embodiment, a processing block 2603 provides processing logic for cellular (e.g., 5G) or other wireless communications functionality as enabled by a transmission (Tx) antenna and associated RF power amplifier and by a reception (Rx) antenna and associated analog-to-digital converter. In some embodiments, the antennas and associated transceiver logic are configured for wide-band communication (e.g., about 800 MHz-5.8 GHz). Processing block 2603 may be implemented as one or more distinct physical processors. While the block is shown with a separate microcontroller and digital signal processor, the two may be combined in a single physical integrated circuit such as an ASIC.

While the embodiment depicted in FIG. 26 provides separate transmit and receive antennas, other embodiments employ a single antenna for transmission and reception. Further, if a digital architectural element supports multiple wireless communications protocols such as one or more cellular formats (e.g., 5G for Sprint, 5G for T mobile, 4G/LTE for ATT, etc.), it may include separate hardware such antennas, amplifiers, and analog-to-digital converters for each format. Further, if a digital architectural element supports non-cellular wireless communications protocols such as Wi-Fi, citizen's band radio system, etc., it may require separate antennas and/or other hardware for each of these. However, in some embodiments, a single power amplifier may be shared by antennas and/or other hardware for multiple wireless communications formats.

In the depicted embodiment, the processing block 2603 may implement functionality associated with communications such as, for example, a baseband radio for cellular or citizens band radio communications. In some cases, different physical processors are employed for each supported wireless communications protocol. In some cases, a single physical processor is configured to implement multiple baseband radios, which optionally share certain additional hardware such as power amplifiers and/or antennas. In such cases, the different baseband radios may be definable in software or other configurable logic. Examples of network and control system can be found in U.S. Provisional patent application Ser. No. 63/027,452, filed May 20, 2020, titled “DATA AND POWER NETWORK OF AN ENCLOSURE,” which is incorporated herein by reference in its entirety.

In some embodiments, a digital architectural element includes a controller. The controller may monitor and/or direct (e.g., physical) alteration of the operating conditions of the apparatuses, software, and/or methods described herein. Control may comprise regulate, manipulate, restrict, direct, monitor, adjust, modulate, vary, alter, restrain, check, guide, or manage. Controlled (e.g., by a controller) may include attenuated, modulated, varied, managed, curbed, disciplined, regulated, restrained, supervised, manipulated, and/or guided. The control may comprise controlling a control variable (e.g., temperature, power, voltage, and/or profile). The control can comprise real time or off-line control. A calculation utilized by the controller can be done in real time, and/or offline. The controller may be a manual or a non-manual controller. The controller may be an automatic controller. The controller may operate upon request. The controller may be a programmable controller. The controller may be programed. The controller may comprise a processing unit (e.g., CPU or GPU). The controller may receive an input (e.g., from at least one sensor). The controller may deliver an output. The controller may comprise multiple (e.g., sub-) controllers. The controller may be a part of a control system. The control system may comprise a master controller, floor controller, local controller (e.g., enclosure controller, or window controller). The controller may receive one or more inputs. The controller may generate one or more outputs. The controller may be a single input single output controller (SISO) or a multiple input multiple output controller (MIMO). The controller may interpret the input signal received. The controller may acquire data from the one or more sensors. Acquire may comprise receive or extract. The data may comprise measurement, estimation, determination, generation, or any combination thereof. The controller may comprise feedback control. The controller may comprise feed-forward control. The control may comprise on-off control, proportional control, proportional-integral (PI) control, or proportional-integral-derivative (PID) control. The control may comprise open loop control, or closed loop control. The controller may comprise closed loop control. The controller may comprise open loop control. The controller may comprise a user interface. The user interface may comprise (or operatively coupled to) a keyboard, keypad, mouse, touch screen, microphone, speech recognition package, camera, imaging system, or any combination thereof. The outputs may include a display (e.g., screen), speaker, or printer.

The methods, systems, and/or the apparatus described herein may comprise a control system. The control system can be in communication with any of the apparatuses (e.g., sensors) described herein. The sensors may be of the same type or of different types, e.g., as described herein. For example, the control system may be in communication with the first sensor and/or with the second sensor. The control system may control the one or more sensors. The control system may control one or more components of a building management system (e.g., lightening, security, and/or air conditioning system). The controller may regulate at least one (e.g., environmental) characteristic of the enclosure (e.g., sound). The control system may regulate the enclosure environment using any component of the building management system. For example, the control system may regulate the energy supplied by a heating element and/or by a cooling element. For example, the control system may regulate velocity of an air flowing through a vent to and/or from the enclosure. The controller may control items (e.g., level angle, and/or surface roughness) and/or sounds (e.g., white noise) affecting the acoustic mapping in the enclosure. The control system may comprise a processor. The processor may be a processing unit. The controller may comprise a processing unit. The processing unit may be central. The processing unit may comprise a central processing unit (abbreviated herein as “CPU”). The processing unit may be a graphic processing unit (abbreviated herein as “GPU”). The controller(s) or control mechanisms (e.g., comprising a computer system) may be programmed to implement one or more methods of the disclosure. The processor may be programmed to implement methods of the disclosure. The controller may control at least one component of the forming systems and/or apparatuses disclosed herein.

The computer system that is programmed or otherwise configured to one or more operations of any of the methods provided herein can control (e.g., direct, monitor, and/or regulate) various features of the methods, apparatuses and systems of the present disclosure, such as, for example, control heating, cooling, lightening, and/or venting of an enclosure, or any combination thereof. The computer system can be part of, or be in communication with, any sensor or sensor ensemble disclosed herein (e.g., as part of a device ensemble). The sensor may be a standalone sensor or be integrated as part of a device ensemble, e.g., having a single housing. The computer may be coupled to one or more mechanisms disclosed herein, and/or any parts thereof. For example, the computer may be coupled to one or more sensors, valves, switches, lights, windows (e.g., IGUs), motors, pumps, optical components, or any combination thereof.

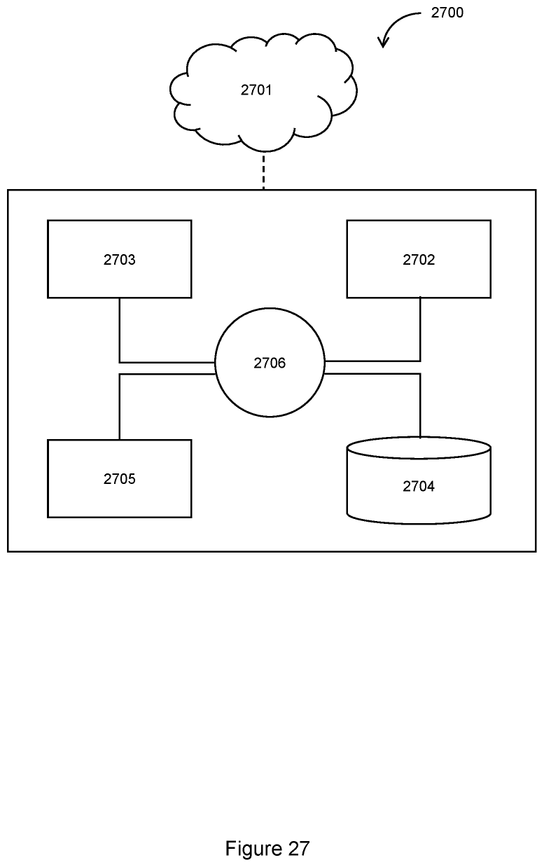

FIG. 27 shows a schematic example of a computer system 2700 that is programmed or otherwise configured to one or more operations of any of the methods provided herein. The computer system can include a processing unit (e.g., 2706) (also “processor,” “computer” and “computer processor” used herein). The computer system may include memory or memory location (e.g., 2702) (e.g., random-access memory, read-only memory, flash memory), electronic storage unit (e.g., 2704) (e.g., hard disk), communication interface (e.g., 2703) (e.g., network adapter) for communicating with one or more other systems, and peripheral devices (e.g., 2705), such as cache, other memory, data storage and/or electronic display adapters. In the example shown in FIG. 27, the memory 2702, storage unit 2704, interface 2703, and peripheral devices 2705 are in communication with the processing unit 2706 through a communication bus (solid lines), such as a motherboard. The storage unit can be a data storage unit (or data repository) for storing data. The computer system can be operatively coupled to a computer network (“network”) (e.g., 2701) with the aid of the communication interface. The network can be the Internet, an internet and/or extranet, or an intranet and/or extranet that is in communication with the Internet. In some cases, the network is a telecommunication and/or data network. The network can include one or more computer servers, which can enable distributed computing, such as cloud computing. The network, in some cases with the aid of the computer system, can implement a peer-to-peer network, which may enable devices coupled to the computer system to behave as a client or a server.

The processing unit can execute a sequence of machine-readable instructions, which can be embodied in a program or software. The instructions may be stored in a memory location, such as the memory 2702. The instructions can be directed to the processing unit, which can subsequently program or otherwise configure the processing unit to implement methods of the present disclosure. Examples of operations performed by the processing unit can include fetch, decode, execute, and write back. The processing unit may interpret and/or execute instructions. The processor may include a microprocessor, a data processor, a central processing unit (CPU), a graphical processing unit (GPU), a system-on-chip (SOC), a co-processor, a network processor, an application specific integrated circuit (ASIC), an application specific instruction-set processor (ASIPs), a controller, a programmable logic device (PLD), a chipset, a field programmable gate array (FPGA), or any combination thereof. The processing unit can be part of a circuit, such as an integrated circuit. One or more other components of the system 2700 can be included in the circuit.

The storage unit can store files, such as drivers, libraries and saved programs. The storage unit can store user data (e.g., user preferences and user programs). In some cases, the computer system can include one or more additional data storage units that are external to the computer system, such as located on a remote server that is in communication with the computer system through an intranet or the Internet.

The computer system can communicate with one or more remote computer systems through a network. For instance, the computer system can communicate with a remote computer system of a user (e.g., operator). Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. A user (e.g., client) can access the computer system via the network.

Methods as described herein can be implemented by way of machine (e.g., computer processor) executable code stored on an electronic storage location of the computer system, such as, for example, on the memory 2702 or electronic storage unit 2704. The machine executable or machine-readable code can be provided in the form of software. During use, the processor 2706 can execute the code. In some cases, the code can be retrieved from the storage unit and stored on the memory for ready access by the processor. In some situations, the electronic storage unit can be precluded, and machine-executable instructions are stored on memory.

The code can be pre-compiled and configured for use with a machine have a processer adapted to execute the code or can be compiled during runtime. The code can be supplied in a programming language that can be selected to enable the code to execute in a pre-compiled or as-compiled fashion.

In some embodiments, the processor comprises a code. The code can be program instructions. The program instructions may cause the at least one processor (e.g., computer) to direct a feed forward and/or feedback control loop. In some embodiments, the program instructions cause the at least one processor to direct a closed loop and/or open loop control scheme. The control may be based at least in part on one or more sensor readings (e.g., sensor data). One controller may direct a plurality of operations. At least two operations may be directed by different controllers. In some embodiments, a different controller may direct at least two of operations (a), (b) and (c). In some embodiments, different controllers may direct at least two of operations (a), (b) and (c). In some embodiments, a non-transitory computer-readable medium cause each a different computer to direct at least two of operations (a), (b) and (c). In some embodiments, different non-transitory computer-readable mediums cause each a different computer to direct at least two of operations (a), (b) and (c). The controller and/or computer readable media may direct any of the apparatuses or components thereof disclosed herein. The controller and/or computer readable media may direct any operations of the methods disclosed herein.

In some embodiments, a tintable window exhibits a (e.g., controllable and/or reversible) change in at least one optical property of the window, e.g., when a stimulus is applied. The change may be a continuous change. A change may be to discrete tint levels (e.g., to at least about 2, 4, 8, 16, or 32 tint levels). The optical property may comprise hue, or transmissivity. The hue may comprise color. The transmissivity may be of one or more wavelengths. The wavelengths may comprise ultraviolet, visible, or infrared wavelengths. The stimulus can include an optical, electrical and/or magnetic stimulus. For example, the stimulus can include an applied voltage and/or current. One or more tintable windows can be used to control lighting and/or glare conditions, e.g., by regulating the transmission of solar energy propagating through them. One or more tintable windows can be used to control a temperature within a building, e.g., by regulating the transmission of solar energy propagating through the window. Control of the solar energy may control heat load imposed on the interior of the facility (e.g., building). The control may be manual and/or automatic. The control may be used for maintaining one or more requested (e.g., environmental) conditions, e.g., occupant comfort. The control may include reducing energy consumption of a heating, ventilation, air conditioning and/or lighting systems. At least two of heating, ventilation, and air conditioning may be induced by separate systems. At least two of heating, ventilation, and air conditioning may be induced by one system. The heating, ventilation, and air conditioning may be induced by a single system (abbreviated herein as “HVAC”). In some cases, tintable windows may be responsive to (e.g., and communicatively coupled to) one or more environmental sensors and/or user control. Tintable windows may comprise (e.g., may be) electrochromic windows. The windows may be located in the range from the interior to the exterior of a structure (e.g., facility, e.g., building). However, this need not be the case. Tintable windows may operate using liquid crystal devices, suspended particle devices, microelectromechanical systems (MEMS) devices (such as microshutters), or any technology known now, or later developed, that is configured to control light transmission through a window. Windows (e.g., with MEMS devices for tinting) are described in U.S. Pat. No. 10,359,681, issued Jul. 23, 2019, filed May 15, 2015, titled “MULTI-PANE WINDOWS INCLUDING ELECTROCHROMIC DEVICES AND ELECTROMECHANICAL SYSTEMS DEVICES,” and incorporated herein by reference in its entirety. In some cases, one or more tintable windows can be located within the interior of a building, e.g., between a conference room and a hallway. In some cases, one or more tintable windows can be used in automobiles, trains, aircraft, and other vehicles, e.g., in lieu of a passive and/or non-tinting window.

In some embodiments, the tintable window comprises an electrochromic device (referred to herein as an “EC device” (abbreviated herein as ECD), or “EC”). An EC device may comprise at least one coating that includes at least one layer. The at least one layer can comprise an electrochromic material. In some embodiments, the electrochromic material exhibits a change from one optical state to another, e.g., when an electric potential is applied across the EC device. The transition of the electrochromic layer from one optical state to another optical state can be caused, e.g., by reversible, semi-reversible, or irreversible ion insertion into the electrochromic material (e.g., by way of intercalation) and a corresponding injection of charge-balancing electrons. For example, the transition of the electrochromic layer from one optical state to another optical state can be caused, e.g., by a reversible ion insertion into the electrochromic material (e.g., by way of intercalation) and a corresponding injection of charge-balancing electrons. Reversible may be for the expected lifetime of the ECD. Semi-reversible refers to a measurable (e.g., noticeable) degradation in the reversibility of the tint of the window over one or more tinting cycles. In some instances, a fraction of the ions responsible for the optical transition is irreversibly bound up in the electrochromic material (e.g., and thus the induced (altered) tint state of the window is not reversible to its original tinting state). In various EC devices, at least some (e.g., all) of the irreversibly bound ions can be used to compensate for “blind charge” in the material (e.g., ECD).

In some implementations, suitable ions include cations. The cations may include lithium ions (Li+) and/or hydrogen ions (H+) (e.g., protons). In some implementations, other ions can be suitable. Intercalation of the cations may be into an (e.g., metal) oxide. A change in the intercalation state of the ions (e.g., cations) into the oxide may induce a visible change in a tint (e.g., color) of the oxide. For example, the oxide may transition from a colorless to a colored state. For example, intercalation of lithium ions into tungsten oxide (WO3−y (0<y≤˜0.3)) may cause the tungsten oxide to change from a transparent state to a colored (e.g., blue) state. EC device coatings as described herein are located within the viewable portion of the tintable window such that the tinting of the EC device coating can be used to control the optical state of the tintable window.

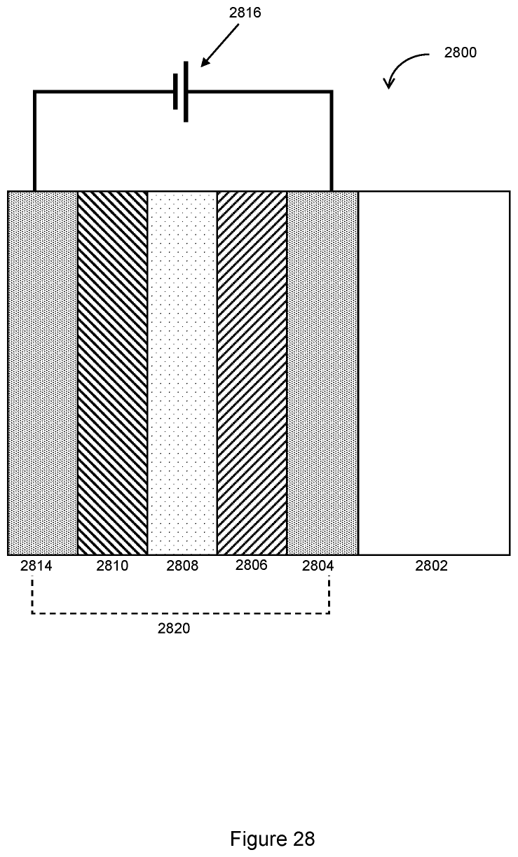

FIG. 28 shows an example of a schematic cross-section of an electrochromic device 2800 in accordance with some embodiments. The EC device coating is attached to a substrate 2802, a transparent conductive layer (TCL) 2804, an electrochromic layer (EC) 2806 (sometimes also referred to as a cathodically coloring layer or a cathodically tinting layer), an ion conducting layer or region (IC) 2808, a counter electrode layer (CE) 2810 (sometimes also referred to as an anodically coloring layer or anodically tinting layer), and a second TCL 2814.

Elements 2804, 2806, 2808, 2810, and 2814 are collectively referred to as an electrochromic stack 2820. A voltage source 2816 operable to apply an electric potential across the electrochromic stack 2820 effects the transition of the electrochromic coating from, e.g., a clear state to a tinted state. In other embodiments, the order of layers is reversed with respect to the substrate. That is, the layers are in the following order: substrate, TCL, counter electrode layer, ion conducting layer, electrochromic material layer, TCL.

In various embodiments, the ion conductor region (e.g., 2808) may form from a portion of the EC layer (e.g., 2806) and/or from a portion of the CE layer (e.g., 2810). In such embodiments, the electrochromic stack (e.g., 2820) may be deposited to include cathodically coloring electrochromic material (the EC layer) in direct physical contact with an anodically coloring counter electrode material (the CE layer). The ion conductor region (sometimes referred to as an interfacial region, or as an ion conducting substantially electronically insulating layer or region) may form where the EC layer and the CE layer meet, for example through heating and/or other processing steps. Examples of electrochromic devices (e.g., including those fabricated without depositing a distinct ion conductor material) can be found in U.S. patent application Ser. No. 13/462,725, filed May 2, 2012, titled “ELECTROCHROMIC DEVICES,” that is incorporated herein by reference in its entirety. In some embodiments, an EC device coating may include one or more additional layers such as one or more passive layers. Passive layers can be used to improve certain optical properties, to provide moisture, and/or to provide scratch resistance. These and/or other passive layers can serve to hermetically seal the EC stack 2820. Various layers, including transparent conducting layers (such as 2804 and 2814), can be treated with anti-reflective and/or protective layers (e.g., oxide and/or nitride layers).

In certain embodiments, the electrochromic device is configured to (e.g., substantially) reversibly cycle between a clear state and a tinted state. Reversible may be within an expected lifetime of the ECD. The expected lifetime can be at least about 5, 10, 15, 25, 50, 75, or 100 years. The expected lifetime can be any value between the aforementioned values (e.g., from about 5 years to about 100 years, from about 5 years to about 50 years, or from about 50 years to about 100 years). A potential can be applied to the electrochromic stack (e.g., 2820) such that available ions in the stack that can cause the electrochromic material (e.g., 2806) to be in the tinted state reside primarily in the counter electrode (e.g., 2810) when the window is in a first tint state (e.g., clear). When the potential applied to the electrochromic stack is reversed, the ions can be transported across the ion conducting layer (e.g., 2808) to the electrochromic material and cause the material to enter the second tint state (e.g., tinted state).

It should be understood that the reference to a transition between a clear state and tinted state is non-limiting and suggests only one example, among many, of an electrochromic transition that may be implemented. Unless otherwise specified herein, whenever reference is made to a clear-tinted transition, the corresponding device or process encompasses other optical state transitions such as non-reflective-reflective, and/or transparent-opaque. In some embodiments, the terms “clear” and “bleached” refer to an optically neutral state, e.g., untinted, transparent and/or translucent. In some embodiments, the “color” or “tint” of an electrochromic transition is not limited to any wavelength or range of wavelengths. The choice of appropriate electrochromic material and counter electrode materials may govern the relevant optical transition (e.g., from tinted to untinted state).

In certain embodiments, at least a portion (e.g., all of) the materials making up electrochromic stack are inorganic, solid (e.g., in the solid state), or both inorganic and solid. Because various organic materials tend to degrade over time, particularly when exposed to heat and UV light as tinted building windows are, inorganic materials offer an advantage of a reliable electrochromic stack that can function for extended periods of time. In some embodiments, materials in the solid state can offer the advantage of being minimally contaminated and minimizing leakage issues, as materials in the liquid state sometimes do. One or more of the layers in the stack may contain some amount of organic material (e.g., that is measurable). The ECD or any portion thereof (e.g., one or more of the layers) may contain little or no measurable organic matter. The ECD or any portion thereof (e.g., one or more of the layers) may contain one or more liquids that may be present in little amounts. Little may be of at most about 100 ppm, 10 ppm, or 1 ppm of the ECD. Solid state material may be deposited (or otherwise formed) using one or more processes employing liquid components, such as certain processes employing sol-gels, physical vapor deposition, and/or chemical vapor deposition.

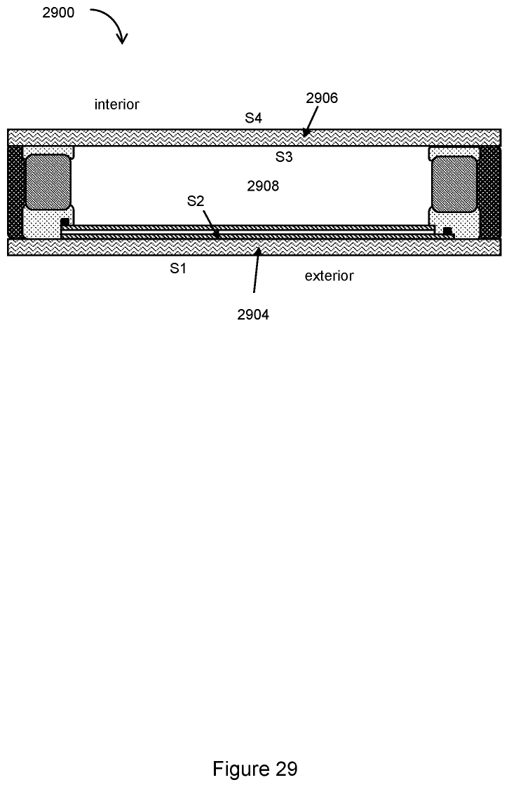

FIG. 29 shows an example of a cross-sectional view of a tintable window embodied in an insulated glass unit (“IGU”) 2900, in accordance with some implementations. The terms “IGU,” “tintable window,” and “optically switchable window” can be used interchangeably herein. It can be desirable to have IGUs serve as the fundamental constructs for holding electrochromic panes (also referred to herein as “lites”) when provided for installation in a building. An IGU lite may be a single substrate or a multi-substrate construct. The lite may comprise a laminate, e.g., of two substrates. IGUs (e.g., having double- or triple-pane configurations) can provide a number of advantages over single pane configurations. For example, multi-pane configurations can provide enhanced thermal insulation, noise insulation, environmental protection and/or durability, when compared with single-pane configurations. A multi-pane configuration can provide increased protection for an ECD. For example, the electrochromic films (e.g., as well as associated layers and conductive interconnects) can be formed on an interior surface of the multi-pane IGU and be protected by an inert gas fill in the interior volume (e.g., 2908) of the IGU. The inert gas fill may provide at least some (heat) insulating function for an IGU. Electrochromic IGUs may have heat blocking capability, e.g., by virtue of a tintable coating that absorbs (and/or reflects) heat and light.

In some embodiments, an “IGU” includes two (or more) substantially transparent substrates. For example, the IGU may include two panes of glass. At least one substrate of the IGU can include an electrochromic device disposed thereon. The one or more panes of the IGU may have a separator disposed between them. An IGU can be a hermetically sealed construct, e.g., having an interior region that is isolated from the ambient environment. A “window assembly” may include an IGU. A “window assembly” may include a (e.g., stand-alone) laminate. A “window assembly” may include one or more electrical leads, e.g., for connecting the IGUs and/or laminates. The electrical leads may operatively couple (e.g., connect) one or more electrochromic devices to a voltage source, switches and the like, and may include a frame that supports the IGU or laminate. A window assembly may include a window controller, and/or components of a window controller (e.g., a dock).

FIG. 29 shows an example implementation of an IGU 2900 that includes a first pane 2904 having a first surface S1 and a second surface S2. In some implementations, the first surface S1 of the first pane 2904 faces an exterior environment, such as an outdoors or outside environment. The IGU 2900 also includes a second pane 2906 having a first surface S3 and a second surface S4. In some implementations, the second surface (e.g., S4) of the second pane (e.g., 2906) faces an interior environment, such as an inside environment of a home, building, vehicle, or compartment thereof (e.g., an enclosure therein such as a room).

In some implementations, the first and the second panes (e.g., 2904 and 2906) are transparent or translucent, e.g., at least to light in the visible spectrum. For example, each of the panes (e.g., 2904 and 2906) can be formed of a glass material. The glass material may include architectural glass, and/or shatter-resistant glass. The glass may comprise a silicon oxide (SOₓ). The glass may comprise a soda-lime glass or float glass. The glass may comprise at least about 75% silica (SiO₂). The glass may comprise oxides such as Na₂O, or CaO. The glass may comprise alkali or alkali-earth oxides. The glass may comprise one or more additives. The first and/or the second panes can include any material having suitable optical, electrical, thermal, and/or mechanical properties. Other materials (e.g., substrates) that can be included in the first and/or the second panes are plastic, semi-plastic and/or thermoplastic materials, for example, poly(methyl methacrylate), polystyrene, polycarbonate, allyl diglycol carbonate, SAN (styrene acrylonitrile copolymer), poly(4-methyl-1-pentene), polyester, and/or polyamide. The first and/or second pane may include mirror material (e.g., silver). In some implementations, the first and/or the second panes can be strengthened. The strengthening may include tempering, heating, and/or chemically strengthening.

In some embodiments, the device ensemble (e.g., DAE) has one or more holes in its casing (e.g., housing or container). The holes may facilitate sensing attributes by the senso(s) disposed in the device ensemble casing. For example, a hole of the casing may be aligned with a sound sensor disposed in the interior of the device ensemble casing.

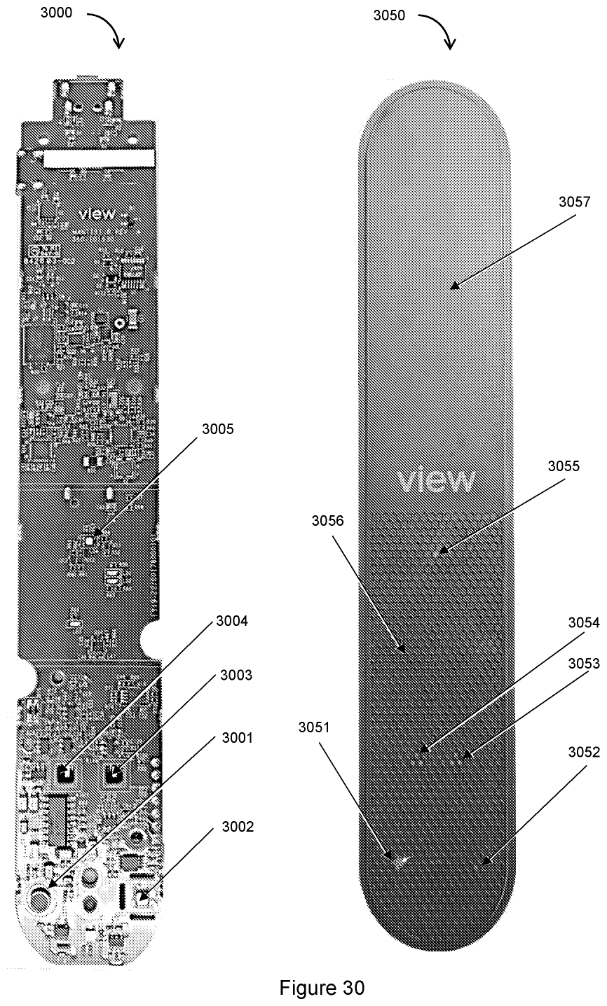

FIG. 30 shows an example of a device ensemble having a casing cover 3051 that comprises a smoother externally exposed surface portion 3057 and a rougher externally exposed surface portion 3056 depicting a pattern that is a hexagonal pattern (e.g., honeycomb pattern). The rougher externally exposed surface portion comprises a plurality of holes including 3051, 3052, 3053, 3054, and 3055. The casing cover is of a casing that houses a circuit board (e.g., printed circuit board) 3000 that includes devices. The devices can comprise sensor(s), emitter(s), processor(s), network interface, memory, transceiver, antenna(s), communication and power port(s), controller(s), and/or any other device disclosed herein. The holes 3051-3052 may be disposed such that they align with a sensor or sensor array. The sensor(s) may be disposed on a front side of circuit board 3000 facing the viewer, or on a back side of circuit board 3000 away from the viewer. For example, hole 3051 aligns with sound sensor 3001 disposed on the front side of circuit board 3000 facing the viewer; hole 3052 aligns with sensor 3002 disposed on the front side of circuit board 3000 facing the viewer; hole 3053 aligns with sensor 3003 disposed on aback side of circuit board 3000 away from the viewer; hole 3054 aligns with sensor 3004 disposed on aback side of circuit board 3000 away from the viewer; hole 3055 aligns with sensor 3005 disposed on the front side of circuit board 3000 facing the viewer. The sensor(s) disposed in the back side of circuit board 3000 may be gas sensor(s) such as carbon dioxide and/or humidity sensors. The circuit board may have a plurality of temperature sensors configure to sense temperature of the devise ensemble interior and/or exterior. A sensor that may be configured to sense the device ensemble exterior may be aligned with a hole in the device ensemble casing cover 3051. Examples of sensor and/or emitter configuration in a device ensemble are disclosed in International Patent Application Serial No. PCT/US21/30798 filed May 5, 2021, titled “DEVICE ENSEMBLES AND COEXISTENCE MANAGEMENT OF DEVICES,” which is incorporated herein by reference in its entirety. The device ensemble may comprise a casing enclosure devices comprising (i) sensors, (ii) a sensor and an emitter, or (iii) a sensor and a transceiver. The device ensemble housing may enclosure at least 2, 3, 5, 7, 10, 15, 20, or 30 devices. The devices of the device ensemble may be operatively couple to one or more circuit boards enclosed by the casing (e.g., by the housing).

In some embodiments, sensors disposed at different locations of a facility measure different measurements of an attribute. For example, different sound sensors disposed in different locations in the facility may measure different sounds and/or different sounds patterns. The sound patterns may have an oscillatory attribute. The oscillation may correspond to a frequency of a mechanical device such as an actuator (e.g., motor). The oscillation may correspond to behavioral patterns occurring around or in the facility, e.g., of behavioral patterns of the facility occupants. The oscillations may have a fine structure that may or may not be oscillating. The fine structure may superimpose the oscillations. For example, a building may be noisy during the day when occupants are active, and quieter during the night when occupants are absent or passive. The noise pattern may raise during the day and fall during the night. In addition, during a gathering (e.g., party or conference), the noise level may especially elevate in the facility. The noise pattern may detect on what day the gathering occurred, and at which location (e.g., location having a sensor that measured that abnormally loud sounds). Once the louds sound is detected, a control system may take remedial measures to dampen the sound. When a repetitive loud sound is detected at a location (e.g., a conference room or cafeteria in which the sound is consistently uncomfortably loud), persistent remedial measures may be taken in that location. The persistent remedial measures may be passive (e.g., installing sound damping wall, ceiling, and/or floor material). The persistent remedial measures may be active (e.g., using persistent white noise machine, vibrating windows to dampen the sound, and the like).

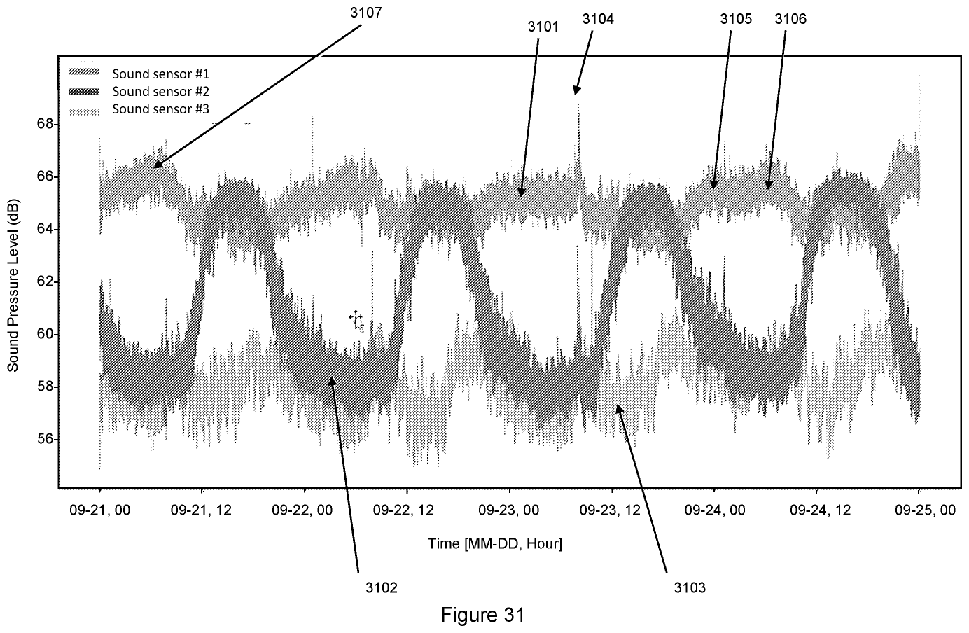

FIG. 31 shows an example of a graph depicting sound as a function of time of three different sensors number 1, 2, and 3 that are disposed in a facility at different locations. The graph delineates a relative lowest noise level of sensor #1 measuring data 3101, as compared to an increased noise level measured by sensor #3 measuring data 3103, and a highest noise level measured by sensor #2 measuring data 3102. All three sensors measure oscillatory noise level that seems to oscillate on an approximate 24 h basis, with some variations. For example, measurements of sensor #1 depict data variations such as spike 3104, two daily maxima 3105 and 3106, and one daily maxima 3107.

While preferred embodiments of the present invention have been shown, and described herein, it will be obvious to those skilled in the art that such embodiments are provided by way of example only. It is not intended that the invention be limited by the specific examples provided within the specification. While the invention has been described with reference to the afore-mentioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations, or relative proportions set forth herein which depend upon a variety of conditions and variables. It should be understood that various alternatives to the embodiments of the invention described herein might be employed in practicing the invention. It is therefore contemplated that the invention shall also cover any such alternatives, modifications, variations, or equivalents. It is intended that the following claims define the scope of the invention and that methods and structures within the scope of these claims and their equivalents be covered thereby.

1. A method of acoustic mapping, the method comprising:
using an emitter to emit a first acoustic test signal, which first emitter is disposed at a first location in an enclosure;
using a sensor to measure a first acoustic response corresponding to the first acoustic test signal, which sensor is disposed at a second location;
storing a first acoustic map indicative of an acoustic transfer function between the first location and the second location;
using the emitter to emit a second acoustic test signal;
measuring a second acoustic response corresponding to the second acoustic test signal;
determining a second acoustic map; and
generating a notification and/or a report when a difference between the second acoustic map and the first acoustic map is greater than a threshold.

2. The method of claim 1, further comprising controlling at least one apparatus in the enclosure and/or in a facility in which the enclosure is disposed, wherein the emitter is operatively coupled to a control system; and the controlling is by the control system.

3. (canceled)

4. The method of claim 2, wherein the at least one apparatus comprises a lighting device, a tintable window, another sensor, another emitter, a media display, a dispenser, a processor, a power source, a security system, a fire alarm system, a sound media, a heater, a cooler, a vent, or a heating ventilation and air conditioning system (HVAC).

5. The method of claim 1, further comprising using the emitter to emit sounds including discrete sounds of a sound spectrum.

6. (canceled)

7. The method of claim 1, further comprising using the emitter to emit the first acoustic test signal and/or the second acoustic test signal when the enclosure is non-inhabited.

8. The method of claim 1, further comprising using the emitter to emit the second acoustic test signal according to a schedule that considers a change in a Building Information Modeling file of the enclosure and/or of the facility in which the enclosure is disposed.

9. The method of claim 1, wherein measurement of the second acoustic response is by the same sensor measuring the first acoustic response.

10. (canceled)

11. The method of claim 1, wherein the sensor is a first sensor, and wherein the method further comprises:
using a second sensor disposed at a third location to measure a third acoustic response to the second acoustic test signal, wherein the second acoustic response measured is sensed at the second location by the second sensor; and
comparing the second acoustic response and the third acoustic response to detect a fault in the emitter or in one of the sensors.

12. The method of claim 1, wherein the emitter is a first emitter, and wherein the method further comprises:
using a second emitter at a third location to emit a third acoustic test signal;
measuring a third acoustic response corresponding to the third acoustic test signal; and
comparing the third acoustic response to the acoustic response to the second acoustic test signal to detect a fault in the sensor, in the first emitter, or in the second emitter.

13. The method of claim 1, further comprising:
detecting an irregular sound event in the enclosure utilizing a plurality of sensors that include the sensor;
compensating the detected sound event according to a corresponding acoustic transfer function from the first acoustic map and/or the second acoustic map;
recognizing an event type utilizing the compensated detected sound event; and
generating a notification of the event type to a user.

14.-18. (canceled)

19. A method of acoustic mapping, the method comprising:
using an emitter to emit an acoustic test signal, which emitter is disposed at a first location in an enclosure;
using a sensor to measure an acoustic response corresponding to the acoustic test signal, which sensor is disposed at a second location; and
using information pertaining to an inanimate alteration to generate an acoustic map indicative of an acoustic transfer function between the first location and the second location, which inanimate alteration is projected to affect the acoustic mapping of the enclosure.

20. The method of claim 19, further comprising using the emitter to emit the acoustic test signal according to a schedule.

21. (canceled)

22. (canceled)

23. The method of claim 19, wherein the sensor is a first sensor, and wherein the method further comprises using a second sensor to measure at least one other acoustic response corresponding to the acoustic test signal, which second sensor is disposed at a third location different from the second location.

24. The method of claim 19, wherein the information comprises a shape, or a material property of one or more fixtures.

25. The method of claim 19, wherein the inanimate alteration is of one or more fixtures and/or non-fixtures.

26. (canceled)

27. (canceled)

28. The method of claim 19, wherein generation of the acoustic map utilizes information of sound frequency sweeping, location, and coordination, of the emitter, of the sensor, of the at least one other emitter, and/or of the at least one sensor.

29.-33. (canceled)

34. A method of acoustic mapping, the method comprising:
sensing a present sound event in an enclosure by using a plurality of sensors;
comparing the present sound event sensed by the plurality of sensors to historic sensed data by the plurality of sensors to generate a result;
using the result to determine any irregular sound event in the enclosure by comparing to a threshold; and
compensating for the irregular sound event according to a corresponding acoustic transfer function of the enclosure, which transfer function is determined utilizing at least one sensor of the plurality of sensors.

35. The method of claim 34, further comprising localizing an origination of the irregular sound event based at least in part on relative magnitudes of the detected irregular sound event sensed by at least two, or by at least three of the plurality of sensors.

36. The method of claim 34, further comprising recognizing an event type of the irregular sound event, and generating a notification of the event type to a user.

37. The method of claim 34, wherein the compensation utilizes one or more acoustic modification devices operatively coupled to a network to which the plurality of sensors are operatively coupled to.

38.-62. (canceled)
